(19) United States
(12) Patent Application Publication
(10) Pub. No.: US 2016/0005997 A1
(43) Pub. Date: Jan. 7, 2016

(54) ORGANIC ELECTROLUMINESCENT ELEMENT AND METHOD OF MANUFACTURING ORGANIC ELECTROLUMINESCENT ELEMENT

(71) Applicant: KONICA MINOLTA, INC., Tokyo (JP)

(72) Inventor: Shota HIROSAWA, Tokyo (JP)

(21) Appl. No.: 14/770,254

(22) PCT Filed: Mar. 7, 2014
(86) PCT No.: PCT/JP2014/056064

§ 371 Date: Aug. 25, 2015

(30) Foreign Application Priority Data
Mar. 8, 2013 (JP) 2013-046994

(51) Int. Cl. H01L 51/52

(52) U.S. Cl. CPC H01L 51/5253; H01L 51/5246; H01L 2251/5338; H01L 2251/301

(57) ABSTRACT

This organic electroluminescent element is provided with the following: a barrier layer that is provided on a flexible substrate and comprises a modified-polysilazane layer; a laminate that is laid out on top of the barrier layer and is provided with an organic functional layer that has at least one light-emitting layer between a pair of electrodes; a covering intermediate layer formed on top of the barrier layer at least at the periphery of the laminate; and a sealing member joined to the top of the covering intermediate layer with a sealing resin layer interposed therebetween.

### TECHNICAL FIELD

The present invention relates to an organic electroluminescent element and a method of manufacturing the organic electroluminescent element.

### BACKGROUND ART

An organic electroluminescent element (hereinafter, referred to as organic EL element) by using an organic substance is considered to be useful in applications to, for example, an inexpensive large-area full-color display element of a solid light emission type, a light emitter of a writing light source array, and the like, and thus the research and development of the organic EL element has been actively progressed.

Recently, in the field of the organic EL element, there are particularly required light weight, flexibility, ease of handling, and the like from the viewpoints of curved surface arrangement and increase in size of the organic EL element panels. On the other hand, in order to enhance reliability and maintenance of the organic EL element, it is considered to be necessary to forma barrier layer obtained by imparting a high gas barrier ability to a flexible substrate.

As such a barrier layer, there has been proposed a gas barrier film in which a barrier layer obtained by performing modification treatment on a polysilazane-containing liquid is provided on the substrate (for example, refer to Patent Literature 1). According to the gas barrier film, it has been disclosed that performance deterioration of an organic photoelectric conversion element, or the like can be suppressed because of its low moisture vapor transmission rate. In addition, it has been disclosed that a functional layer such as an organic photoelectric conversion layer is solid-sealed by using a resin adhesive and a sealing material.

### CITATION LIST

### Patent Literature

Patent Literature 1: Japanese Patent Laid-Open No. 2011-68124

### SUMMARY OF INVENTION

### Technical Problem

However, when the barrier layer obtained by performing modification treatment on the polysilazane-containing liquid is formed on the substrate, adhesion between the sealing member and the substrate is lowered in performing solid-sealing by using a sealing resin such as a thermosetting resin. This lowering of the adhesion of the sealing resin causes failures of the element by peeling-off or the like of the sealing member. For example, moisture or the like permeates through the interface between the sealing member and the barrier layer to thereby lower reliability of the organic EL element.

In order to solve the above problem, the present invention can provide an organic electroluminescent element capable of enhancing the reliability.

### Solution to Problem

The organic electroluminescent element of the present invention includes a barrier layer that is provided on a flexible substrate and includes a modified-polysilazane layer; a laminate that is laid out on top of the barrier layer and that is provided with an organic functional layer that has at least one light-emitting layer between a pair of electrodes; a covering intermediate layer formed on top of the barrier layer at least at the periphery of the laminate; and a sealing member joined to the top of the covering intermediate layer with a sealing resin layer interposed therebetween. In addition, the element is solid-sealed by a flexible substrate and a sealing member joined, by a sealing resin layer, to the flexible substrate.

A method of manufacturing an organic electroluminescent element of the present invention includes the steps of: forming a barrier layer on a flexible substrate; forming a laminate by laminating, on top of the barrier layer, a pair of electrodes and an organic functional layer that has at least one light-emitting layer between the electrodes; forming a covering intermediate layer on top of the barrier layer at the periphery of the laminate; and coating a sealing resin layer and performing solid-sealing by a sealing member.

According to the organic electroluminescent element of the present invention, the covering intermediate layer is provided between the barrier layer made of the modified-polysilazane layer and the sealing resin layer. Accordingly, the lowering of the adhesion of the sealing resin layer can be suppressed, with the result that the reliability of the organic electroluminescent element is enhanced.

### Advantageous Effects of Invention

According to the present invention, an organic electroluminescent element having a high reliability can be provided.

### BRIEF DESCRIPTION OF DRAWINGS

FIG. 1 is a drawing showing a schematic configuration of the organic electroluminescent element in a first embodiment.

FIG. 2 is a drawing showing a schematic configuration of the organic electroluminescent element in a second embodiment.

FIG. 3 is a drawing showing a schematic configuration of the organic electroluminescent element in a third embodiment.

### DESCRIPTION OF EMBODIMENTS

Hereinafter, embodiments of the present invention will be explained based on the drawings in the following order.

1. Organic electroluminescent element (First embodiment)

2. Organic electroluminescent element (Second embodiment: overall covered)

3. Organic electroluminescent element (Third embodiment: two barrier layers)

4. Manufacturing method of the organic electroluminescent element (Fourth embodiment)

### 1. Organic Electroluminescent Element

### First Embodiment

Hereinafter, specific embodiments of the organic electroluminescent element (hereinafter, referred to as organic EL element) of the present invention will be explained.

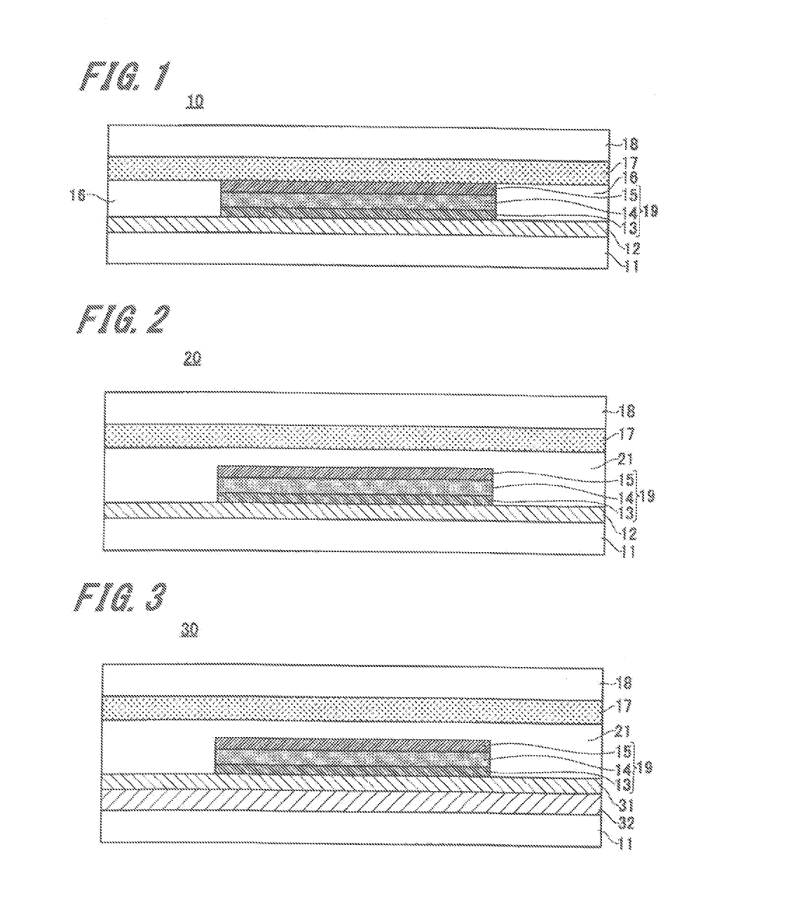

In FIG. 1, a schematic configuration view (a cross-sectional view) of the the organic EL element in the first embodiment of the present invention is shown. As shown in FIG. 1, the organic EL element 10 is provided with a substrate 11, a barrier layer 12, a first electrode 13, an organic functional layer 14, a second electrode 15, a covering intermediate layer 16, a sealing resin layer 17, and a sealing member 18.

The organic EL element 10 shown in FIG. 1 includes a laminate (hereinafter, referred to as light-emitting laminate) 19 having a configuration in which the organic functional layer 14 provided with a light-emitting layer, and the second electrode 15 serving as a cathode are laminated on the first electrode 13 serving as an anode. Among them, the first electrode 13 used as the anode is constituted as a translucent electrode. In the configuration, only the part where the organic functional layer 14 is sandwiched by the first electrode 13 and the second electrode 15 serves as a light emission region in the organic EL element 10. In addition, the organic EL element 10 is configured as a bottom emission type in which light generated is taken out at least from the side of the substrate 11.

In addition, the organic EL element 10 has a configuration in which the light-emitting laminate 19 is arranged on the substrate 11 obtained by providing the barrier layer 12, and is solid-sealed by the covering intermediate layer 16, the sealing resin layer 17 and the sealing member 18.

Namely, the organic EL element 10 includes the light-emitting laminate 19 having a configuration in which the organic functional layer 14 having least one light-emitting layer serving as a main portion for light-emission in the organic EL element 10 is sandwiched between the first electrode 13 and second electrode 15. In addition, the light-emitting laminate 19 obtained by providing the organic functional layer 14 between the pair of the first electrode 13 and second electrode 15 is covered with the covering intermediate layer 16 provided on the barrier layer 12 at the periphery of the light-emitting laminate 19 (organic functional layer 14), and the thermosetting sealing resin layer 17 which covers the light-emitting laminate 19.

According to the configuration, the sealing member 18 is joined to the substrate 11 via the sealing resin layer 17 by causing the sealing resin layer 17 to adhere to the light-emitting laminate 19 and the covering intermediate layer 16. Furthermore, there is obtained a configuration in which the sealing resin layer 17 and the barrier layer 12 do not make direct contact with each other by covering the barrier layer 12 with the covering intermediate layer 16. Moreover, the sealing resin layer 17 has a configuration of making contact with not only the covering intermediate layer 16 but also the second electrode 15.

In addition, in the organic EL element 10, at least the uppermost surface of the barrier layer 12 is constituted of the modified-polysilazaned layer. Furthermore, a material highly adhesive to the sealing resin layer 17 is used for the covering intermediate layer 16. Moreover, it is preferable to use, for the covering intermediate layer 16, a material having a high sealing property to the first electrode 13, the organic functional layer 14 and the second electrode 15 which are to be sealed.

In the configuration shown in FIG. 1, the covering intermediate layer 16 is interposed between the sealing resin layer 17 and the barrier layer 12. Accordingly, the surface adhering to the sealing resin layer 17 has a configuration of not making direct contact with the barrier layer 12 of the modified-polysilazane layer. In the configuration, even when adhesion between the barrier layer 12 made of the modified-polysilazane layer and the sealing resin layer 17 is low and thus the contact surface is likely to be peeled off, the adhesion of the sealing resin layer 17 is enhanced by interposing the covering intermediate layer 16. Therefore, it is possible to suppress the peeling-off of the sealing member 18 and the sealing resin layer 17 and to constitute the organic EL element 10 having a high reliability.

Note that, in FIG. 1, although the covering intermediate layer 16 is formed at the same thickness as that of the light-emitting laminate 19, the thickness of the covering intermediate layer 16 is not particularly limited, and the covering intermediate layer may be formed so as to cover at least the top of the barrier layer 12 around the light-emitting laminate 19, and may be particularly formed so as to cover the entire surface of the barrier layer 12. The covering intermediate layer 16 may be formed to be thinner than the light-emitting laminate 19.

In addition, for example, it is preferable that the organic functional layer 14 has a configuration of not being exposed from the covering intermediate layer 16, by forming the thickness of the covering intermediate layer 16 so as to be larger than that of the contact surface (interface) of the organic functional layer 14 and the second electrode 15 of the light-emitting laminate 19. Namely, it is preferable that the covering intermediate layer 16 is formed so that the height from the barrier layer 12 is at a position higher than the contact surface (interface) of the organic functional layer 14 and the second electrode 15.

Thereby, it is possible to prevent the components of the sealing resin layer 17, filler, and the like from making contact with the organic functional layer 14 and to suppress adverse influences on the organic functional layer 14 by the sealing resin layer 17.

Hereinafter, as to the organic EL element 10 of the exemplary embodiment, there will be described detailed configurations of the substrate 11, the barrier layer 12, the first electrode 13 and the second electrode 15, the organic functional layer 14, the covering intermediate layer 16, the sealing member 18 and the sealing resin layer 17 in this order. Note that, in the organic EL element 10 of the exemplary embodiment, translucency means that a light transmittance at a wavelength of 550 nm is 50% or more.

[Substrate]

The substrate 11 applied to the organic EL element 10 is not particularly limited as long as it is a flexible substrate which can give flexibility to the organic EL element 10. Examples of the flexible substrate can include a transparent resin film.

Examples of the resin film include, for example, polyesters such as polyethylene terephthalate (PET) and polyethylene naphthalate (PEN), polyethylene, polypropylene, cellulose esters or derivative thereof such as cellophane, cellulose diacetate, cellulose triacetate (TAC), cellulose acetate butylate, cellulose acetate propionate (CAP), cellulose acetate phthalate and cellulose nitrate, polyvinylidene chloride, polyvinyl alcohol, polyethylene vinyl alcohol, syndiotactic polystyrene, polycarbonate, norbornen resin, polymethylpenten, polyether ketone, polyimide, polyether sulphone (PES), polyphenylene sulfide, polysluphones, polyether imide, polyether ketone imide, polyamide, fluoro resin, Nylon, polymethyl methacrylate, acryl or polyallylates, cycloolefins-based resins such as Alton (commercial name of JSR) and APEL (commercial name of Mitsui Chemicals), and the like.

[Barrier Layer]

The barrier layer 12 formed of a modified-polysilazane layer is provided on the surface of the substrate 11. When the substrate 11 is made of a resin film, a coating film made of an inorganic material or an organic material, or the barrier layer 12 obtained by combining these coating films is required to be formed on the surface of the resin film. The barrier layer 12 described above preferably has a water vapor transmission rate of 0.01 g/(m²·24 hr) or less when measured in accordance with JIS-K-7129-1992 (temperature: 25±0.5° C., relative humidity: 90±2% RH). Furthermore, an oxygen transmission rate measured in accordance with JIS-K-7126-1987 is preferably 10⁻³ ml/(m²·24 h·atm) or less and a water vapor transmission rate is preferably 10⁻⁵ g/(m²·24 hr) or less.

The modified-polysilazane layer is a layer formed by subjecting the coating layer of the polysilazane-containing liquid to modification treatment. The modified layer is composed mainly of a silicon oxide or a silicon oxynitride compound.

A method for forming the polysilazane-modified layer include a method for forming a layer containing a silicon oxide or a silicon oxynitride compound, by performing a modification treatment after coating at least one coating liquid containing a polysilazane compound on a substrate.

As to the supply of a silicon oxide or a silicon oxynitride compound for forming the polysilazane-modified layer of a silicon oxide or a silicon oxynitride compound, the coating on the surface of the substrate rather than the supply as gas like in a CVD (Chemical Vapor Deposition) method makes it possible to form a more uniform and smooth layer. In the case of a CVD method and the like, it is known that unnecessary foreign substances referred to as a particle are generated in the gas phase, at the same time as the process of the vapor deposition of a raw material having an increased reactivity in the gas phase on the surface of the substrate. As the result of the accumulation of these generated particles, the smoothness of the surface deteriorates. In the coating method, the suppression of the generation of these particles becomes possible by not allowing raw materials to exist in a gas-phase reaction space. Consequently, a smooth surface can be formed through the use of the coating method.

(Coated Film of Polysilazane-Containing Liquid)

The coated film of a polysilazane-containing liquid is formed by coating a coating liquid containing a polysilazane compound at least in one layer on the substrate.

Any appropriate method may be employed as a coating method. Specific examples include a spin coat method, a roll coat method, a flow coat method, an ink jet method, a spray coat method, a print method, a dip coat method, a casting film formation method, a bar coat method, a gravure printing method etc. The thickness of the application may be set appropriately corresponding to an object. For example, the coating thickness may be set so that the thickness after drying is preferably approximately 1 nm to 100 μm, more preferably approximately 10 nm to 10 μm, and most preferably approximately 10 nm to 1 μm.

“Polysilazane” is a polymer having a silicon-nitrogen bond, and is a ceramic precursor inorganic polymer such as SiO₂, Si₃N₄ and an intermediate solid solution SiOₓN_{y} of both the substances, made of Si—N, Si—H, N—H and the like. The polysilazane is represented by a general formula (I) below.

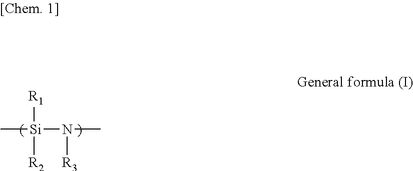

In order to perform the coating so as not to damage the substrate 11, one that is made into a ceramic at comparatively low temperatures and is modified into silica is preferable as described in Japanese Patent Laid-open No. 08-112879.

In the formula, R1, R2 and R3 each represent independently a hydrogen atom, an alkyl group, an alkenyl group, a cycloalkyl group, an aryl group, an alkylsilyl group, an alkylamimo group, an alkoxy group or the like.

From the viewpoint of denseness of a barrier film to be obtained, perhydropolysilazane in which all of R1, R2 and R3 are hydrogen atoms is particularly preferable.

On the other hand, organopolysilazane in which a part of the hydrogen portion to be bonded to Si thereof is substituted by an alkyl group or the like has the advantage that the generation of crack is suppressed even when (an average) film thickness is made larger, because adhesiveness to the substrate of the base is improved by having an alkyl group such as a methyl group and toughness can be given to a ceramic film based on hard and brittle polysilazane. The perhydropolysilazane or organopolysilazane may be selected, or these can be used in mixture, depending on use applications.

The perhydropolysilazane is presumed to have a structure in which a linear structure and a ring structure with 6- and 8-membered ring as the center exist. The molecular weight thereof is approximately 600 to 2000 (in terms of polystyrene) in number average molecular weight (Mn), and the perhydropolysilazane is a liquid or solid material and differs depending on the molecular weight. These are available in the market in a solution state dissolved in an organic solvent, and a commercially available product can be used as is, as a polysilazane-containing coating liquid.

Other examples of polysilazane changing into ceramic at low temperatures include siliconalkoxide-added polysilazane obtained by causing polysilazane represented by the general formula (I) described above to react with siliconalkoxide (Japanese Patent Laid-Open No. 05-238827), glycidol-added polysilazane obtained by causing the polysilazane to react with glycidol (for example, Japanese Patent Laid-Open No. 06-122852), alcohol-added polysilazane obtained by causing the polysilazane to react with alcohol (Japanese Patent Laid-Open No. 06-240208), metal carboxylate-added polysilazane obtained by causing the polysilazane to react with metal carboxylate (Japanese Patent Laid-Open No. 06-299118), acetylacetonate complex-added polysilazane obtained by causing the polysilazane to react with acetylacetonate complex containing a metal (Japanese Patent Laid-Open No. 06-306329), metal-fine-particle-added polysilazane obtained by adding metal fine particles (Japanese Patent Laid-Open No. 07-196986) and the like.

Organic solvents that can be used for preparing a liquid containing polysilazane include, specifically, hydrocarbon solvents such as aliphatic hydrocarbon, alicyclic hydrocarbon and aromatic hydrocarbon, halogenated hydrocarbon solvents, and ethers such as aliphatic ether and alicyclic ether. Specifically, there are hydrocarbons such as pentane, hexane, cyclohexane, toluene, xylene, Solvesso and terpene, halogenated hydrocarbons such as methylene chloride and trichloroethane, ethers such as dibutyl ether, dioxane and tetrahydrofuran. These solvents are selected in accordance with an object such as the solubility of polysilazane, vapor deposition rate or the like, and a plurality of solvents may be mixed. Note that an alcohol-based and water-containing solvent are not preferable because of reacting easily with polysilazane.

The concentration of polysilazane in the polysilazane-containing coating liquid is approximately 0.2 to 35% by mass, although the concentration differs depending on an intended silica film thickness or a pot life of the coating liquid.

The organic polysilazane may be a derivative in which a part of the hydrogen portions that is bonded to Si thereof are substituted by an alkyl group or the like. The adhesiveness to an underlying substrate is improved by having an alkyl group, particularly, a methyl group with the smallest molecular weight, toughness can be imparted to a hard and brittle silica film, and the generation of a crack is suppressed even when the film thickness is made larger.

A catalyst of amine or metal can also be added in order to accelerate the conversion to a silicon oxide compound. Specifically, AQUAMICANAX120-20, NN110, NN310, NN320, NL110A, NL120A, NL150A, NP110, NP140, SP140 and the like, all of which are manufactured by AZ ELECTRONIC MATERIALS, are included.

(Process for Forming Polysilazane-Containing Layer)

Moisture is preferably to be removed from the coating film of a polysilazane-containing liquid before the modification treatment or during the treatment. Therefore, the process is preferably separated into a first process for the purpose of removing the solvent in the polysilazane-containing layer and a subsequent second process for the purpose of removing the moisture in the polysilazane-containing layer.

In the first process, drying conditions for mainly removing the solvent can appropriately be determined by a method of a thermal treatment, and the conditions of removing the moisture at this time are also acceptable. A thermal treatment temperature is preferably high from the viewpoint of a rapid treatment, but temperature and treatment time are determined in consideration of a thermal damage to a resin substrate. For example, when a PET substrate having the glass transition temperature (Tg) of 70° C. is used as the resin substrate, the thermal treatment temperature can be set to be 200° C. or less. The treatment time is preferably set so that the solvent is to be removed, and in a short time so as to reduce a thermal damage to the substrate, and when the thermal treatment temperature is 200° C. or less, the treatment time can be set within 30 minutes.

The second process is a process for removing the moisture in the polysilazane-containing layer, and an aspect of being maintained in a low humidity environment is preferable as a method for removing the moisture. The humidity in the low humidity environment changes depending on temperatures and thus, regarding the relationship between the temperature and humidity, a preferable form is shown based on the specification of the dew-point temperature. A preferable dew-point temperature is 4 degrees or less (temperature 25 degree/humidity 25%), a more preferable dew-point temperature is −8 degrees or less (temperature 25 degree/humidity 100), and a further more preferable dew-point temperature is −31 degrees or less (temperature 25 degree/humidity 10), and the time to be maintained changes appropriately depending on the thickness of the polysilazane-containing layer. Under conditions in which the thickness of the polysilazane-containing layer is 1 μm or less, a preferable dew-point temperature is −8 degrees or less and the time to be maintained is 5 minutes or more. In addition, reduced-pressure drying may be performed so that the moisture is easily removed. The pressure in the reduced-pressure drying can be selected from a normal pressure to 0.1 MPa.

As to preferable conditions in the second process relative to the conditions in the first process, for example, when the solvent is removed at a temperature of 60 to 150° C. for a treatment time of 1 minute to 30 minutes in the first process, conditions for removing the moisture in which a dew point of 4 degrees or less and a treatment time of 5 minutes to 120 minutes can be selected in the second process. The classification of the first process and the second process can be distinguished based on the change in the dew point, and the classification can be carried out by the change in the difference of dew points of process environments by 10 degrees or more.

Even after the removal of the moisture in the second process, the polysilazane-containing layer is preferably subjected to a modification treatment while the state is maintained.

(Moisture Content of Polysilazane-Containing Layer Layer)

The moisture quantity contained in the polysilazane-containing layer can be detected in accordance with a following analytical method.

Headspace gas chromatography/mass spectrometry

Apparatus: HP6890GC/HP5973MSD

Oven: 40° C. (2 min), after that, temperature is raised to 150° C. at a rate of 10° C./min

Column: DB-624 (0.25 mmid×30 m)

Injection port: 230° C.

Detector: SIM m/z=18

HS condition: 190° C., 30 min

The moisture content in the polysilazane-containing layer is defined as a value obtained by dividing the moisture quantity obtained by the above-described analytical method, by the volume of the polysilazane-containing layer, and the content is preferably 0.1% or less in a state where the moisture has been removed in the second process. Further preferable moisture content is 0.01% or less (detection limit or less).

The removal of the moisture before the modification treatment or during the modification is a preferred aspect because a dehydration reaction of the polysilazane having converted to a silanol is accelerated.

(Modification Treatment)

A known method based on the conversion reaction of polysilazane can be selected as the modification treatment. High temperatures of 450° C. or more is required for the production of a silicon oxide film or a silicon oxynitride film by a substitution reaction of a silazane compound, and adaptation is difficult in the case of flexible substrates such as plastic. Conversion reactions using plasma, ozone or ultraviolet rays capable of a conversion reaction at lower temperatures are preferable for the adaptation for a plastic substrate.

(Plasma Treatment)

A known method can be used for a plasma treatment as the modification treatment, and an atmospheric pressure plasma treatment is preferable. In the case of the atmospheric pressure plasma treatment, nitrogen gas and/or atoms in Group XVIII in the periodic table, specifically, helium, neon, argon, krypton, xenon, radon or the like is used as a discharge gas. Among these, nitrogen, helium and argon is used preferably, and in particular, nitrogen is low in cost and preferable.

As an example of the plasma treatment, the atmospheric pressure plasma treatment will be explained. Specifically, the atmospheric pressure plasma is one, as described in International Publication No. WO 2007/026545, in which two or more electric fields of different frequencies are formed in a discharge space, and an electric field in which a first radio frequency electric field and a second radio frequency electric field are superposed is preferably formed.

In the atmospheric pressure plasma treatment, a frequency ω2 of the second radio frequency electric field is higher than a frequency ω1 of the first radio frequency electric field, the relationship among an intensity V1 of the first radio frequency electric field, an intensity V2 of the second radio frequency electric field and an intensity IV of an discharge starting electric field satisfies

V1≦IV>V2 or V1>IV≧V2

and the output density of the second radio frequency electric field is 1 W/cm² or more.

For example, even in the case of discharge gas having a high discharge starting electric field intensity such as nitrogen gas, it is possible to start discharge, to maintain a plasma state with high density and stability, and to form a thin film of high performance, by adopting such discharge conditions.

According to the above measurement, when setting nitrogen gas as a discharge gas, the discharge starting electric field intensity IV (½Vp−p) is approximately 3.7 kV/mm, and accordingly, in the above-described relationship, it is possible to excite the nitrogen gas and to make the nitrogen gas into a plasma state, by applying a first applied electric field intensity as V1≧3.7 kV/mm.

Here, as to the frequency of a first power source, 200 kHz or less can be used preferably. In addition, as to the waveform of the electric field, both a continuous wave and a pulse wave are usable. The lower limit is desirably approximately 1 kHz.

On the other hand, as the frequency of a second power source, 800 kHz or more can be used preferably. A higher frequency of the second power source gives a higher plasma density to thereby give a dense and high-quality thin film. The upper limit is desirably approximately 200 kHz.

The formation of radio frequency electric fields from such two power sources is necessary for starting discharge of a discharge gas having a high discharge starting electric field intensity by the first radio frequency electric field, and the plasma density can be made high and a dense and high-quality thin film can be formed by a high frequency and high output density of the second radio frequency electric field.

(Ultraviolet Ray Irradiation Treatment)

A treatment by ultraviolet ray irradiation is also preferable as the modification treatment. Ozone and active oxygen atoms generated by ultraviolet ray (the same meaning as ultraviolet light) has a high oxidation capability, and a silicon oxide film or a silicon oxynitride film having high denseness and insulation performance at low temperatures can be produced.

The substrate is heated by the ultraviolet ray irradiation, and O₂ and H₂O contributing to ceramic formation (silica conversion), an ultraviolet absorber, and the polysilazane itself are excited and activated, and thus the excitation of the polysilazane accelerates the ceramic formation of the polysilazane, and the obtained ceramic film becomes dense. The ultraviolet ray irradiation may be effectively carried out at any time even after formation of the coated film.

The method according to the present embodiment may be used in any commonly used ultraviolet ray generation apparatus.

Note that, in the present example, “ultraviolet ray” generally means an electromagnetic wave having a wavelength of 10 to 400 nm, and in the case of the ultraviolet ray irradiation treatment except for a vacuum ultraviolet ray (10 to 200 nm) treatment to be described later, preferably ultraviolet rays of 210 to 350 nm are used.

In the ultraviolet ray irradiation, an irradiation intensity and irradiation time are set within a range not damaging the substrate holding a coated film to be irradiated.

When taking, as an example, the case where a plastic film is used as the substrate, it is possible to set the distance between the substrate—lamp so that the intensity on the substrate surface becomes 20 to 300 mW/cm², preferably 50 to 200 mW/cm² for 0.1 sec to 10 min by, for example, using a lamp of 2 kW (80 W/cm×25 cm), and to perform the irradiation for 0.1 sec to 10 min.

Generally, when the substrate temperature at the time of the ultraviolet ray irradiation treatment becomes 150° C. or more, damage of the substrate such as the deformation or strength degradation of the substrate is carried out in the case of a plastic film or the like. However, in the case of a film having high heat resistance such as polyimide and a substrate of metal or the like, a treatment at higher temperatures is possible. Accordingly, there is no general upper limit on the substrate temperature at the time of the ultraviolet ray irradiation, and a person skilled in the art can suitably set the substrate temperature depending on kinds of the substrates. Furthermore, an ultraviolet ray irradiation atmosphere is not particularly limited and the ultraviolet ray irradiation may be performed in the air.

Examples of generation methods of the ultraviolet ray include metal halide lamp, high-pressure mercury vapor lamp, low-pressure mercury vapor lamp, xenon arc lamp, carbon arc lamp, excimer lamp (single wavelength of 172 nm, 222 nm, 308 nm, for example, manufactured by Ushio, Inc.), UV lasers, and the like, but the generation methods are not particularly limited. Furthermore, in irradiating a polysilazane coated film with the generated ultraviolet ray, the coated film is desirably irradiated with the ultraviolet ray from a generation source, reflected from a reflection plate, also in order to achieve uniform irradiation for improving the efficiency.

The ultraviolet ray irradiation is applicable to both a batch treatment and a continuous treatment, and an appropriate selection is possible depending on shapes of coated substrates. For example, in the case of a batch treatment, a substrate having a polysilazane-coated film on the surface (for example, silicon wafer) can be treated with a burning furnace provided with the ultraviolet ray generation source. The ultraviolet ray burning furnace itself is generally known, and for example, one manufactured by EYE GRAPHICS CO., LTD. can be used. Furthermore, when a substrate having a polysilazane-coated film on the surface is in a shape of long film, the formation into ceramic can be performed by a drying zone provided with such ultraviolet ray generation source as described above continuously irradiating the long film with ultraviolet rays while conveying the long film. A time period necessary for the ultraviolet ray irradiation is generally from 0.1 sec to 10 min, preferably 0.5 sec to 3 min, although the time period depends on a substrate to be coated, a composition or concentration of the coating composition.

(Vacuum Ultraviolet Ray Irradiation Treatment; Excimer Irradiation Treatment)

In the present embodiment, a treatment by vacuum ultraviolet ray irradiation is included as a way of a further preferable modification treatment. The treatment by vacuum ultraviolet ray irradiation is a method in which, through the use of an optical energy of 100 to 200 nm lager than the inter-atomic bonding strength in the silicon compound, preferably, through the use of an energy of light having a wavelength of 100 to 180 nm, a silicon oxide film is formed at relatively low temperatures by advancing an oxidation reaction using active oxygen or ozone while directly cutting the bonding of atoms by an action only of photons referred to as a photon process.

An inert gas excimer lamp is preferably used as a vacuum ultraviolet light source necessary for this.

(Excimer Light Emission)

A rare gas atom such as Xe, Kr, Ar, or Ne does not form a molecule through chemical bonding, such a rare gas is referred to as an inert gas. However, atoms of an inert gas having obtained an energy by discharge or the like (excited atom) can be bonded to another atom to thereby form a molecule. When an inert gas is xenon, the reaction is as follows:

e+Xe→e+Xe*

Xe*+Xe+Xe→Xe²*+Xe

and when Xe²* being an excited excimer molecule transitions to the ground state, it emits excimer light of 172 nm. The characteristics of an excimer lamp include having a high efficiency because the emission is concentrated on one wavelength and light other than required light is almost not emitted.

Furthermore, since no excessive light is emitted, the temperature of an object can be kept low. Moreover, since much time is not required for starting and re-starting, instantaneous lighting and blinking are possible.

A method of using dielectric barrier discharge is known in order to obtain excimer emission. The dielectric barrier discharge is discharge referred to as micro discharge that is generated in the gas space, by providing a gas space between both electrodes via a dielectric substance (transparent quartz in the case of an excimer lamp) and applying a high-frequency high voltage of several 10 kHz to the electrode, and that is like very thin thunder. When the streamer of the micro discharge reaches a tube wall (dielectric substance), charges accumulate on the surface of the dielectric substance, and thus the micro discharge is extinguished. In this way, the dielectric barrier discharge is discharge in which the micro discharge spreads over the whole of the tube wall and repeats the generation and extinction. Therefore, flickering of the light that can be recognized with the naked eye arises. Additionally, since streamer at a very high temperature reaches locally and directly the tube wall, deterioration of the tube wall may be accelerated.

Electrodeless electric field discharge is also possible in addition to the dielectric barrier discharge, as a method for effectively obtaining excimer emission. The electrodeless electric field discharge is one based on capacitive coupling and is referred to as RF discharge as a byname. Basically, the same lamp and electrode and the arrangement thereof as those in the dielectric barrier discharge are acceptable, and radio frequency to be applied to both electrodes is lit at several MHz. In the electrodeless electric field discharge, since spatially and temporally uniform discharge is obtained as described above, a lamp free of flickering of light and has a long life time can be obtained.

In the case of the dielectric barrier discharge, since the micro discharge is generated only between electrodes, an outside electrode covers the whole outer surface and has to be one that allows light to pass through for the purpose of extracting the light to the outside, in order to generate discharge in the whole discharge space. For that purpose, an electrode obtained by forming a thin metal into a net-like shape is used. Since a wire as thin as possible is used for the electrode so as not to shield light, the electrode is easily damaged by ozone and the like generated by vacuum ultraviolet light, in an oxygen atmosphere.

In order to prevent this, there is generated the necessity of setting the circumference of the lamp, namely, the inside of the irradiation apparatus to be an atmosphere of inert gas such as nitrogen and of providing a window of synthesized quartz to extract irradiation right.

The window of synthesized quartz is not only an expensive consumable article, but also generates loss of light.

Since a double cylindrical type lamp has an outer diameter of approximately 25 mm, the difference in distances to an irradiation surface between directly below a lamp axis and a lamp side surface cannot be neglected and a large difference in illuminance arises. Accordingly, even if lamps are aligned in close contact, uniform illuminance distribution cannot be obtained. When an irradiation apparatus provided with a window of synthesized quartz is used, the distance in an oxygen atmosphere can be made uniform and uniform illuminance distribution is obtained.

In the case where the electrodeless electric field discharge is used, the outside electrode is not required to be in a net shape. Glow discharge spreads over the whole discharge space only by providing the outside electrode on a part of the lamp outer surface. An electrode usually formed of an aluminum block and doubling also as a reflection plate of light is used as the outside electrode on the rear face of the lamp. However, since the lamp outer diameter is large as in the case for the dielectric barrier discharge, synthesized quartz becomes necessary in order to make the illumination distribution uniform.

The greatest feature of a thin tube excimer lamp is a simple structure thereof. The structure is only such that both ends of a quartz tube are closed and gas for performing excimer emission is sealed inside. Accordingly, a very inexpensive light source can be provided.

In the double cylindrical type lamp, since processing of connecting and closing the both ends of inner and outer tubes has been performed, the lamp tends to be damaged in handling or transportation as compared with the thin tube lamp. Furthermore, the outer diameter of the tube of the thin tube lamp is approximately 6 to 12 mm, and when the tube is too thick, a high voltage is required for the starting.

The form of discharge can be used for both the dielectric barrier discharge and the electrodeless electric field discharge. As to the shape of the electrode, the plane to be in contact with a lamp may be flat, but when the shape is made in accordance with a curved plane of the lamp, discharge is made more stable since the lamp can be firmly fixed firmly and the electrode closely adheres to the lamp. In addition, when the curved surface is made into a mirror surface by using aluminum, the curved surface also serves as a reflection plate of light.

A xenon excimer lamp emits an ultraviolet ray having a short wavelength of 172 nm at a single wavelength, and is excellent in emission efficiency. Since the light represents a large absorption coefficient for oxygen, the light can generate radical oxygen atom species or ozone with a small amount of oxygen. Furthermore, it is known that the energy of light of short wavelength of 172 nm that dissociates the bonding of an organic material has high performance. The modification of the polysilazane-containing layer can be realized in a short period of time, by the active oxygen or ozone, and a high energy of the ultraviolet ray irradiation. Accordingly, as compared with a low-pressure mercury vapor lamp that emits wavelengths of 185 nm and 254 nm, and plasma cleaning, it is made possible to shorten a process time along high throughput, reduce the area of facilities, and to irradiate an organic material, a plastic substrate and the like which are susceptible to damage by heat.

The excimer lamp has high light generation efficiency, and thus can be lit by inputting low electric power. Furthermore, the excimer lamp is characterized in that the increase in the surface temperature of an irradiation object is suppressed since light of a long wavelength that is a cause of temperature rise by light is not emitted and since irradiation with energy having a single wavelength in an ultraviolet ray region is performed. Therefore, the excimer lamp is suitable for a flexible film material such as PET that is considered to be susceptible to the influence of heat.

In addition to the above modified-polysilazane layer, there can be used silicon oxide, silicon dioxide, silicon nitride, and the like as the material for forming the barrier layer 12. Furthermore, in order to improve the fragility of the barrier film, it is more preferable to impart a lamination structure of these inorganic layers and layers made of organic material (organic layers). The lamination order of the inorganic layers and the organic layers is not particularly limited, and it is preferable to alternately laminate the both layers a plurality of times.

Furthermore, the method for forming these layers is not particularly limited, and there can be used, for example, a vacuum vapor deposition method, a spattering method, a reactive spattering method, a molecular beam epitaxy method, a cluster ion beam method, an ion plating method, a plasma polymerization method, an atmospheric plasma polymerization method, a plasma CVD method, a laser CVD method, a thermal CVD method, a coating method, and the like. Particularly, the atmospheric plasma discharge polymerization method described in Japanese Patent Laid-Open No. 2004-68143 can be preferably used.

[First Electrode (Anode Side), Second Electrode (Cathode Side)]

(First Electrode)

In the organic EL element 10, the first electrode 13 substantially serves as an anode. The organic EL element 10 is an element of bottom emission type in which the light is taken out from the substrate 11 side through the first electrode 13. Therefore, the first electrode 13 is required to be formed by a translucent electric conductive layer.

The first electrode 13 is, for example, a layer constituted by containing silver as a main component, and a layer constituted by using silver or an alloy containing silver as a main component. The formation method of the first electrode 13 includes: a method of using a wet process such as an applying method, an inkjet method, a coating method or a dipping method; a method of using a dry process such as a vapor deposition method (resist heating, EB method, or the like), a sputtering method or a CVD method; and the like. Among them, the vapor deposition method is preferably applied.

Examples of the alloy containing silver (Ag) as a main component constituting the first electrode 13 include silver magnesium (AgMg), silver copper (AgCu), silver palladium (AgPd), silver palladium copper (AgPdCu), silver indium (AgIn), and the like.

The above-described first electrode 13 may be a laminated structure where a plural of the layer of silver or the alloy of silver as a main component is laminated, as necessary, in a separated manner.

Furthermore, the first electrode 13 preferably has a thickness of the range of 3 to 15 nm. When the thickness is 15 nm or less, it is preferable because an absorption component and a reflection component in the layer may be suppressed low to thereby maintain the light transmittance of the first electrode 13. In addition, when the thickness is 3 nm or more, the electric conductivity of the layer is ensured.

Note that, as to the above first electrode 13, the upper portion may be covered with a protective film, or may be laminated with other electrically conductive layer. In this case, the protective film and the electrically conductive layer preferably have light transmittance so as not to impair its light transmittance of the organic EL element 10.

In addition, the configuration may be such that necessary a layer as needed is provided at the lower portion of the first electrode 13, namely, also between the barrier layer 12 and the first electrode 13. For example, an underlayer for enhancing the performances of the first electrode 13 or for facilitating the formation may be formed.

Furthermore, the first electrode 13 may have a configuration other than the above configuration of containing silver as a main component. For example, any transparent electrically conductive substance thin film such as other metal or an alloy thereof, ITO, zinc oxide, or tin oxide may be used.

(Second Electrode)

The second electrode 15 is an electrode layer which functions as a cathode for supplying an electron to the organic functional layer 14, and is composed of a metal, an alloy, an electrically conductive organic or inorganic compound, and a mixture thereof. Specific examples include gold, aluminum, silver, magnesium, lithium, magnesium/copper mixture, magnesium/silver mixture, magnesium/aluminum mixture, magnesium/indium mixture, indium, lithium/aluminum mixture, a rare earth metal, ITO, ZnO, TiO₂, SnO₂, and the like.

The second electrode 15 can be formed from an electrically conductive material by the vapor deposition method or the sputtering method, and the like. In addition, the sheet resistance of the second electrode 15 is preferably several hundreds Ω/sq. or less, and a thickness is usually selected from the range of 5 nm to 5 μm, preferably 5 nm to 200 nm.

Note that, when the organic EL element 10 is a both side emitting type in which light is also taken out the emitted light from the second electrode 15 side, the second electrode 15 is configured by selecting an electrically conductive material having a good light transmittance from the above-described electrically conductive materials.

[Nitrogen-Containing Layer]

When the above first electrode 13 is constituted by using silver or an alloy having silver as a main component, it is preferable to form the following nitrogen-containing organic compound layer, as the under coating layer of the first electrode 13. Hereinafter, the nitrogen-containing organic compound layer will be explained as a nitrogen-containing layer.

The nitrogen-containing layer is a layer provided adjacent to the first electrode 13, and constituted using a compound including nitrogen atoms (N). A film thickness of the nitrogen-containing layer is 1 μm or less, preferably 100 nm or less. Additionally, as an example, an unshared electron pair of a nitrogen atom that is stably bonded to the silver being a main material configuring the first electrode 13 among the nitrogen atoms contained in the compound is referred to as an [effective unshared electron pair], and the compound particularly has a content ratio of the [effective unshared electron pair] within a prescribed range.

Here, the “effective unshared electron pair” is defined as an unshared electron pair that is not involved in aromaticity and is not coordinated to a metal, among unshared electron pairs of a nitrogen atom contained in a compound. Here, the aromaticity means an unsaturated ring structure in which atoms having a it electron are laid in a ring shape, and the aromaticity follows the so-called “Huckel's rule” which requires a condition in which the number of electrons contained in the it electron system on the ring is “4n+2” (n=0, or a natural number).

The “effective unshared electron pair” as described above is selected based on whether or not the unshared electron pair of a nitrogen atom is involved in the aromaticity irrespective of whether or not the nitrogen atom itself including the unshared electron pair is a hetero atom constituting the aromatic ring. For example, even if a certain nitrogen atom is a hetero atom constituting an aromatic ring, when the nitrogen atom has an unshared electron pair that is not involved in the aromaticity, the unshared electron pair is counted as one of “effective unshared electron pairs.” In contrast, even in the case where a certain nitrogen atom is not a hetero atom constituting an aromatic ring, if all the unshared electron pairs of the nitrogen atom are involved in the aromaticity, the unshared electron pairs of the nitrogen atom are not counted as the “effective unshared electron pair.” Note that, in respective compounds, the number n of the “effective unshared electron pair” coincides with the number of the nitrogen atoms having the “effective unshared electron pair.”

Particularly in the present embodiment, the number n of the “effective unshared electron pair” relative to the molecular weight M of such a compound is defined as, for example, an effective unshared electron pair content ratio [n/M]. The nitrogen-containing layer is characterized by being constituted using a compound that is selected so that the [n/M] is 2.0×10⁻³≦[n/M]. Furthermore, the nitrogen-containing layer is more preferable when the effective unshared electron pair content ratio [n/M] defined as described above is within the range of 3.9×10⁻³≦[n/M].

Furthermore, it is sufficient that the nitrogen-containing layer is constituted using a compound whose effective unshared electron pair content ratio [n/M] is within the above-described prescribed range, that the layer is also constituted only of such a compound, or that the layer is constituted mixing such a compound and another compound for use. Another compound may or may not contain a nitrogen atom, and furthermore, the effective unshared electron pair content ratio [n/M] may not be within the prescribed range.

When the nitrogen-containing layer is constituted using a plurality of compounds, for example, the molecular weight M of the mixed compound obtained by mixing these compounds is obtained based on the mixing ratio of the compounds, and the total number n of “effective unshared electron pairs” relative to the molecular weight M is obtained as an average value of the effective unshared electron pair content ratio [n/M]. The value is preferably within the prescribed range. Namely, the effective unshared electron pair content ratio [n/M] of the nitrogen-containing layer itself is preferably within the prescribed range.

Note that, in the case where the nitrogen-containing layer is constituted using a plurality of compounds and has a configuration different in the mixing ratio (content ratio) of compounds in the thickness direction, it is sufficient that the effective unshared electron pair content ratio [n/M] in the surface layer of the nitrogen-containing layer on the side in contact with the first electrode 13 is within the prescribed range.

[Compound-1]

Hereinafter, specific examples of compounds (No. 1 to No. 45), which satisfy that the effective unshared electron pair content ratio [n/M] is 2.0×10⁻³≦[n/M], will be shown as compounds constituting the nitrogen-containing layer. In respective compounds of No. 1 to No. 45, ∘ is given to a nitrogen atom having the “effective unshared electron pair.” In addition, in the Table 1 below, molecular weights M of these compounds of No. 1 to No. 45, numbers n of the “effective unshared electron pair,” and effective unshared electron pair content ratios [n/M] are shown. In copper phthalocyanine of a compound No. 33 below, unshared electron pairs not coordinated to the copper, among unshared electron pairs of a nitrogen atom, are counted as the effective unshared electron pair.

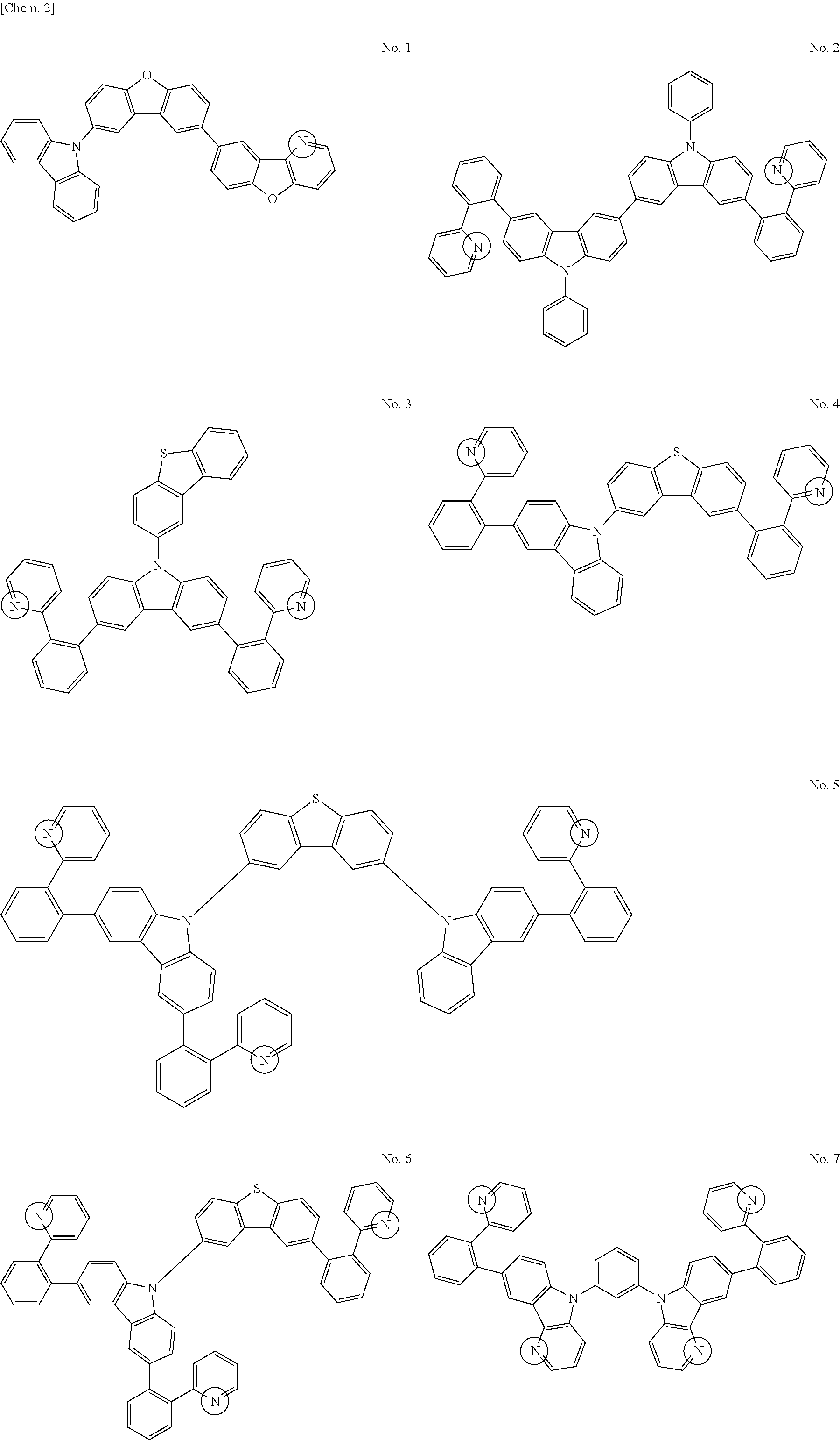

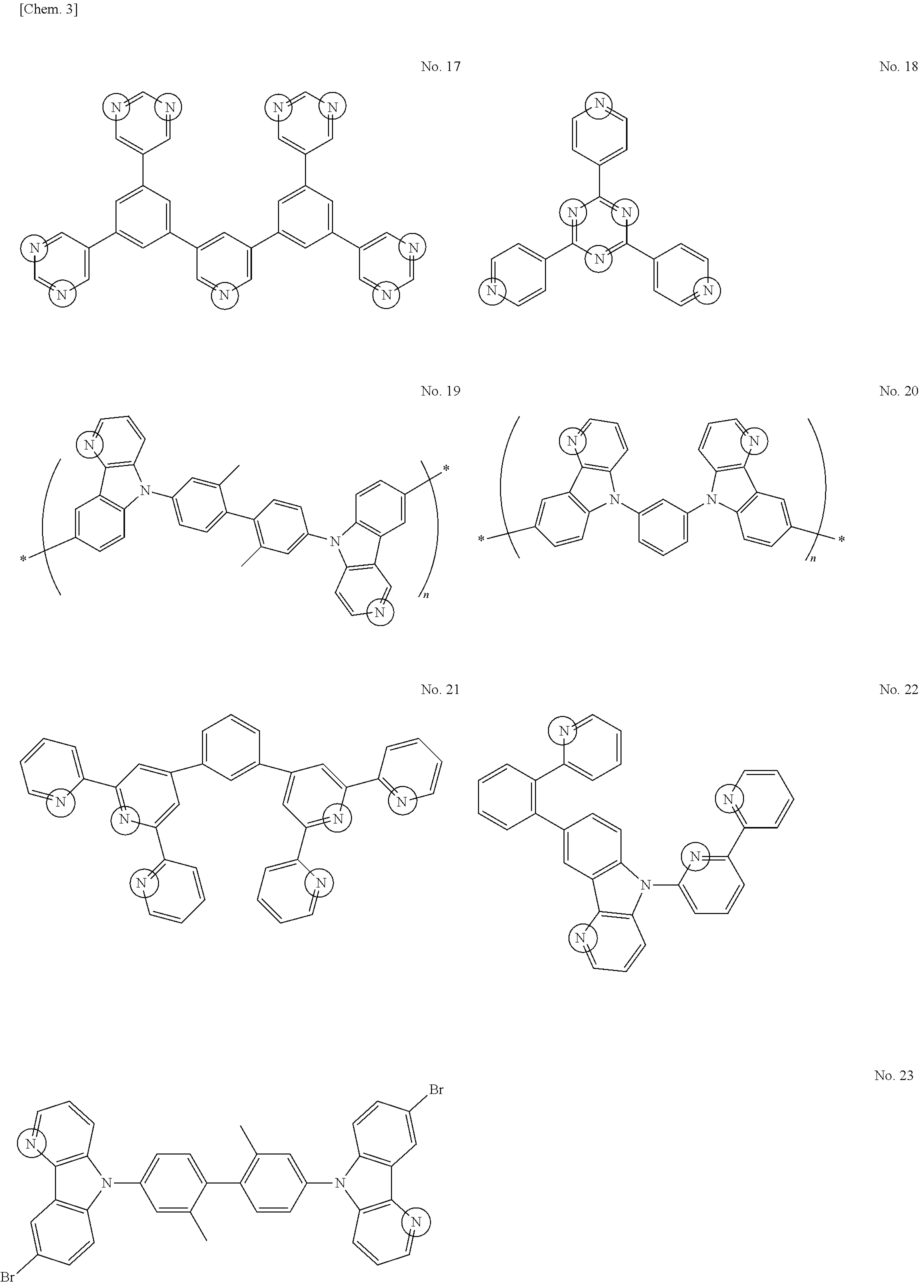

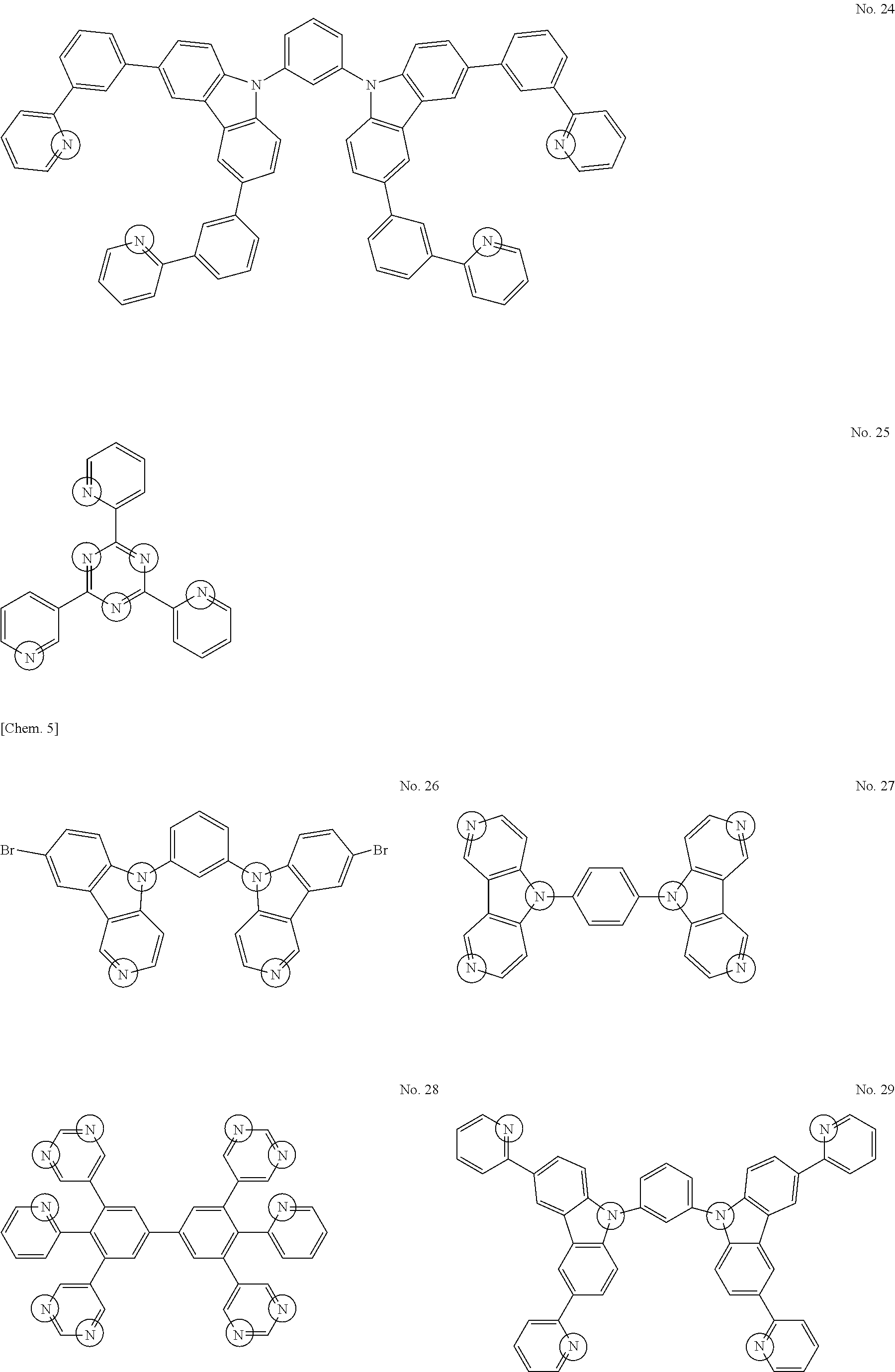 [SMILES: c1ccc(-c2cccc(-c3ccc4c(c3)c3cc(-c5cccc(-c6ccccn6)c5)ccc3n4-c3cccc(-n4c5ccc(-c6cccc(-c7ccccn7)c6)cc5c5cc(-c6cccc(-c7ccccn7)c6)ccc54)c3)c2)nc1 ; c1ccc(-c2nc(-c3cccnc3)nc(-c3ccccn3)n2)nc1 ; Brc1ccc2c(c1)c1cnccc1n2-c1cccc(-n2c3ccncc3c3cc(Br)ccc32)c1 ; c1cc2c(cn1)c1cnccc1n2-c1ccc(-n2c3ccncc3c3cnccc32)cc1 ; c1ccc(-c2c(-c3cncnc3)cc(-c3cc(-c4cncnc4)c(-c4ccccn4)c(-c4cncnc4)c3)cc2-c2cncnc2)nc1 ; c1ccc(-c2ccc3c(c2)c2cc(-c4ccccn4)ccc2n3-c2cccc(-n3c4ccc(-c5ccccn5)cc4c4cc(-c5ccccn5)ccc43)c2)nc1]

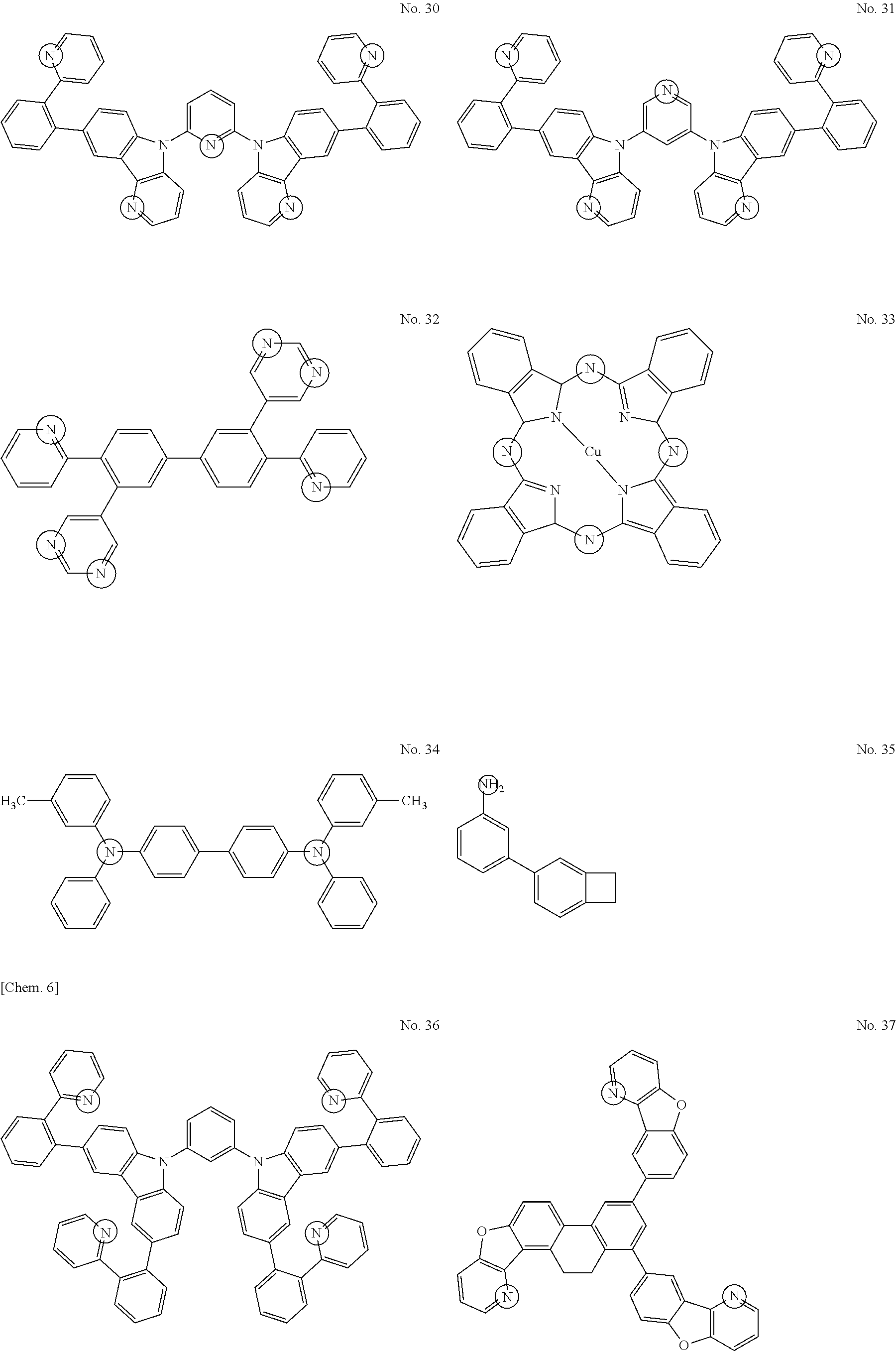

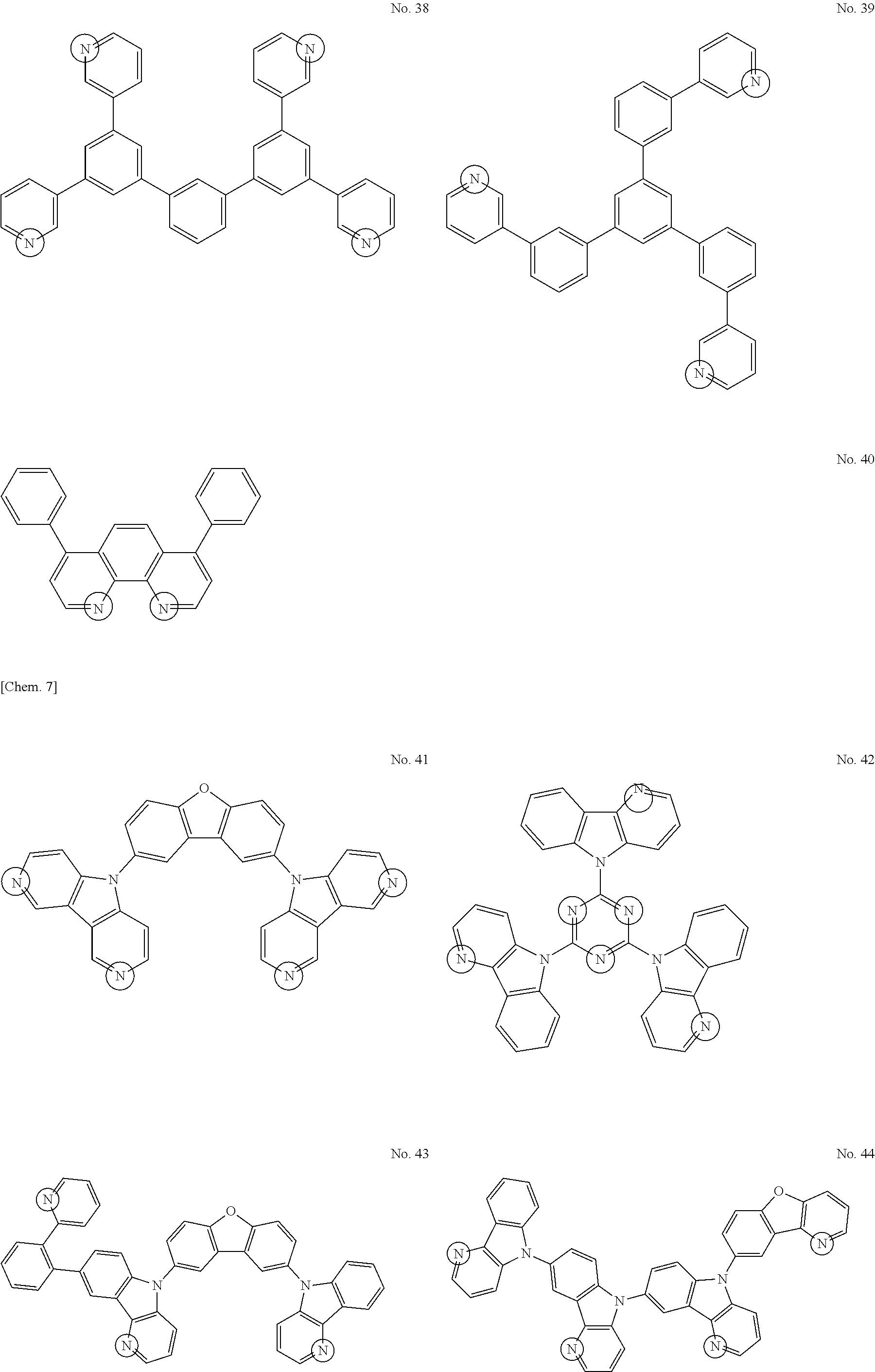

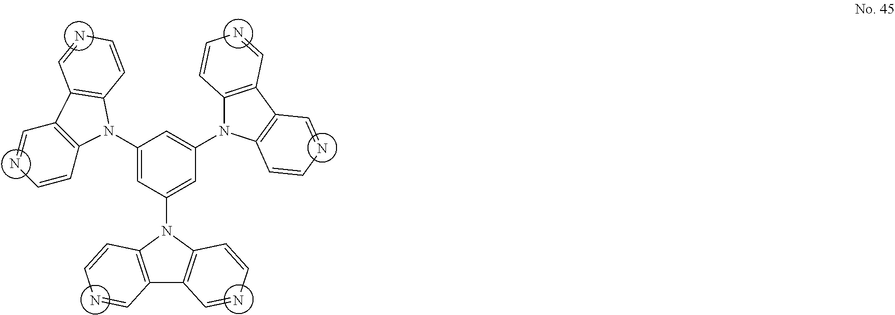 [SMILES: c1cc2c(cn1)c1cnccc1n2-c1cc(-n2c3ccncc3c3cnccc32)cc(-n2c3ccncc3c3cnccc32)c1]

TABLE 1

| | Effective | Molecular | | Corresponding |
|---|---|---|---|---|
| | unshared | weight | | general |
| Compound | electron pair [n] | [M] | [n/M] | formula |
| No. 1 | 1 | 500.55 | 2.0E−03 | (1b) |
| No. 2 | 2 | 790.95 | 2.5E−03 | |
| No. 3 | 2 | 655.81 | 3.0E−03 | |
| No. 4 | 2 | 655.81 | 3.0E−03 | |
| No. 5 | 3 | 974.18 | 3.1E−03 | (2) |
| No. 6 | 3 | 808.99 | 3.7E−03 | |
| No. 7 | 4 | 716.83 | 5.6E−03 | (1a-1), (2) |
| No. 8 | 6 | 1036.19 | 5.8E−03 | (1a-1), (4) |
| No. 9 | 4 | 551.64 | 7.3E−03 | |
| No. 10 | 4 | 516.60 | 7.7E−03 | (1a-2), (3) |
| No. 11 | 5 | 539.63 | 9.3E−03 | |
| No. 12 | 6 | 646.76 | 9.3E−03 | (5) |
| No. 13 | 4 | 412.45 | 9.7E−03 | (1a-2), (3) |
| No. 14 | 6 | 616.71 | 9.7E−03 | (5) |
| No. 15 | 5 | 463.53 | 1.1E−02 | (2) |
| No. 16 | 6 | 540.62 | 1.1E−02 | (6) |
| No. 17 | 9 | 543.58 | 1.7E−02 | |
| No. 18 | 6 | 312.33 | 1.9E−02 | |
| No. 19 | 2 | 512.60 | 3.9E−03 | (1a-1) |
| No. 20 | 2 | 408.45 | 4.9E−03 | (1a-1) |
| No. 21 | 6 | 540.62 | 1.1E−02 | (6) |
| No. 22 | 4 | 475.54 | 8.4E−03 | (1a-1) |
| No. 23 | 2 | 672.41 | 3.0E−03 | (1a-1) |
| No. 24 | 4 | 1021.21 | 3.9E−03 | |
| No. 25 | 6 | 312.33 | 1.9E−02 | (6) |
| No. 26 | 4 | 568.26 | 7.0E−03 | (1a) |
| No. 27 | 4 | 412.45 | 9.7E−03 | (1a-2), (3) |
| No. 28 | 10 | 620.66 | 1.6E−02 | (5) |
| No. 29 | 4 | 716.83 | 5.6E−03 | |
| No. 30 | 5 | 717.82 | 7.0E−03 | (1a-1), (2) |
| No. 31 | 5 | 717.82 | 7.0E−03 | (1a-1), (2) |
| No. 32 | 6 | 464.52 | 1.3E−02 | |
| No. 33 | 4 | 576.10 | 6.9E−03 | |
| No. 34 | 2 | 516.67 | 3.9E−03 | |
| No. 35 | 1 | 195.26 | 5.1E−03 | |
| No. 36 | 4 | 1021.21 | 3.9E−03 | (2) |
| No. 37 | 3 | 579.60 | 5.2E−03 | (1b) |
| No. 38 | 4 | 538.64 | 7.4E−03 | |
| No. 39 | 3 | 537.65 | 5.6E−03 | |
| No. 40 | 2 | 332.40 | 6.0E−03 | |
| No. 41 | 4 | 502.15 | 8.0E−03 | (1a-2), (3) |
| No. 42 | 6 | 579.19 | 1.0E−02 | (1a-1) |
| No. 43 | 3 | 653.22 | 4.6E−03 | (1a-1) |
| No. 44 | 4 | 667.21 | 6.0E−03 | (1a-1), (1b) |
| No. 45 | 6 | 579.19 | 1.0E−02 | (1a-2), (3) |

In the above Table 1, when those exemplified compounds are also involved in the general formulae (1) to (6) which represent other compounds explained herein below, the corresponding general formulae are indicated.

(Compound-2)

In addition, as the compound constituting the nitrogen-containing layer, other than the above compound having the effective unshared electron pair content [n/M] of the above-described predetermined range, compounds having properties to be required for each of the electronic devices to which the nitrogen-containing layer is applied are used. For example, in case of being used for an electrode of an organic electroluminescent element, the following compounds represented by the general formulae such as (1) to (6) are used as the compound constituting the nitrogen-containing layer from the viewpoints of film formation.

Among these compounds represented by the general formulae such as (1) to (6), a compound which falls within the above-described range of the effective unshared electron pair content [n/M] is included, and such a compound can be used alone as the compound constituting the nitrogen-containing layer (See Table 1). On the other hand, if a compound represented by the general formulae such as (1) to (6) does not fall within the above-described range of the effective unshared electron pair content [n/M], the compound is preferably used as the compound constituting the nitrogen-containing layer by mixing with the compound having the above-described range of the effective unshared electron pair content [n/M].

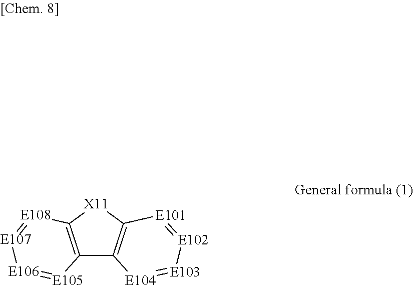

In the above general formula (1), X11 represents —N(R11)- or —O—. Additionally, in the general formula (1), E101 to E108 each represent —C(R12)= or —N═; and at least one of E101 to E108 is —N═. The above-described R11 and the above-described R12 each represent a hydrogen atom (H) or a substituent.

Examples of the substituent include an alkyl group (for example, methyl group, ethyl group, propyl group, isopropyl group, tert-butyl group, pentyl group, hexyl group, octyl group, dodecyl group, tridecyl group, tetradecyl group, pentadecyl group and the like), a cycloalkyl group (for example, cyclopentyl group, cyclohexyl group and the like), an alkenyl group (for example, vinyl group, allyl group and the like), an alkynyl group (for example, ethynyl group, propargyl group and the like), an aromatic hydrocarbon group (also referred to as an aromatic carbon ring group, an aryl group or the like, for example; phenyl group, p-chlorophenyl group, mesityl group, tolyl group, xylyl group, naphthyl group, anthryl group, azulenyl group, acenaphthenyl group, fluorenyl group, phenanthryl group, indenyl group, pyrenyl group, biphenyryl group and the like), an aromatic heterocyclic group (for example, furyl group, thienyl group, pyridyl group, pyridazinyl group, pyrimidinyl group, pyrazinyl group, triazinyl group, imidazolyl group, pyrazolyl group, thiazolyl group, quinazolinyl group, carbazolyl group, carbolinyl group, diazacarbazolyl group (a group in which one of arbitrary carbon atoms constituting the carboline ring of the above-described carbolinyl group is substituted with a nitrogen atom), phtharazinyl group and the like), a heterocyclic group (for example, pyrrolidyl group, imidazolidyl group, morpholyl group, oxazolidyl group and the like), an alkoxy group (for example, methoxy group, ethoxy group, propyloxy group, pentyloxy group, hexyloxy group, octyloxy group, dodecyloxy group and the like), a cycloalkoxy group (for example, cyclopentyloxy group, cyclohexyloxy group and the like), an aryloxy group (for example, phenoxy group, naphthyloxy group and the like), an alkylthio group (for example, methylthio group, ethylthio group, propylthio group, pentylthio group, hexylthio group, octylthio group, dodecylthio group and the like), a cycloalkylthio group (for example, cyclopentylthio group, cyclohexylthio group and the like), an arylthio group (for example, phenylthio group, naphthylthio group and the like), an alkoxycarbonyl group (for example, methyloxycarbonyl group, ethyloxycarbonyl group, butyloxycarbonyl group, octyloxycarbonyl group, dodecyloxycarbonyl group and the like), an aryloxycarbonyl group (for example, phenyloxycarbonyl group, naphthyloxycarbonyl group and the like), a sulfamoyl group (for example, aminosulfonyl group, methylaminosulfonyl group, dimethylaminosulfonyl group, butylaminosulfonyl group, hexylaminosulfonyl group, cyclohexylaminosulfonyl group, octylaminosulfonyl group, dodecylaminosulfonyl group, phenylaminosulfonyl group, naphthylaminosulfonyl group, 2-pyridylaminosulfonyl group and the like), an acyl group (for example, acetyl group, ethylcarbonyl group, propylcarbonyl group, pentylcarbonyl group, cyclohexylcarbonyl group, octylcarbonyl group, 2-ethylhexylcarbonyl group, dodecylcarbonyl group, phenylcarbonyl group, naphthylcarbonyl group, pyridylcarbonyl group and the like), an acyloxy group (for example, acetyloxy group, ethylcarbonyloxy group, butylcarbonyloxy group, octylcarbonyloxy group, dodecylcarbonyloxy group, phenylcarbonyloxy group and the like), an amido group (for example, methylcarbonylamino group, ethylcarbonylamino group, dimethylcarbonylamino group, propylcarbonylamino group, pentylcarbonylamino group, cyclohexylcarbonylamino group, 2-ethylhexylcarbonylamino group, octylcarbonylamino group, dodecylcarbonylamino group, phenylcarbonylamino group, naphthylcarbonylamino group and the like), a carbamoyl group (for example, aminocarbonyl group, methylaminocarbonyl group, dimethylaminocarbonyl group, propylaminocarbonyl group, pentylaminocarbonyl group, cyclohexylaminocarbonyl group, octylaminocarbonyl group, 2-ethylhexylaminocarbonyl group, dodecylaminocarbonyl group, phenylaminocarbonyl group, naphthylaminocarbonyl group, 2-pyridylaminocarbonyl group and the like), an ureido group (for example, methylureido group, ethylureido group, pentylureido group, cyclohexylureido group, octylureido group, dodecylureido group, phenylureido group, naphthylureido group, 2-pyridylaminoureido group and the like), a sulfinyl group (for example, methylsulfinyl group, ethylsulfinyl group, butylsulfinyl group, cyclohexylsulfinyl group, 2-ethylhexylsulfinyl group, dodecylsulfinyl group, phenylsulfinyl group, naphthylsulfinyl group, 2-pyridylsulfinyl group and the like), an alkylsulfonyl group (for example, methylsulfonyl group, ethylsulfonyl group, butylsulfonyl group, cyclohexylsulfonyl group, 2-ethylhexylsulfonyl group, dodecylsulfonyl group and the like), an arylsulfonyl group or a heteroarylsulfonyl group (for example, phenylsulfonyl group, naphthylsulfonyl group, 2-pyridylsulfonyl group and the like), an amino group (for example, amino group, ethylamino group, dimethylamino group, butylamino group, cyclopentylamino group, 2-ethylhexylamino group, dodecylamino group, anilino group, naphthylamino group, 2-pyridylamino group, piperidyl group (also referred to as piperidinyl group), 2,2,6,6-tetramethylpiperidinyl group and the like), a halogen atom (for example, fluorine atom, chlorine atom, bromine atom and the like), a fluorinated hydrocarbon group (for example, fluoromethyl group, trifluoromethyl group, pentafluoroethyl group, pentafluorophenyl group and the like), cyano group, nitro group, hydroxyl group, mercapto group, a silyl group (for example, trimethylsilyl group, triisopropylsilyl group, triphenylsilyl group, phenyldiethylsilyl group and the like), a phosphate group (for example, dihexylphosphoryl group and the like), a phosphite group (for example, diphenylphosphinyl group and the like), phosphono group, and the like.

Some of these substituents may further be substituted by the above-described substituent. In addition, two or more of these substituents may bind to each other to form a ring.

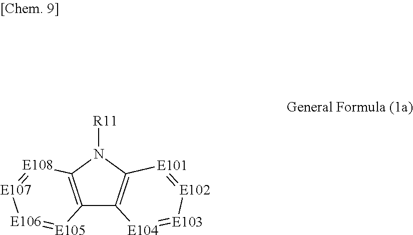

The compound having the structure represented by the above general formula (1a) is one form of the compound having the structure expressed by the above general formula (1), and is a compound in which X11 is —N(R11)- in the general formula (1).

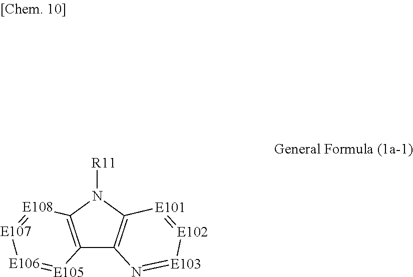

The compound having the structure represented by the above general formula (1a-1) is one form of the compound having the structure represented by the above general formula (1a), and is a compound in which E104 is —N═ in the general formula (1a).

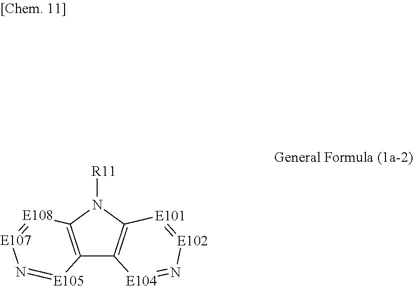

The compound having the structure represented by the above general formula (1a-2) is another form of the compound having the structure represented by the above general formula (1a), and is a compound in which E103 and E106 are —N═ in the general formula (1a).

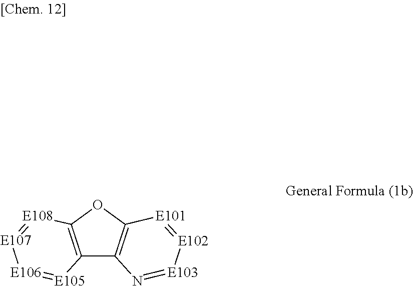

The compound having the structure represented by the above general formula (1b) is another form of the compound having the structure represented by the above general formula (1), and is a compound in which X11 is —O— and E104 is —N═ in the general formula (1).

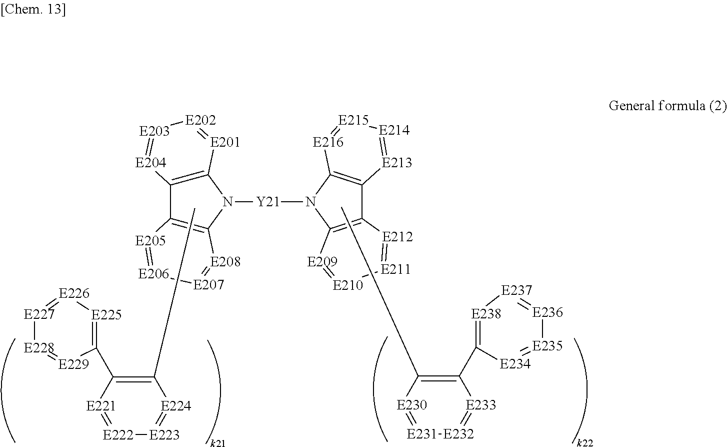

The general formula (2) is also one form of the above-described general formula (1). In the general formula (2), Y21 represents a divalent linking group of an arylene group, a heteroarylene group or a combination thereof. E201 to E216 and E221 to E238 each represent —C(R21)= or —N═. R21 represents hydrogen atom or a substituent. However, at least one of E221 to E229 and at least one of E230 to E238 represent —N═. k21 and k22 represent an integer of 0 to 4, and k21+k22 is an integer of 2 or more.

In the general formula (2), examples of an arylene group represented by Y21 include, for example, o-phenylene group, p-phenylene group, naphthalenediyl group, anthracenediyl group, naphthacenediyl group, pyrenediyl group, naphthylnaphthalenediyl group, biphenyldiyl group (for example, [1,1′-biphenyl]-4,4′-diyl group, 3,3′-biphenyldiyl group, 3,6-biphenyldiyl group and the like), terphenyldiyl group, quaterphenyldiyl group, quinquephenyldiyl group, sexiphenyldiyl group, septiphenyldiyl group, octiphenyldiyl group, nobiphenyldiyl group, deciphenyldiyl group and the like.

Furthermore, in the general formula (2), examples of a heteroarylene group represented by Y21 include, for example, a divalent group derived from a group consisting of carbazole ring, carboline ring, diazacarbazole ring (also referred to as monoazacarboline ring, and indicating a ring structure in which one of carbon atoms constituting the carboline ring is substituted with a nitrogen atom), triazole ring, pyrrole ring, pyridine ring, pyrazine ring, quinoxaline ring, thiophene ring, oxadiazole ring, dibenzofuran ring, dibenzothiophene ring, indole ring and the like.

A preferable aspect of a divalent linking group which is an arylene group, a heteroarylene group or a combination thereof represented by Y21 preferably includes, among the heteroarylene groups, a group which is derived from a condensed aromatic heterocyclic ring formed by condensing three or more rings; and the group derived from the condensed aromatic heterocyclic ring formed by condensing three or more rings is preferably a group derived from dibenzofuran ring or a group derived from dibenzothiophene ring.

In the general formula (2), when the R21 of —C(R21)= each represented by E201 to E216, E221 to E238 is a substituent, as examples of its substituent, the substituent exemplified as R11, R12 of the general formula (1) are applied in the same way.

In the general formula (2), it is preferable that six or more of E201 to E208 and six or more of E209 to E216 each represent —C(R21)=.

In the general formula (2), it is preferable that at least one of E225 to E229 and at least one of E234 to E238 represent —N═.

Furthermore, in the general formula (2), it is preferable that at least one of E225 to E229 and at least one of E234 to E238 represent —N═.

Additionally, in the general formula (2), preferable aspect is that E221 to E224 and E230 to E233 each represent —C(R21)=.

Moreover, in the compound represented by the general formula (2), it is preferable that E203 represents —C(R21)=, and R21 represents a linking moiety, and furthermore it is also preferable that E211 represents —C(R21)=, and R21 represents a linking moiety.

Furthermore, it is preferable that E225 and E234 represent —N═, and it is preferable that E221 to E224 and E230 to E233 each represent —C(R21)=.

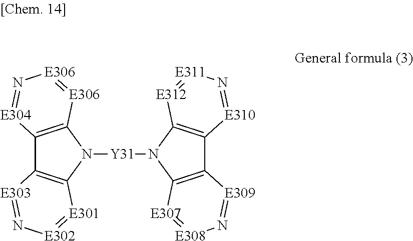

The general formula (3) is also one form of the general formula (1a-2). In the above-described general formula (3), E301 to E312 each represent —C(R31)=, and the R31 represents hydrogen atom (H) or a substituent. Y31 represents a divalent linking group composed of an arylene group, a heteroarylene group or combination thereof.

In the above-described general formula (3), when the R31 of —C(R31)=each represented by E301 to E312 is a substituent, the substituent exemplified as R11, R12 of the general formula (1) are applied as examples of its substituent, in the same way.

In addition, in the general formula (3), a preferable aspect of the divalent linking group of an arylene group, a heteroarylene group or combination thereof represented by Y31, is the same as that in Y21 of the general formula (2).

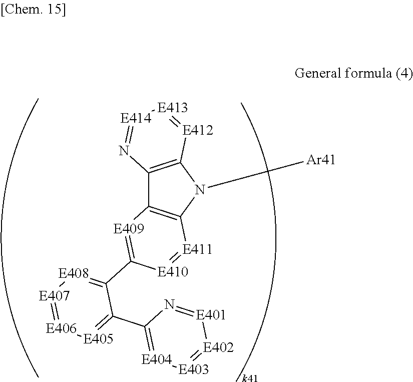

The general formula (4) is also one form of the general formula (1a-1). In the above-described the general formula (4), E401 to E414 each represent —C(R41)=, and the R41 represents hydrogen atom (H) or a substituent. In addition, Ar41 represents a substituted or un-substituted aromatic hydrocarbon ring or aromatic heterocyclic ring. Furthermore, k41 represents an integer of 3 or more.

In the above-described general formula (4), when the R41 of —C(R41)=each represented by E401 to E414 is a substituent, the substituent exemplified as R11, R12 of the general formula (1) are applied as examples of its substituent, in the same way.

Furthermore, in the general formula (4), when Ar41 represents an aromatic hydrocarbon ring, examples of the aromatic hydrocarbon ring include benzene ring, biphenyl ring, naphthalene ring, azulene ring, anthracene ring, phenanthrene ring, pyrene ring, chrysene ring, naphthalene ring, triphenylene ring, o-terphenyl ring, m-terphenyl ring, p-terphenyl ring, acenaphthene ring, coronene ring, fluorene ring, fluoranthrene ring, naphthacene ring, pentacene ring, perylene ring, pentaphene ring, picene ring, pyrene ring, pyranthrene ring, anthranthrene ring, and the like. Furthermore, these rings may also have a substituent represented by R11, R12 of the general formula (1).

Moreover, in the general formula (4), when Ar41 represents an aromatic heterocyclic ring, examples of the aromatic heterocyclic ring include furan ring, thiophene ring, oxazole ring, pyrrole ring, pyridine ring, pyridazine ring, pyrimidine ring, pyrazine ring, triazine ring, benzimidazole ring, oxadiazole ring, triazole ring, imidazole ring, pyrazole ring, triazole ring, indole ring, benzimidazole ring, benzothiazole ring, benzoxazole ring, quinoxaline ring, quinazoline ring, phthalazine ring, carbazole ring, azacarbazole ring, and the like. Note that the azacarbazole ring represents a ring in which one or more carbon atoms of the benzene ring constituting the carbazole ring have been substituted by a nitrogen atom. Furthermore, these rings may also have a substituent represented by R11, R12 of the general formula (1).

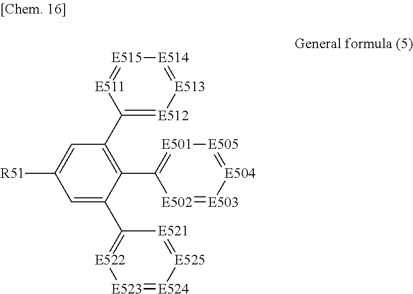

In the above-described general formula (5), R51 represents a substituent. E501, E502, E511 to E515, E521 to E525 each represent —C(R52)= or —N═. E503 to E505 each represent —C(R52)=. R52 represents hydrogen atom (H) or a substituent. At least one of E501 and E502 is —N═, at least one of E511 to E515 is —N═, and at least one of E521 to E525 is —N═.

In the above-described general formula (5), when the R51 represents a substituent and the R52 represents a substituent, the substituent exemplified as R11, R12 of the general formula (1) are applied as examples of the substituent, in the same way.

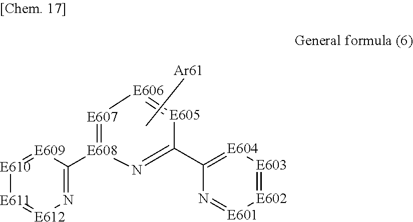

In the above-described general formula (6), E601 to E612 each represent —C(R61)= or —N═, R61 represents hydrogen atom or a substituent. Ar61 represents a substituted or un-substituted aromatic hydrocarbon ring or aromatic heterocyclic ring.

In the above-described general formula (6), when the R61 of —C(R61)=each represented by E601 to E612 is a substituent, the substituent exemplified as R11, R12 of the general formula (1) are applied as examples of its substituent, in the same way.

In addition, in the general formula (6), the substituted or un-substituted aromatic hydrocarbon ring or aromatic heterocyclic ring represented by Ar61 is the same as that in Ar41 of the general formula (4).

[Compound-3]

In addition, as the other compound constituting the nitrogen-containing layer, other than the above compounds represented by the general formulae (1) to (6) or other general formulae, there are compounds 1 to 134 exemplified in the followings. These compounds are materials having electron transport property or electron injection property. Note that, among these compounds 1 to 134, a compound which falls within the above-described range of the effective unshared electron pair content [n/M] is included, and such a compound can be used alone as the compound constituting the nitrogen-containing layer. Furthermore, in the compounds 1 to 134, there are compounds which are applicable to the above-described general formulae (1) to (6) or other general formulae.

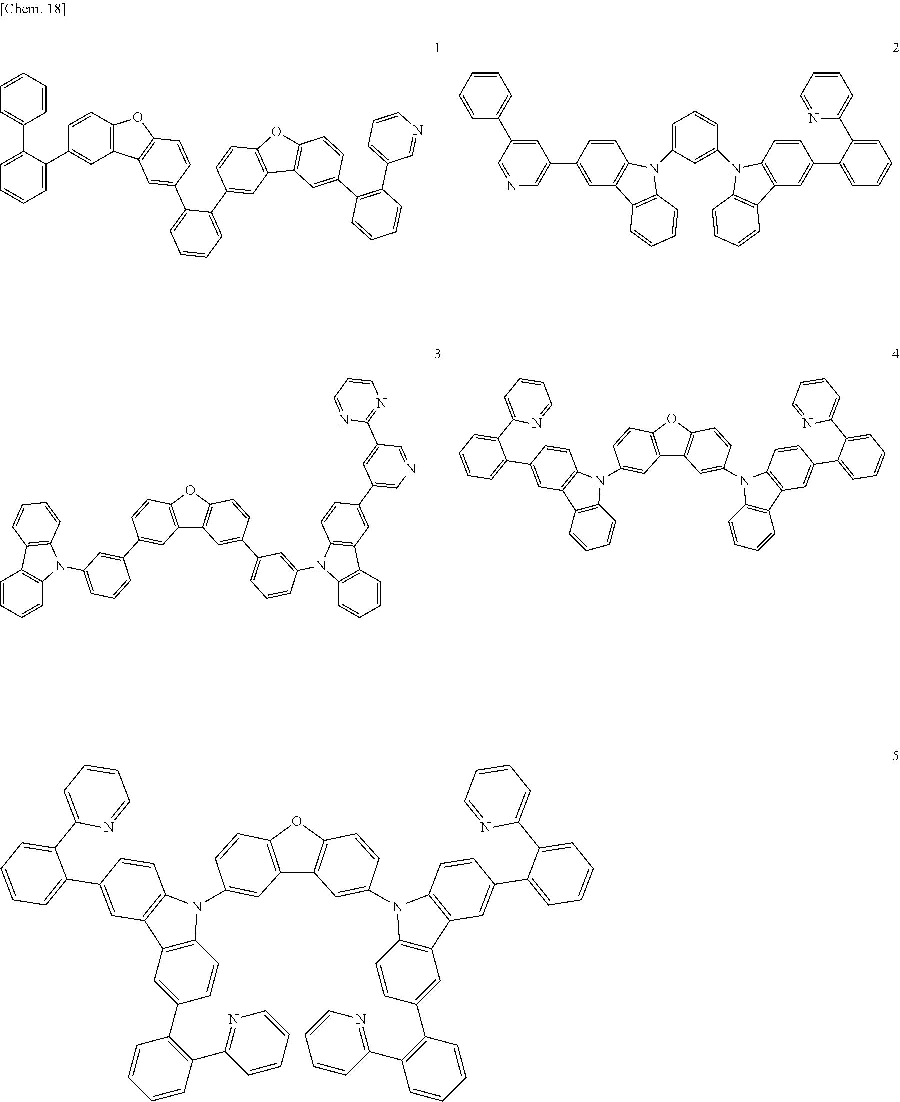

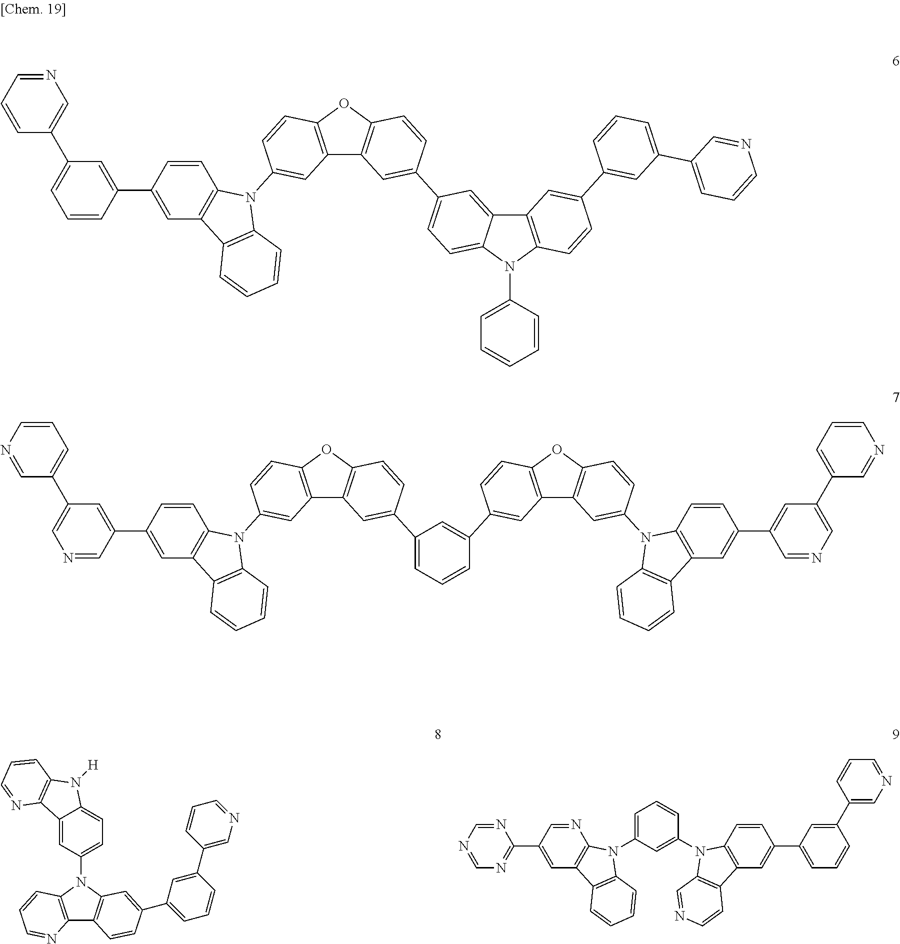

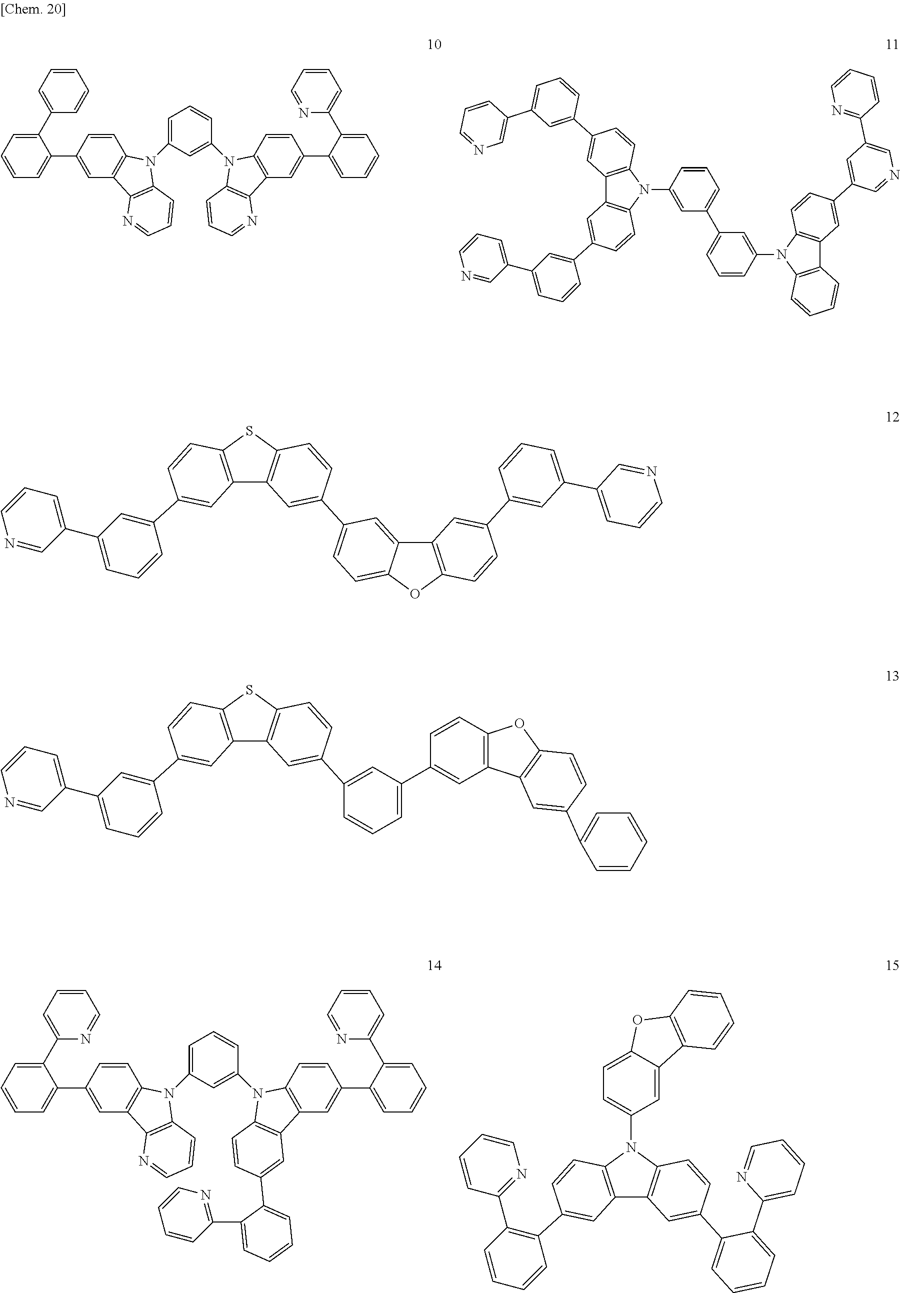

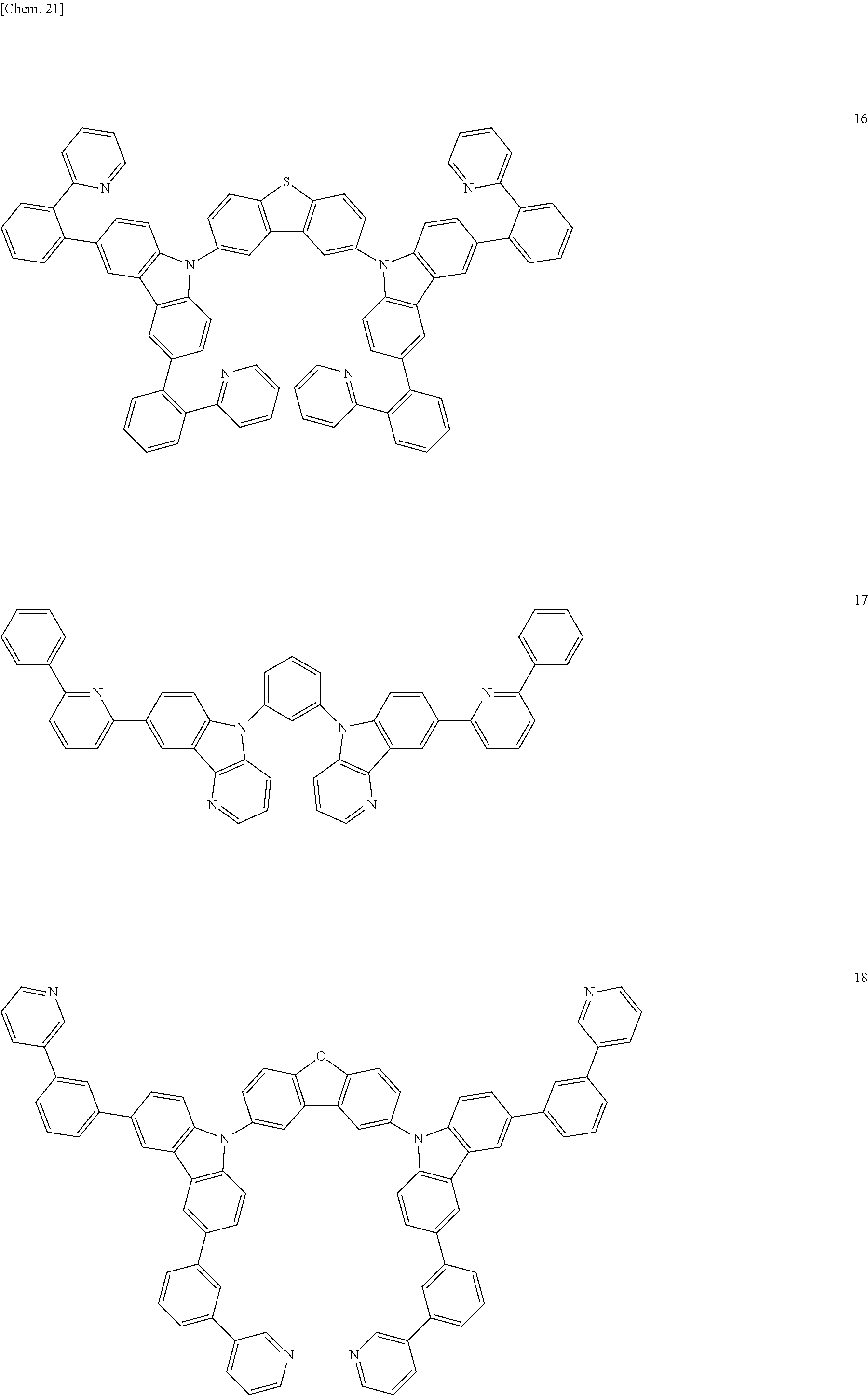

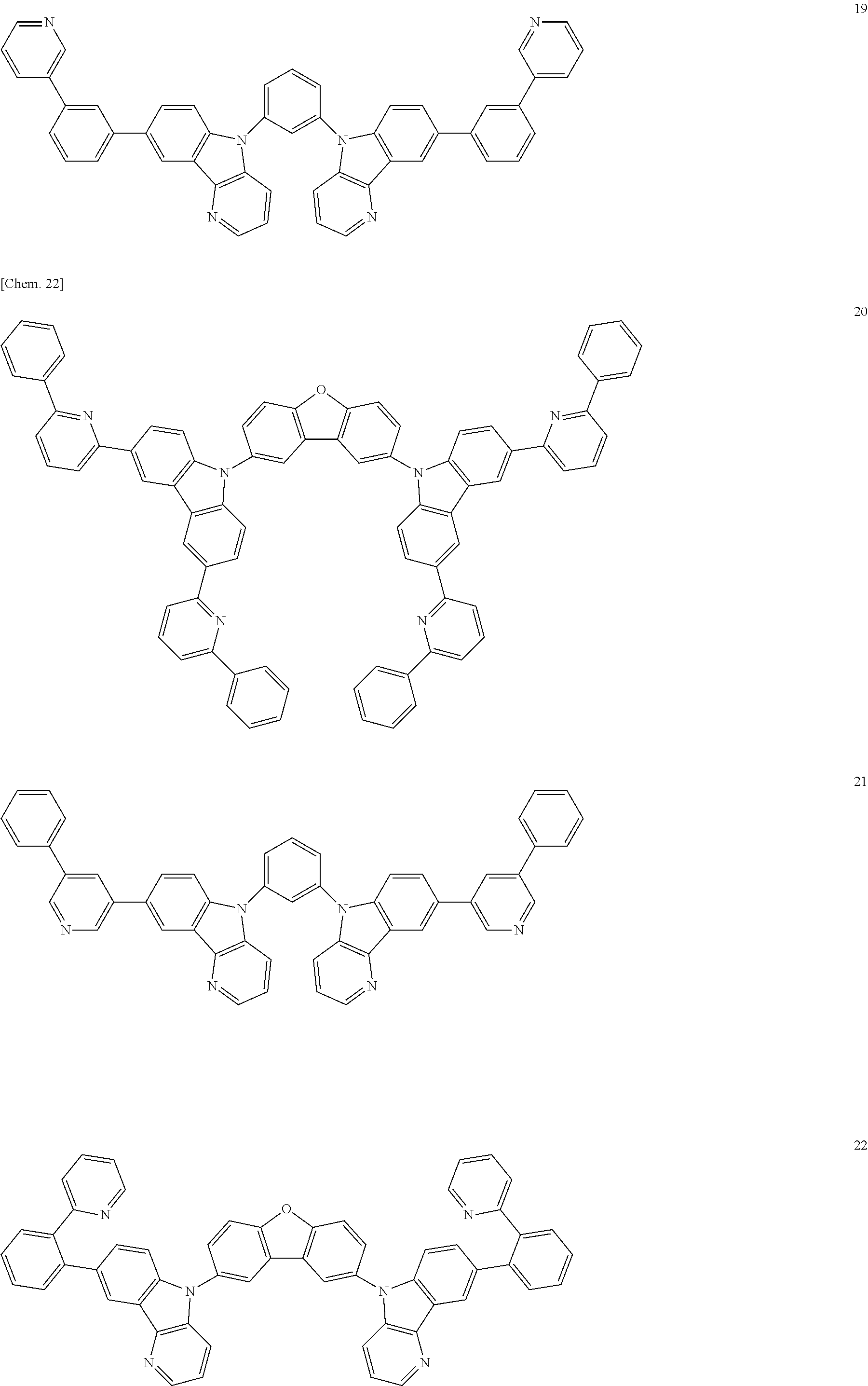

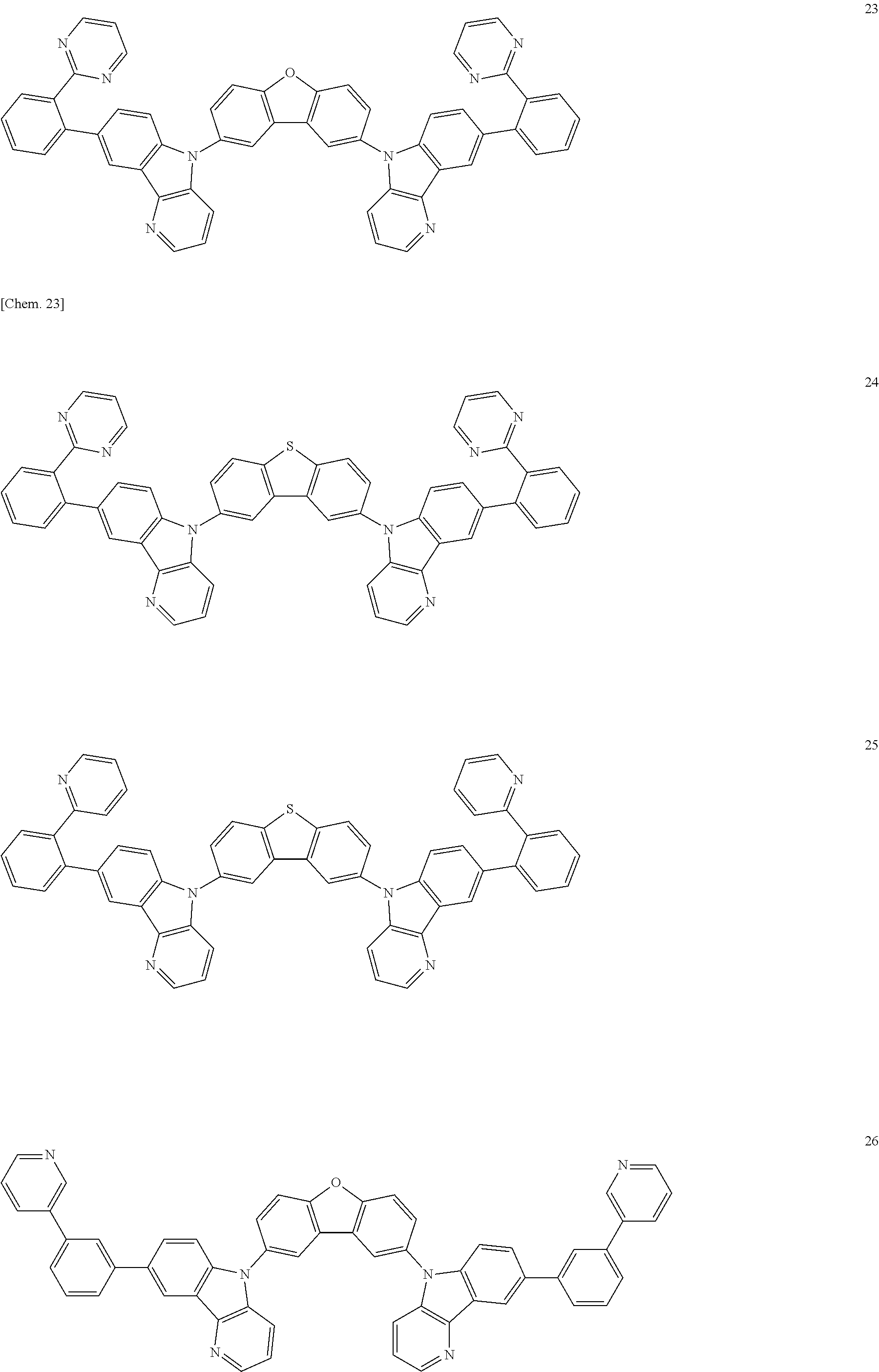

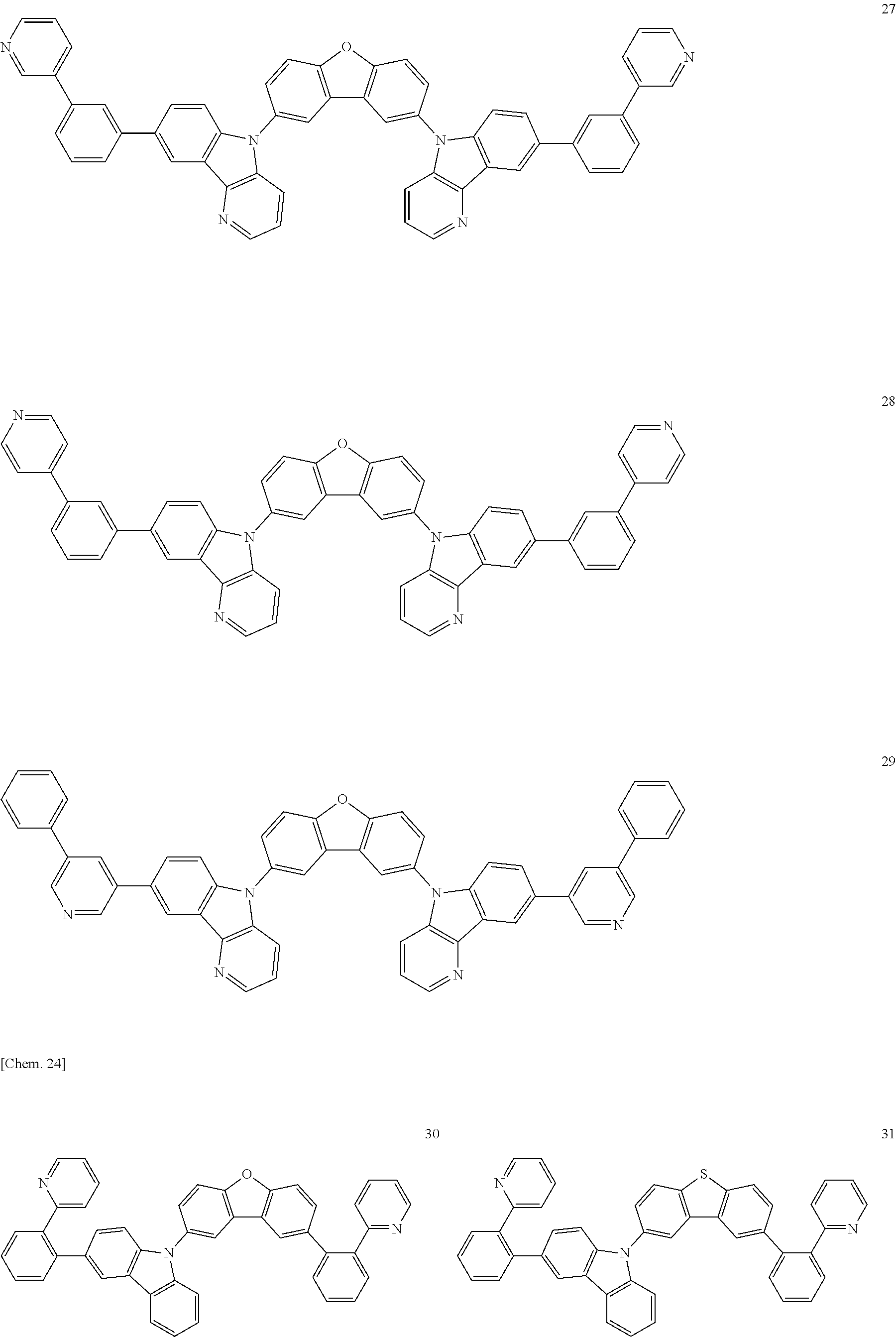

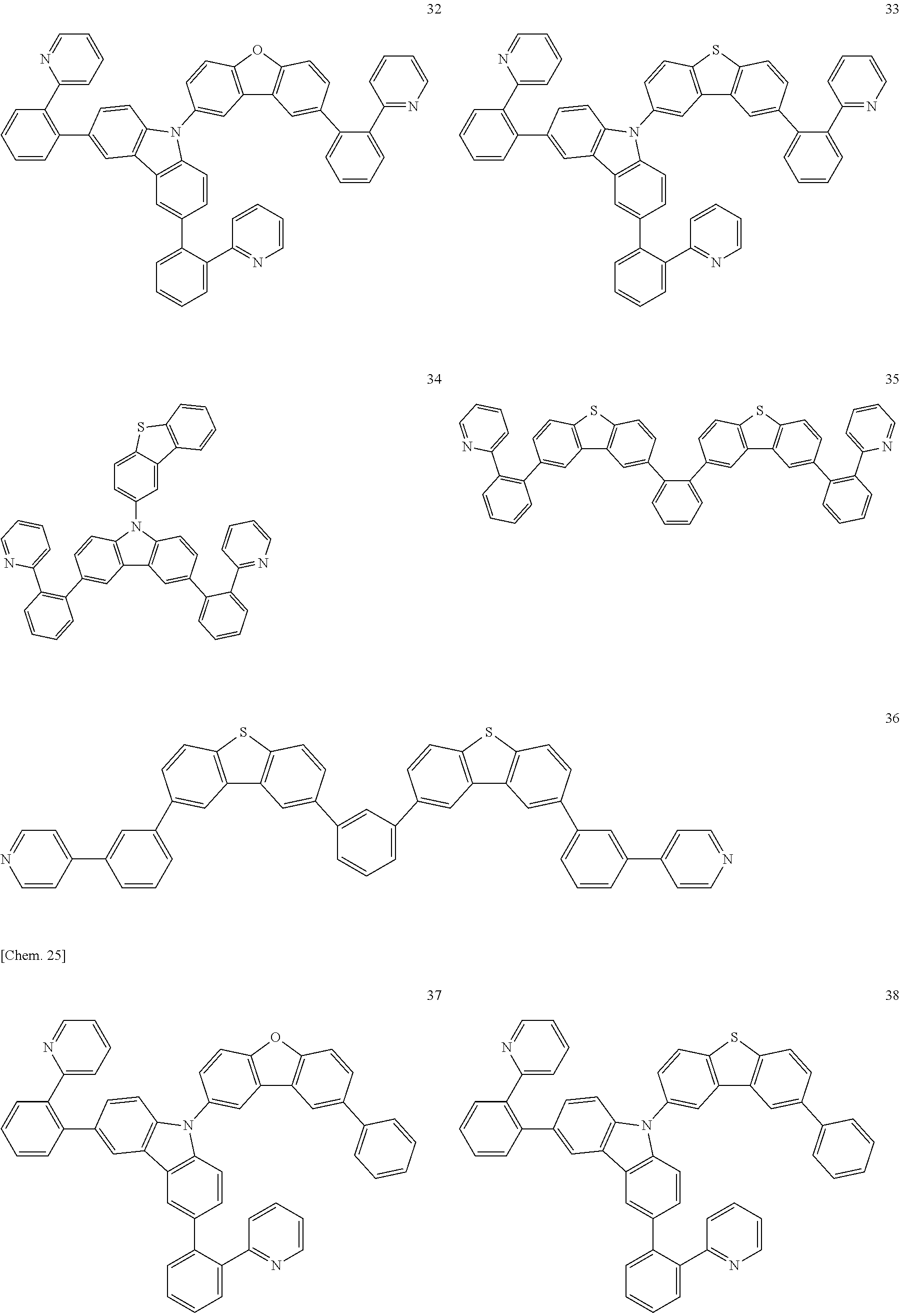

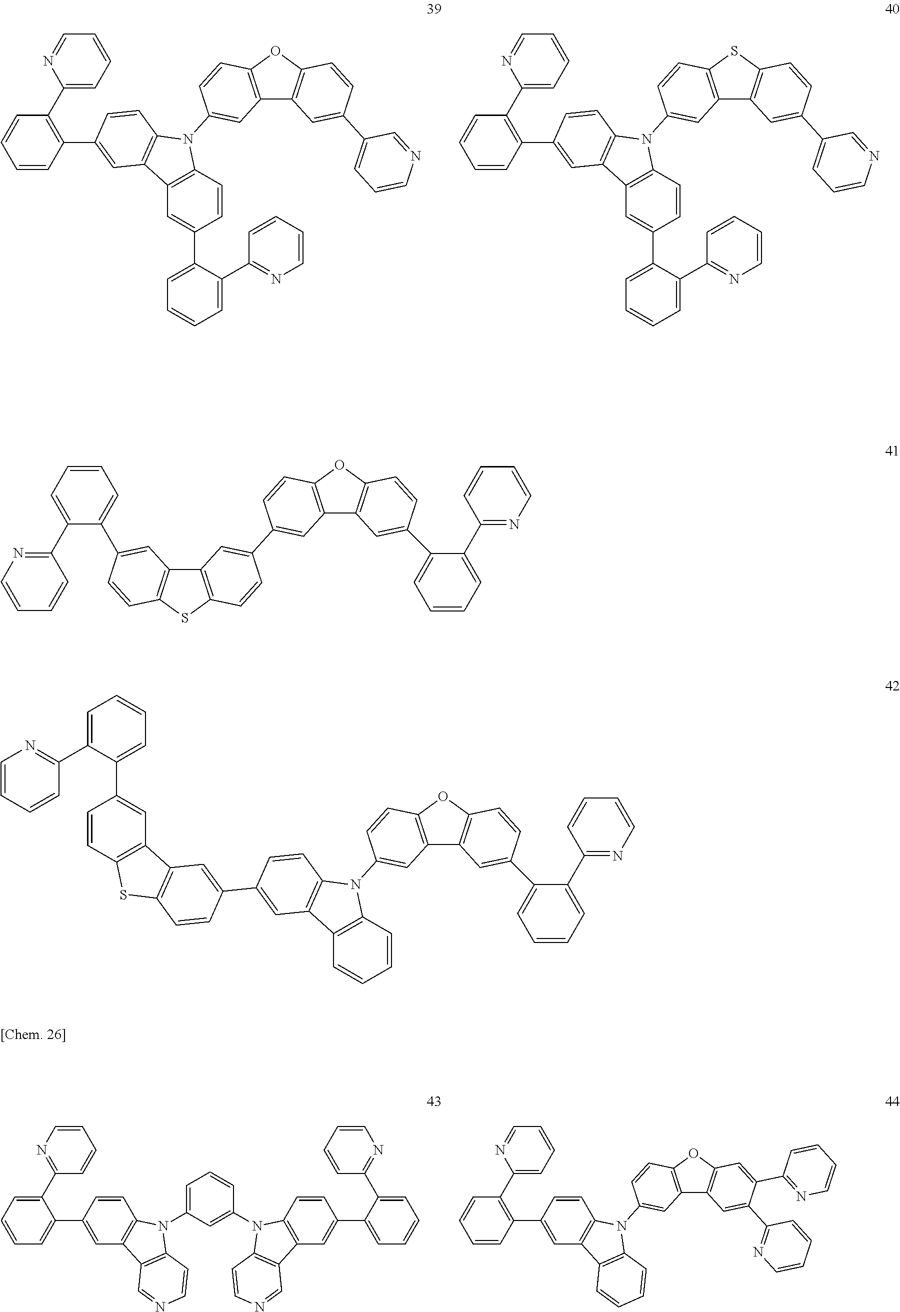

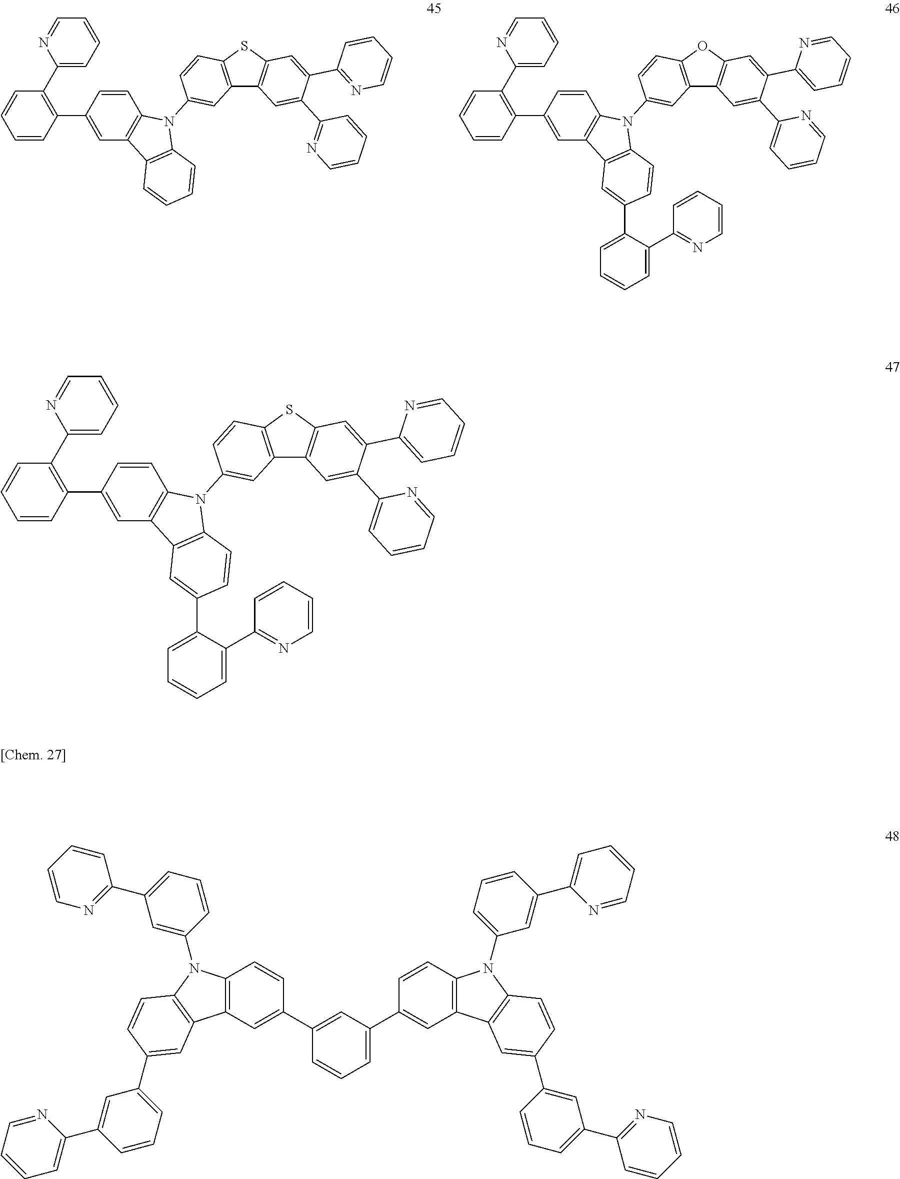

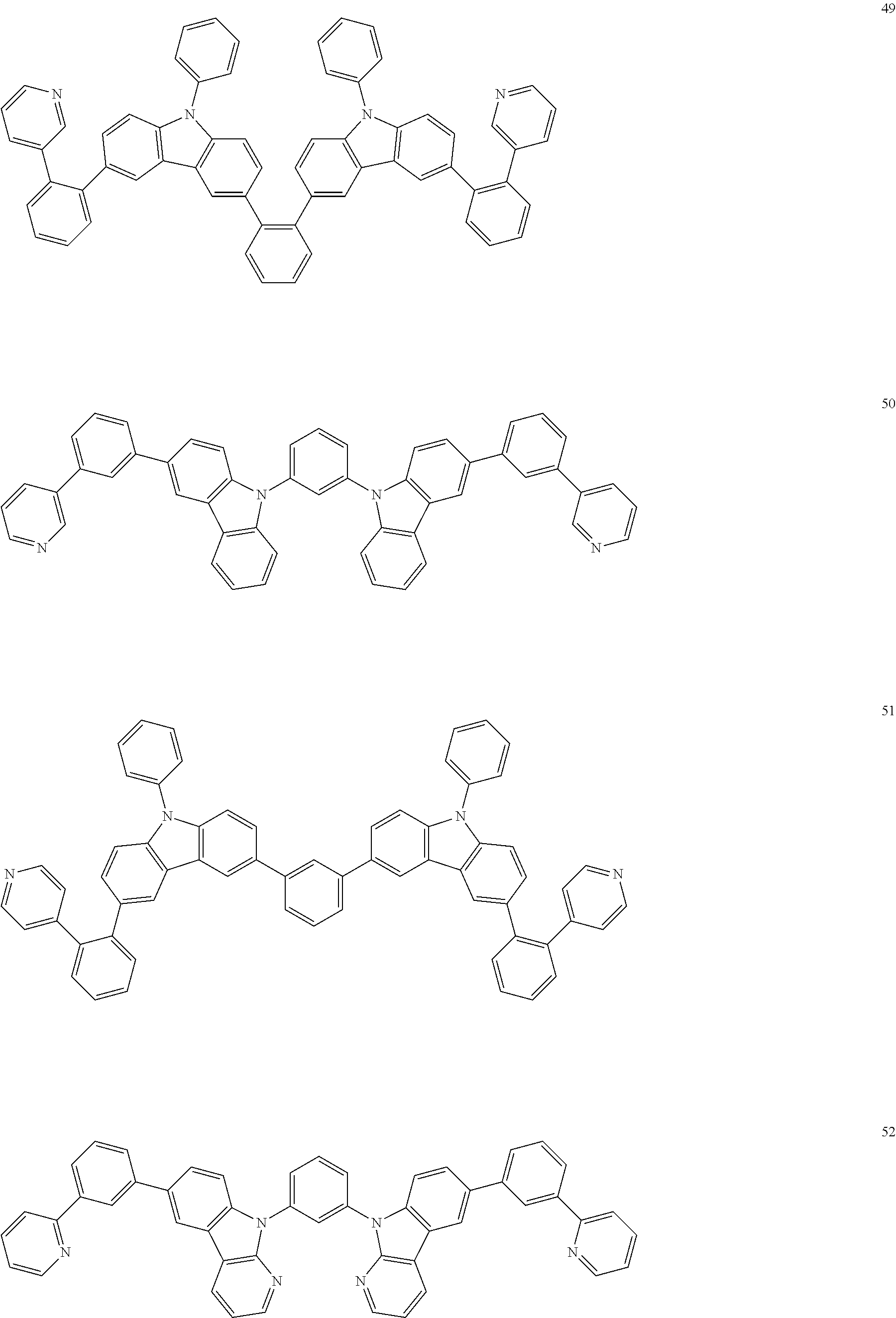

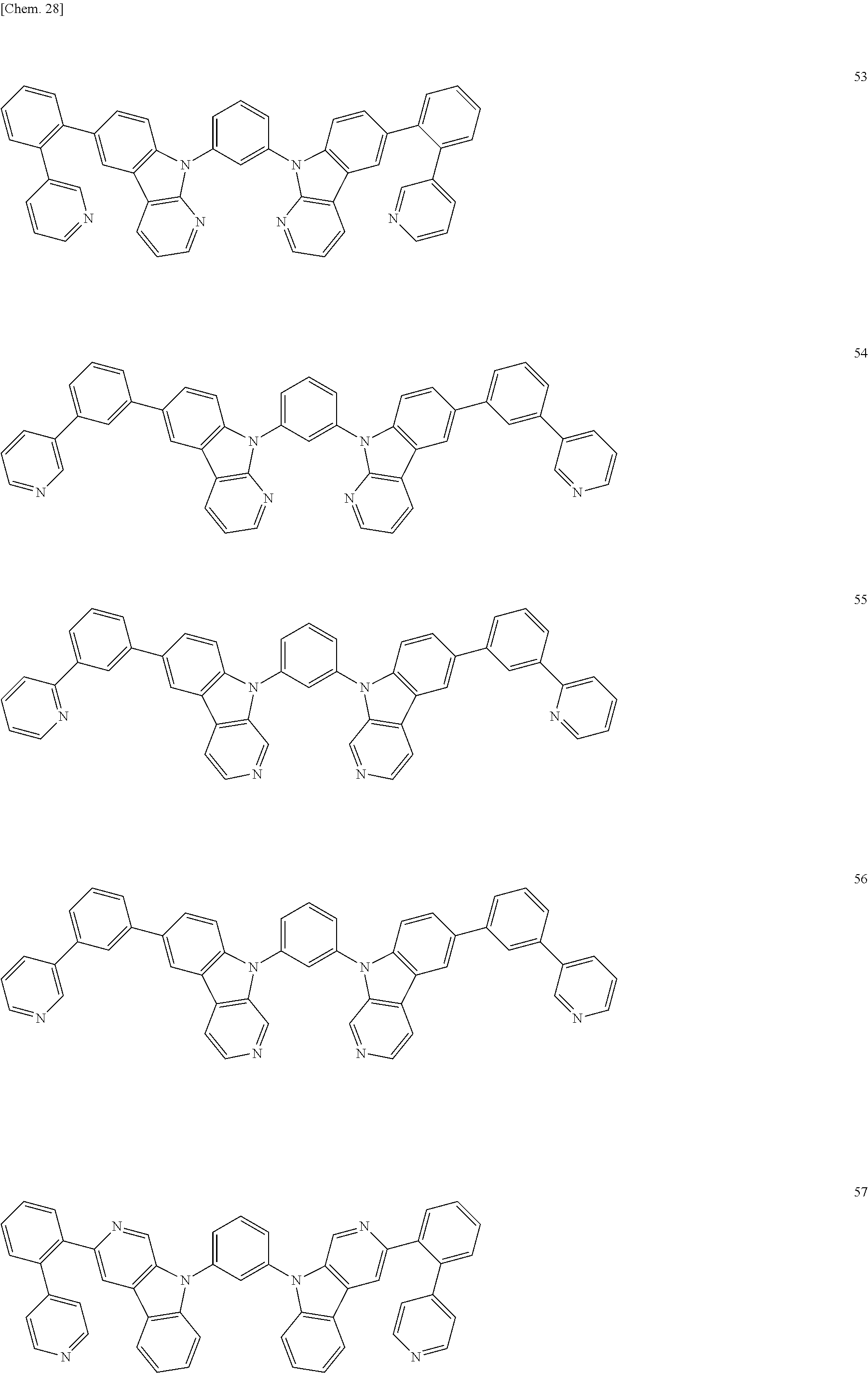

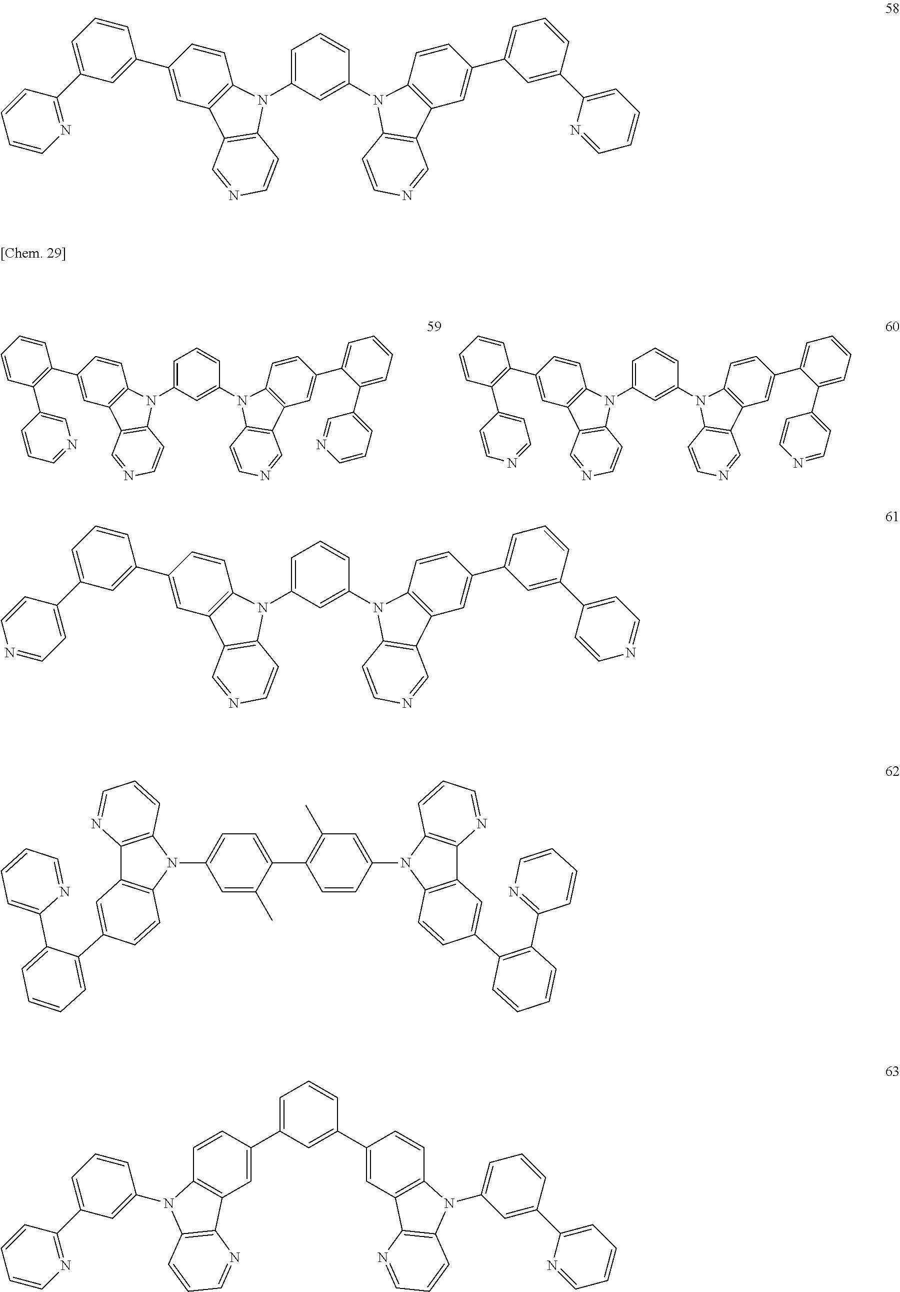

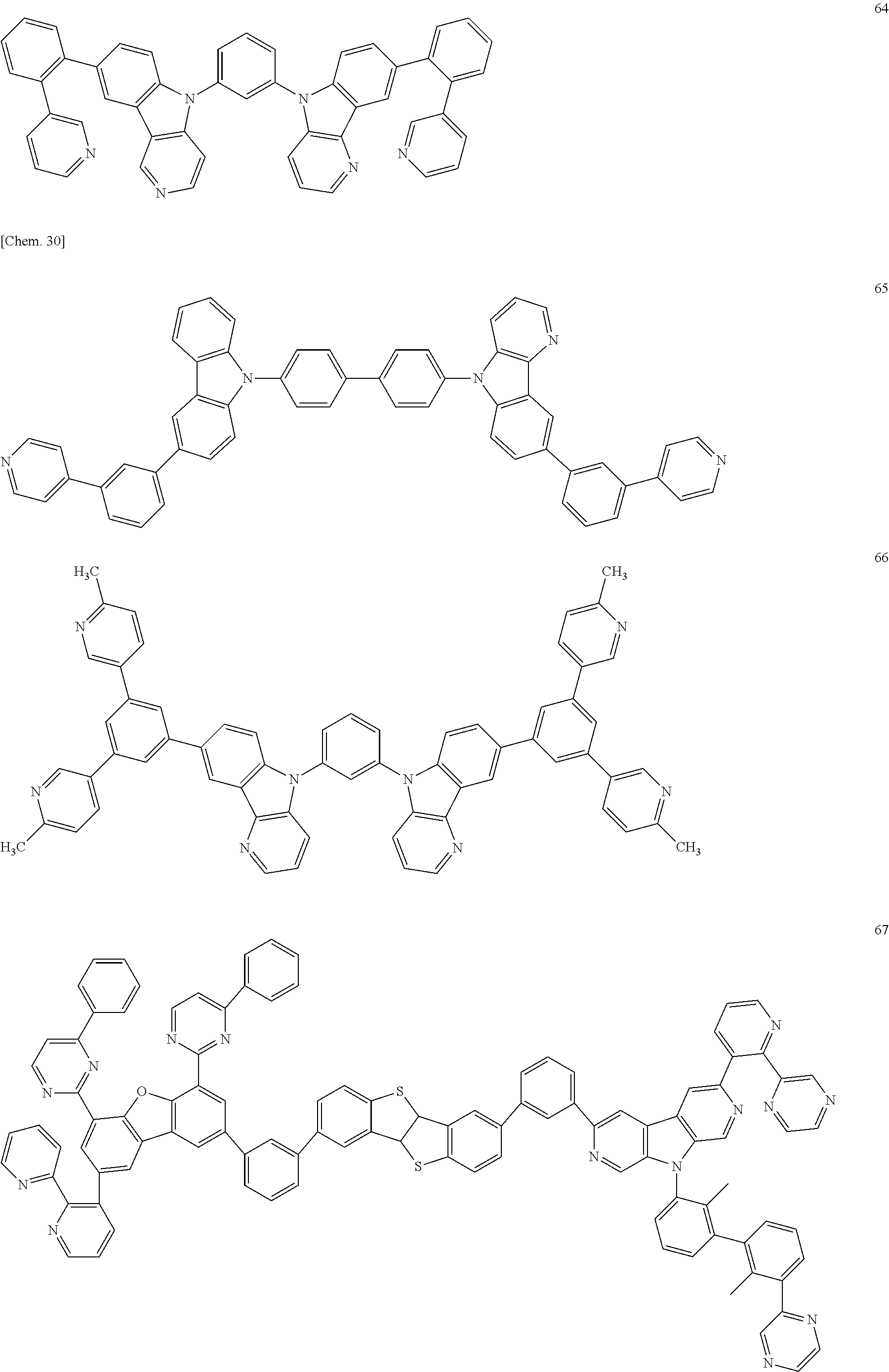

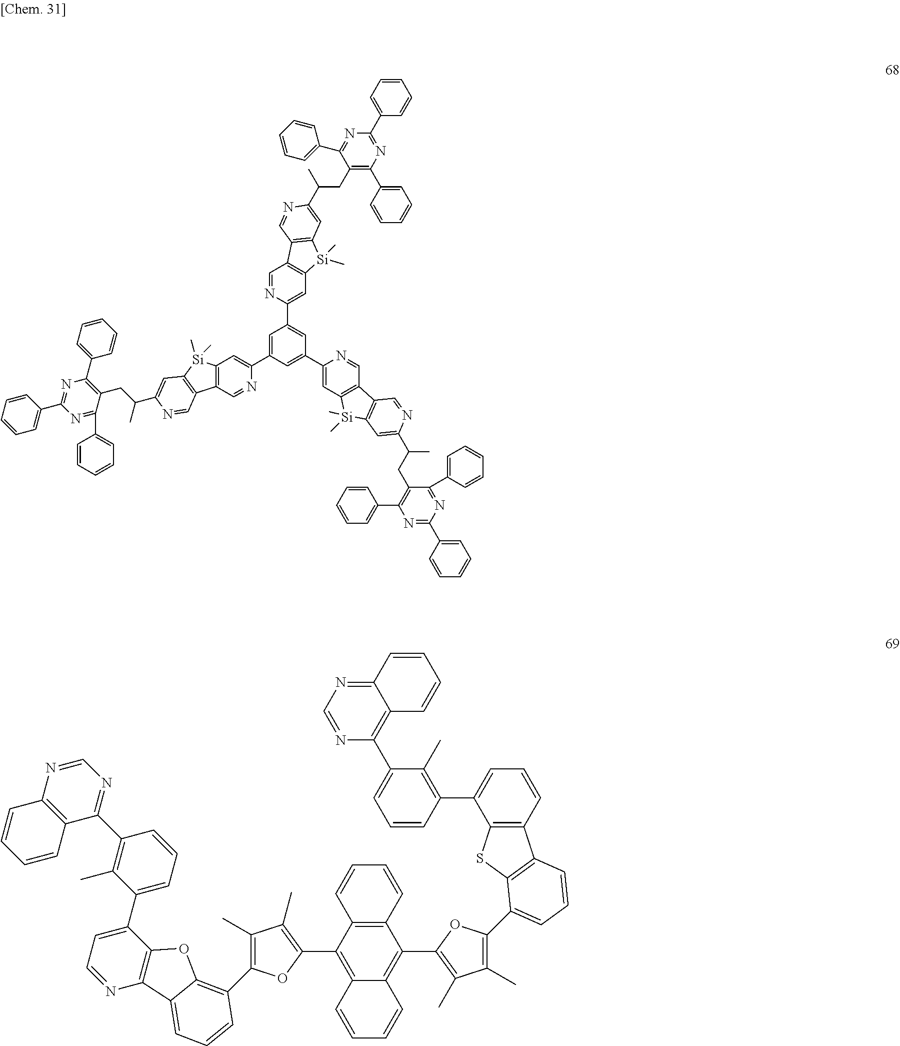

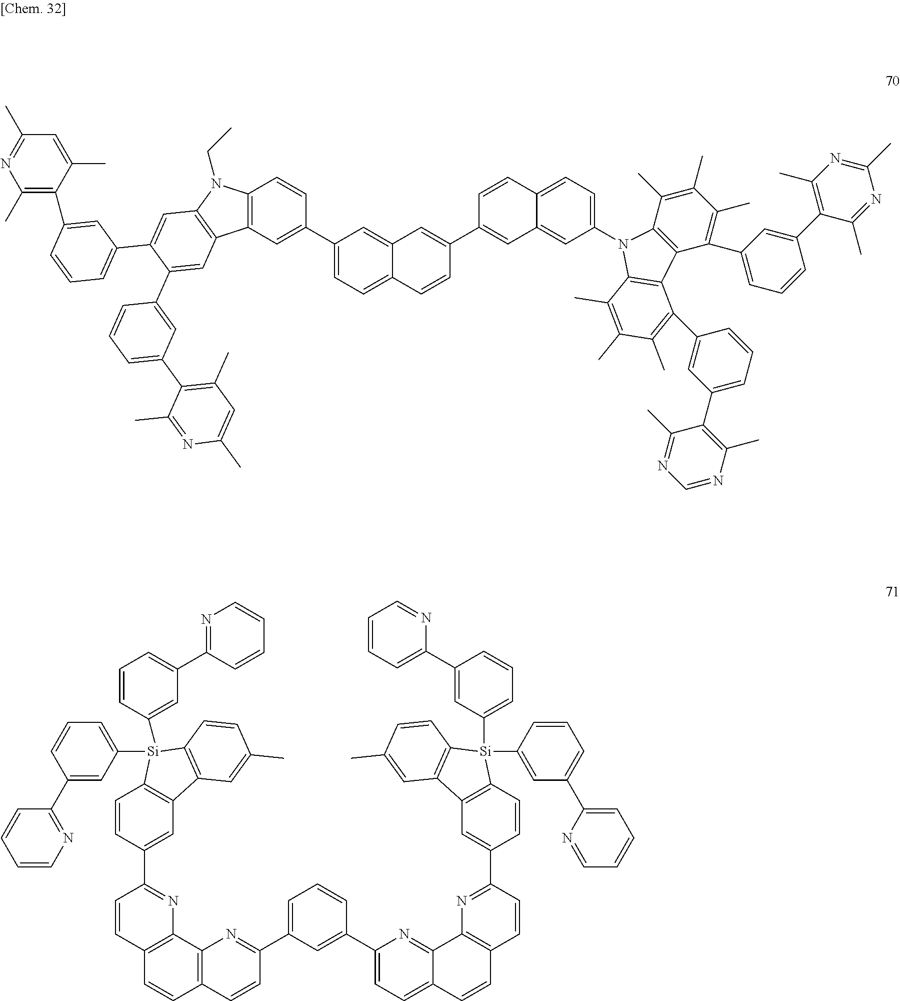

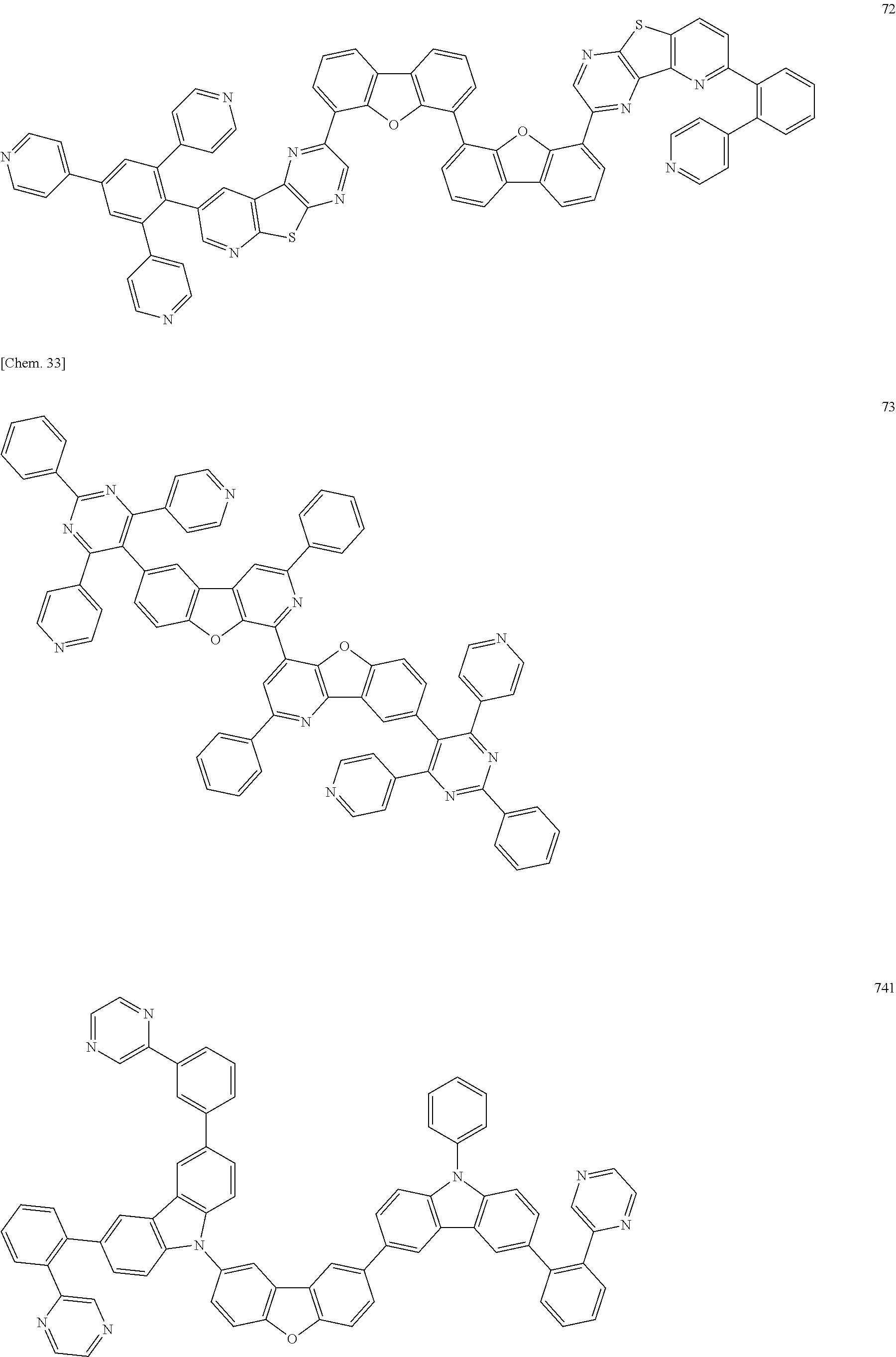

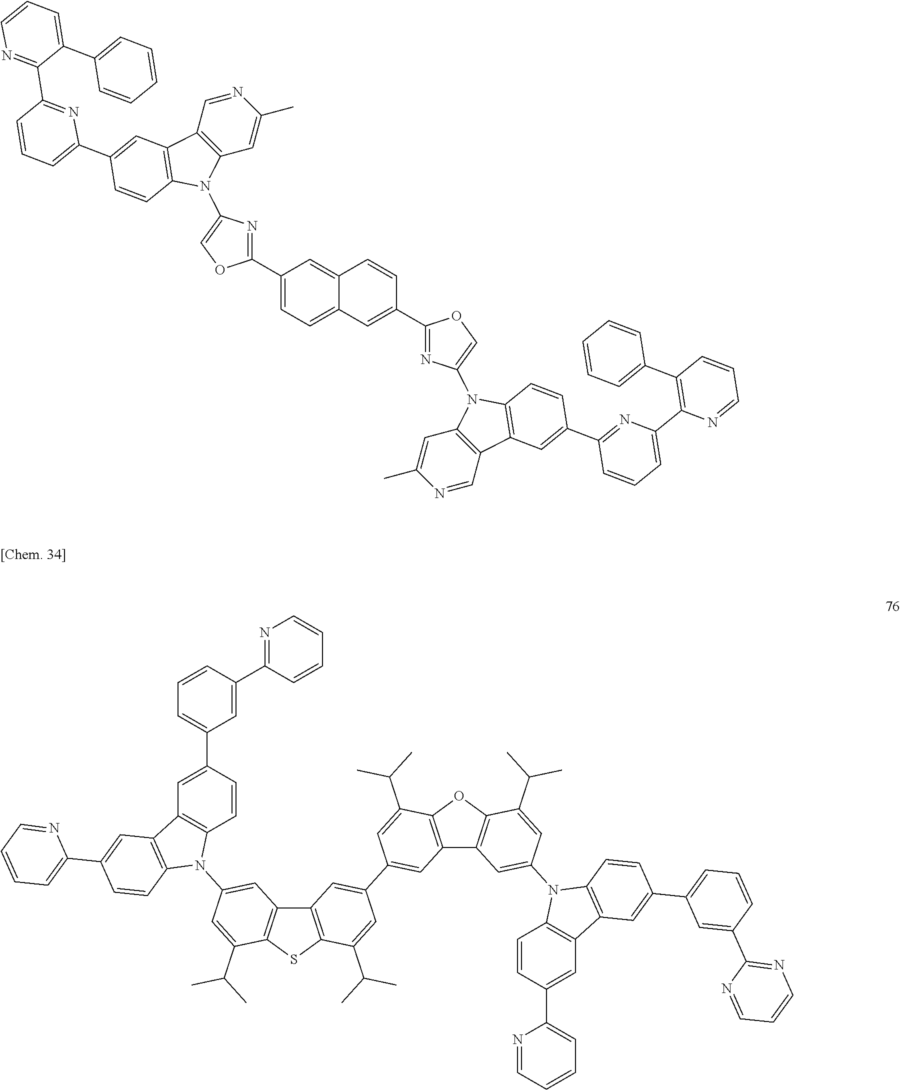

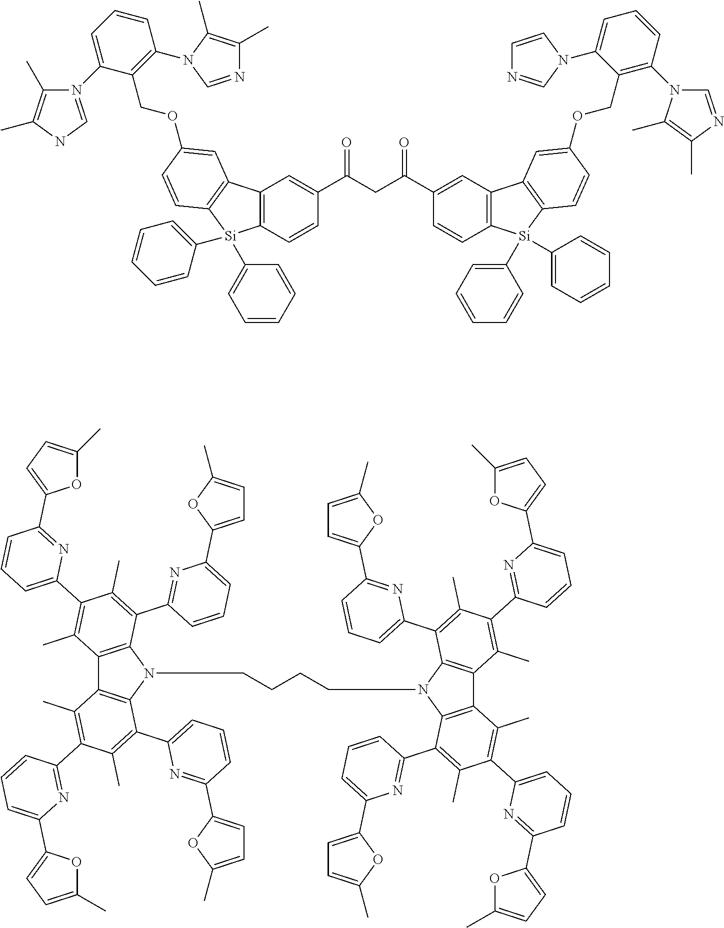

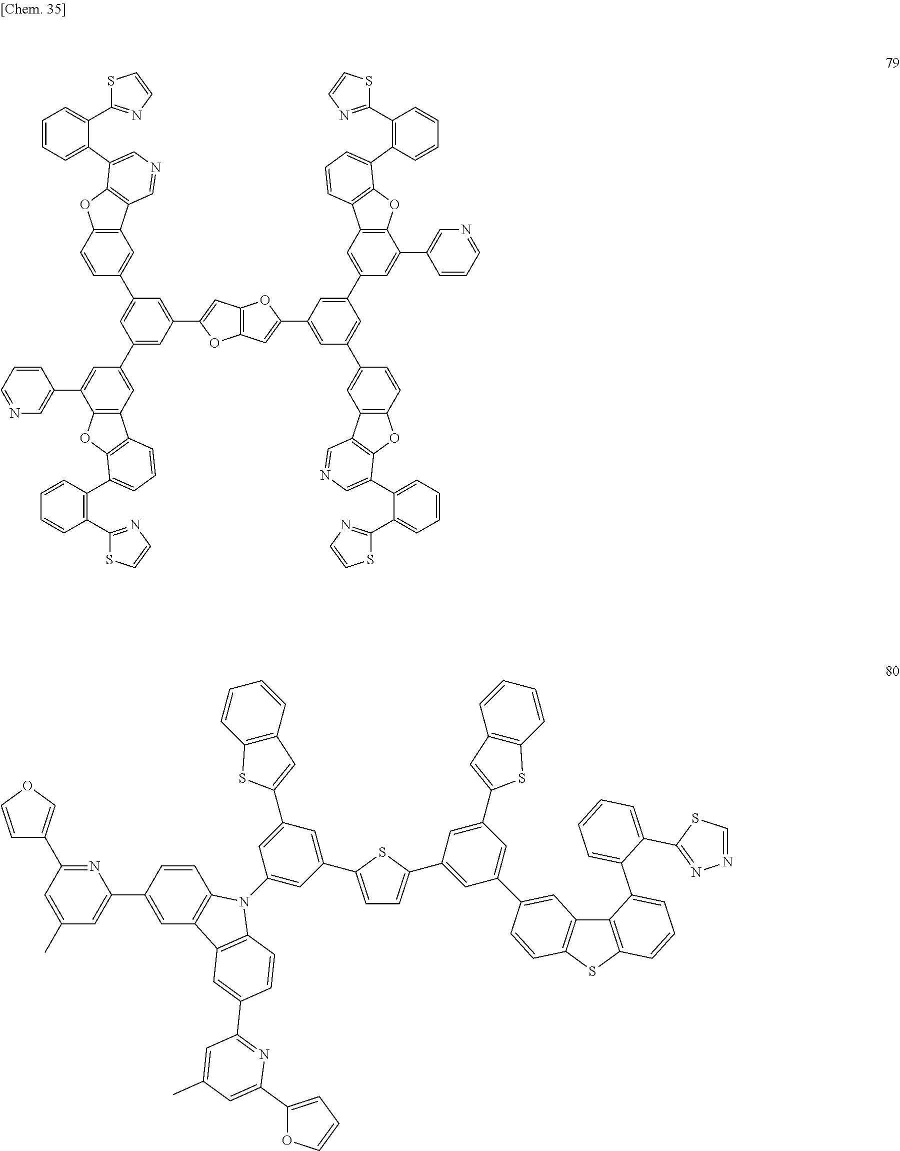

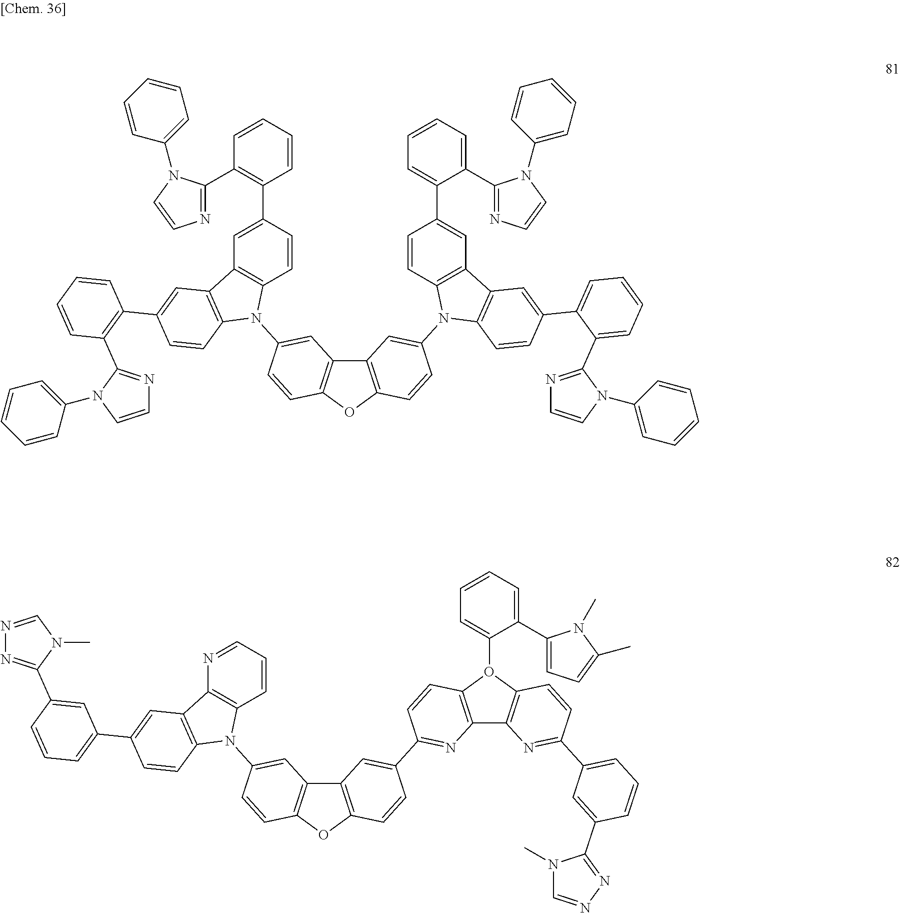

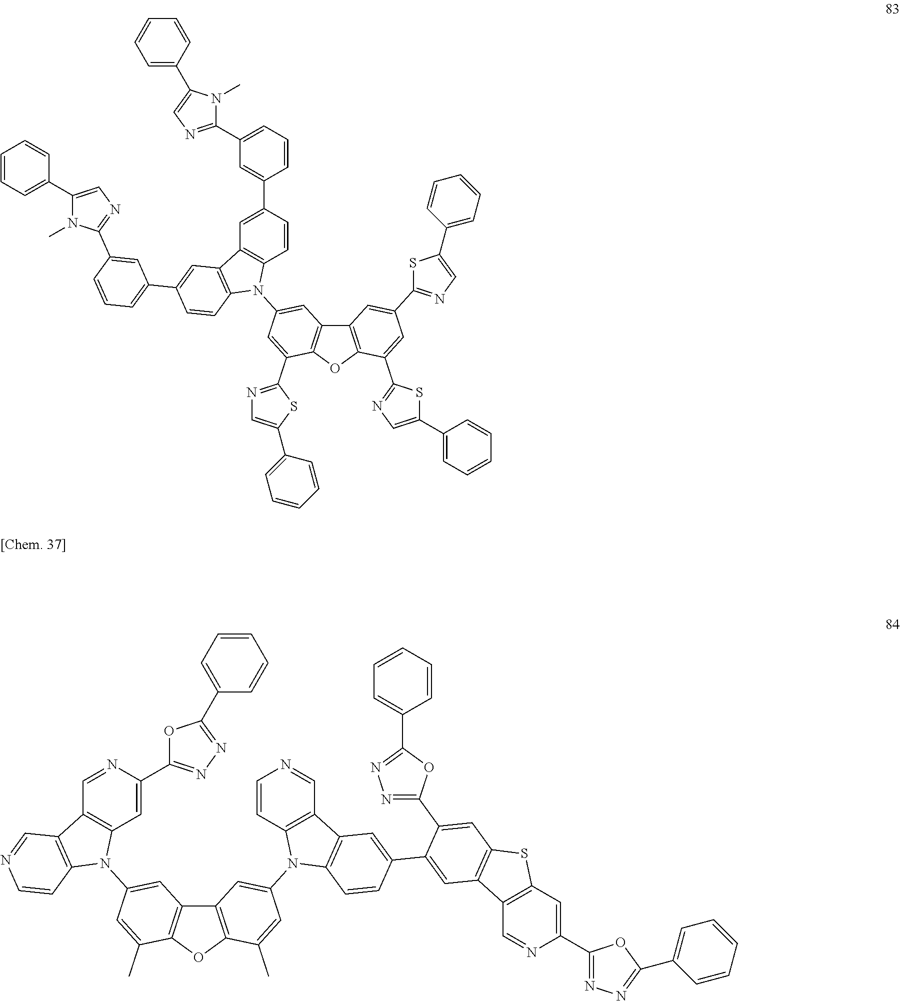

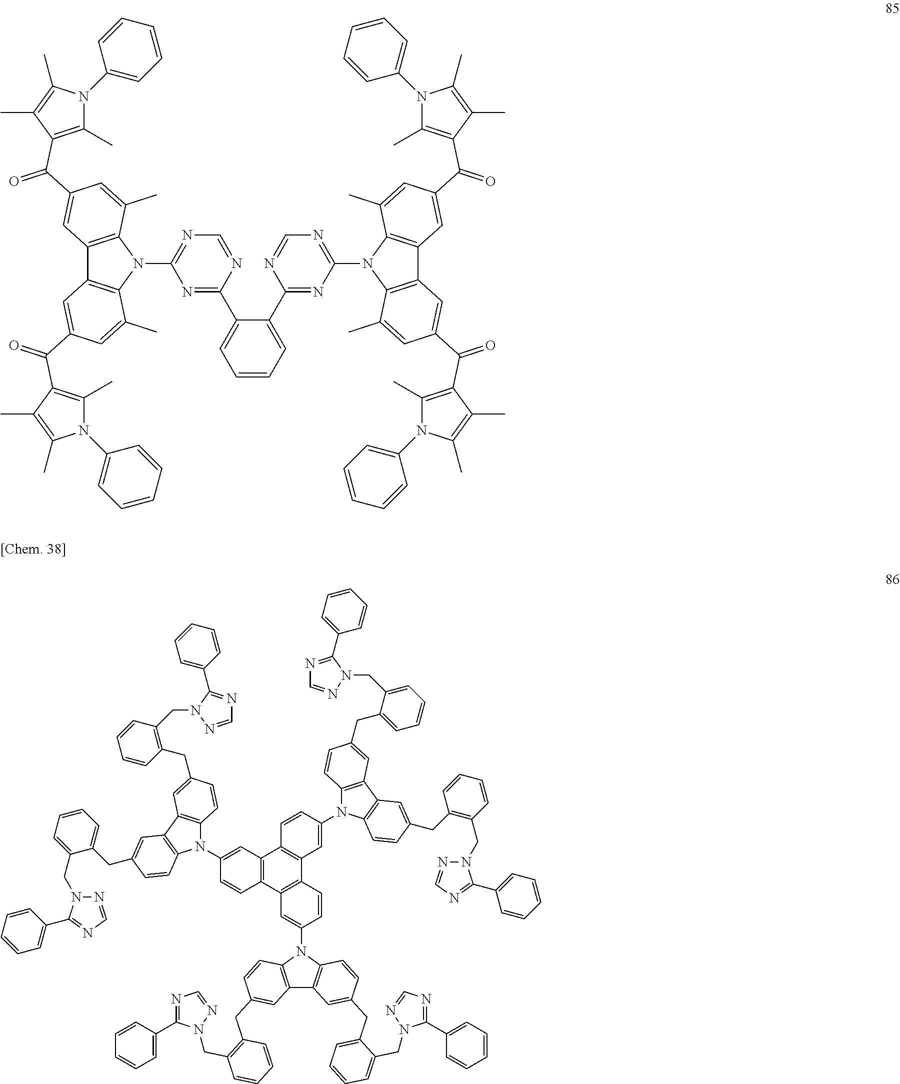

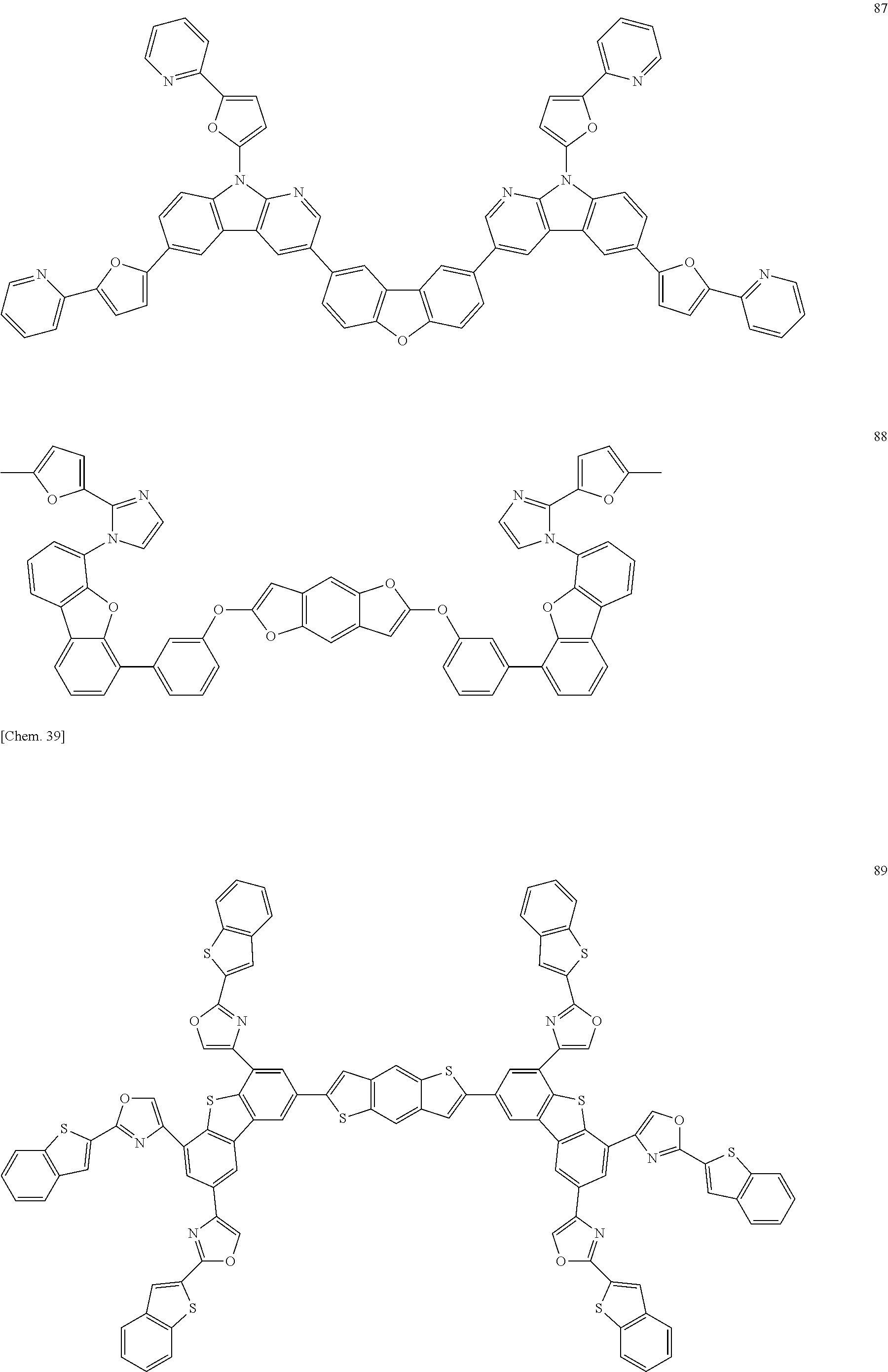

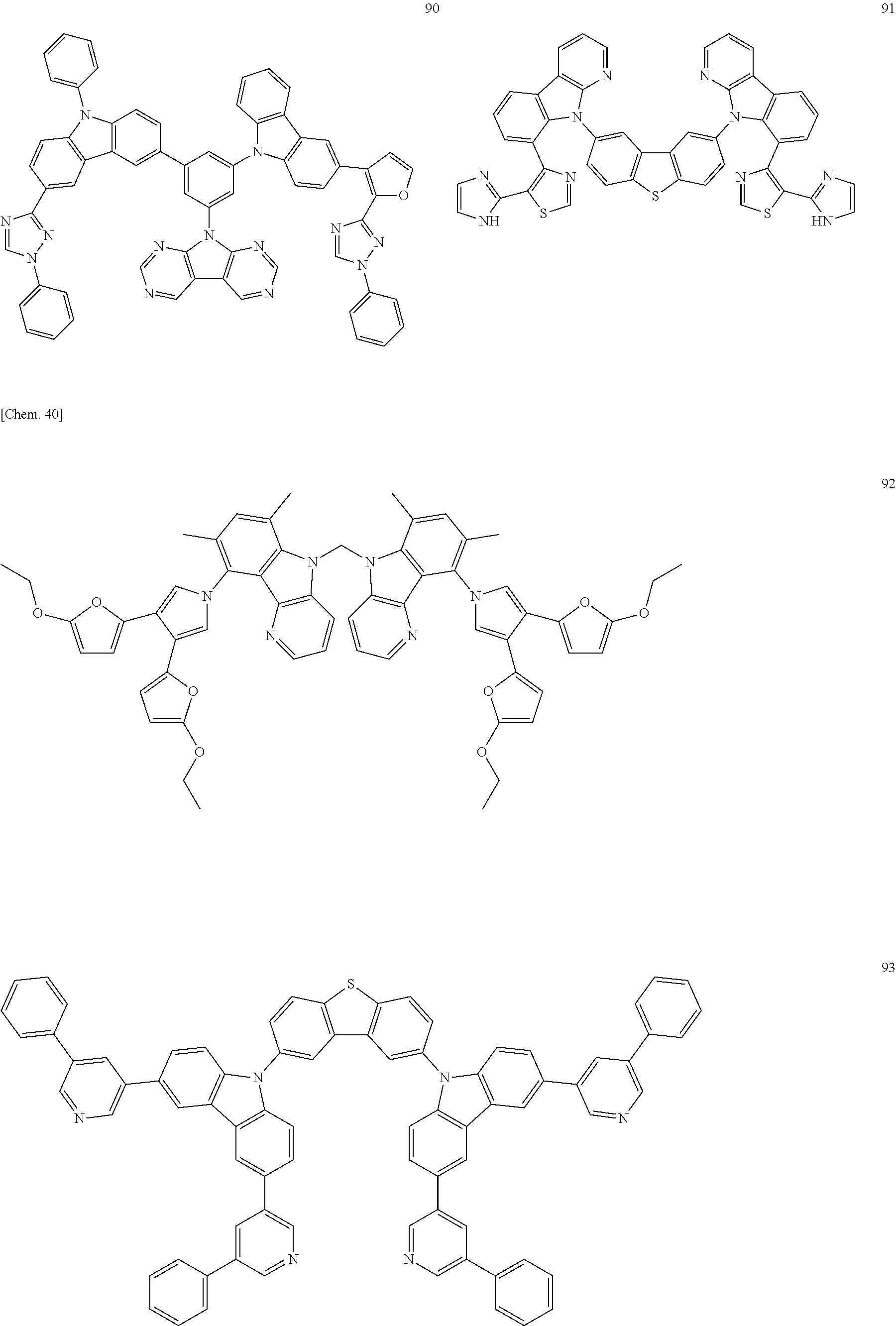

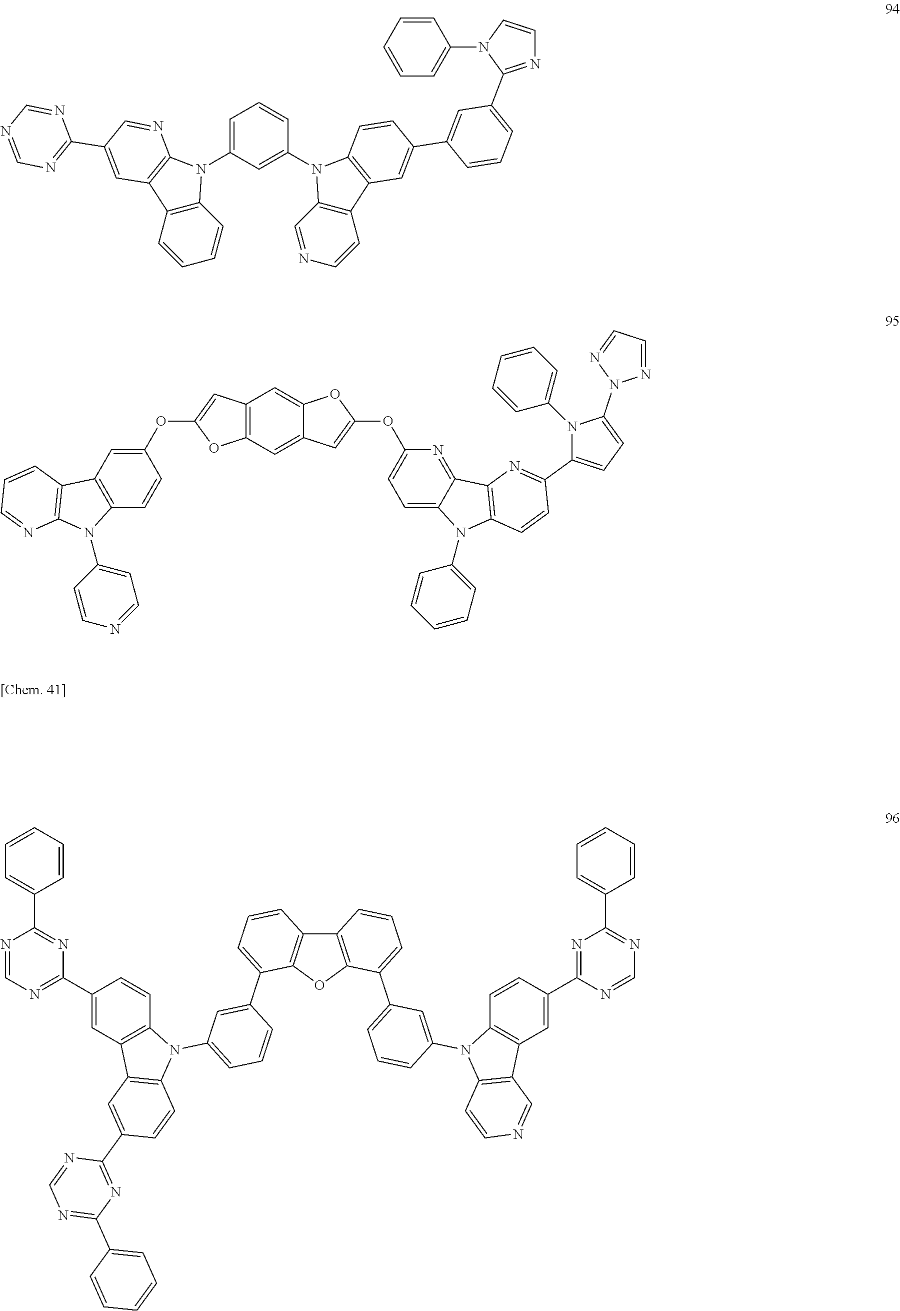

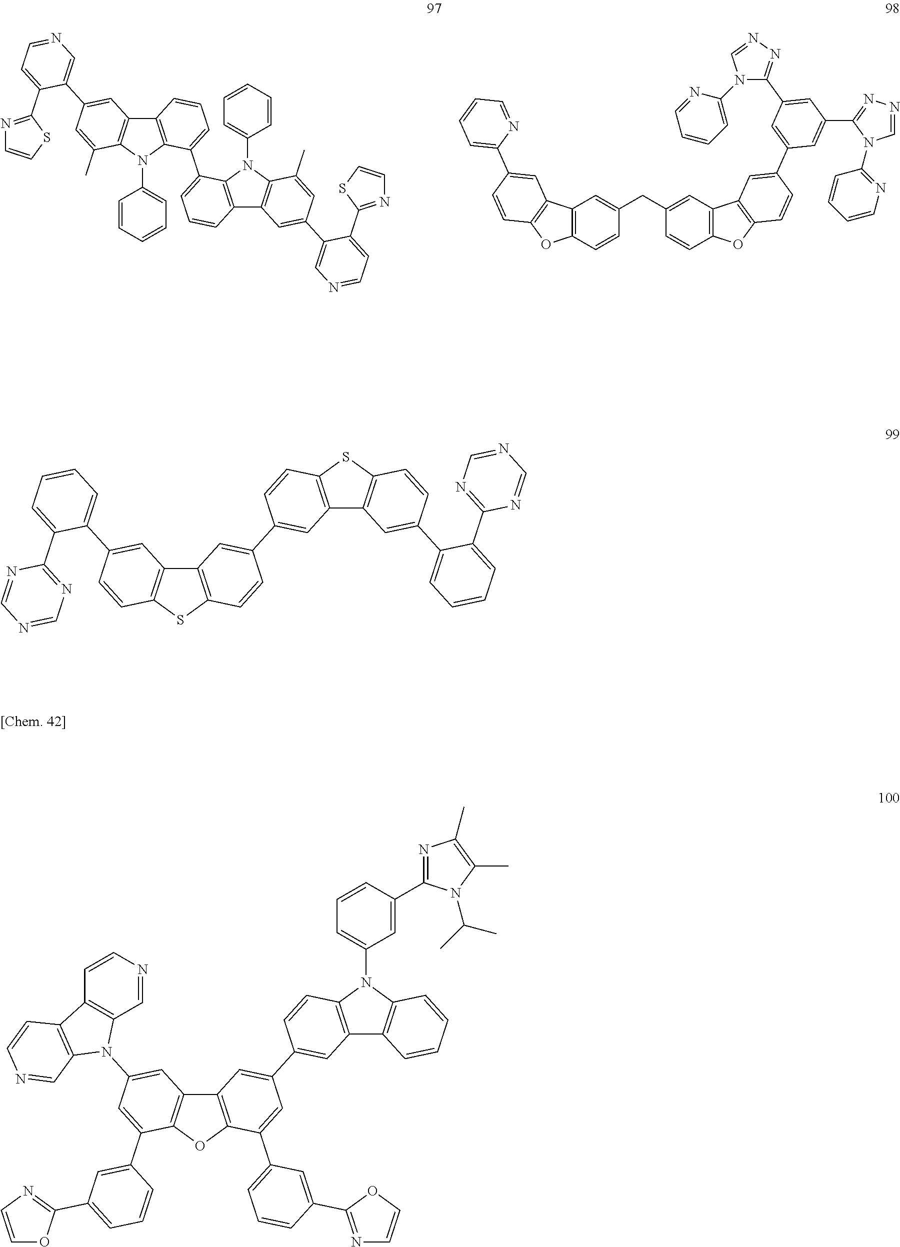

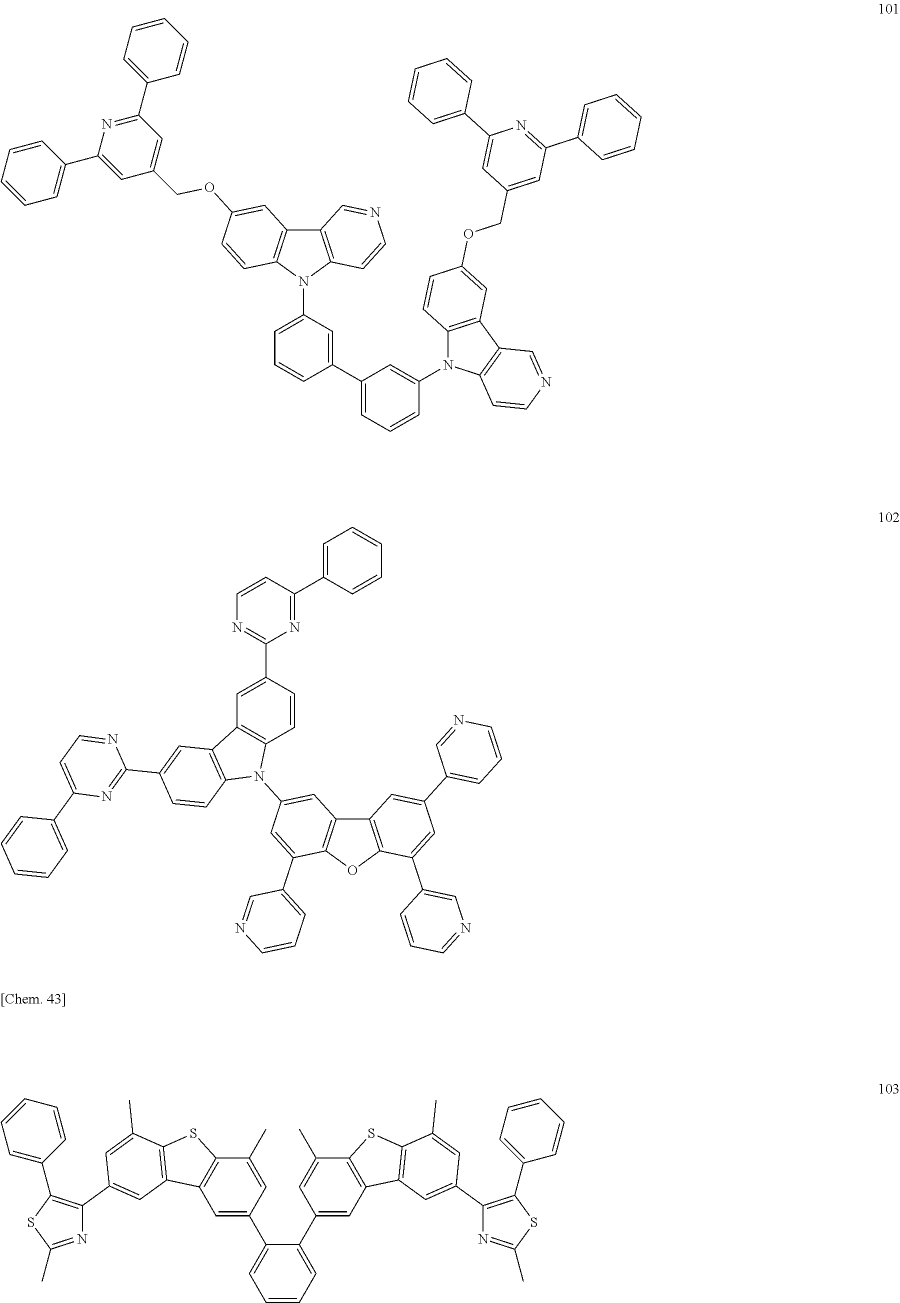

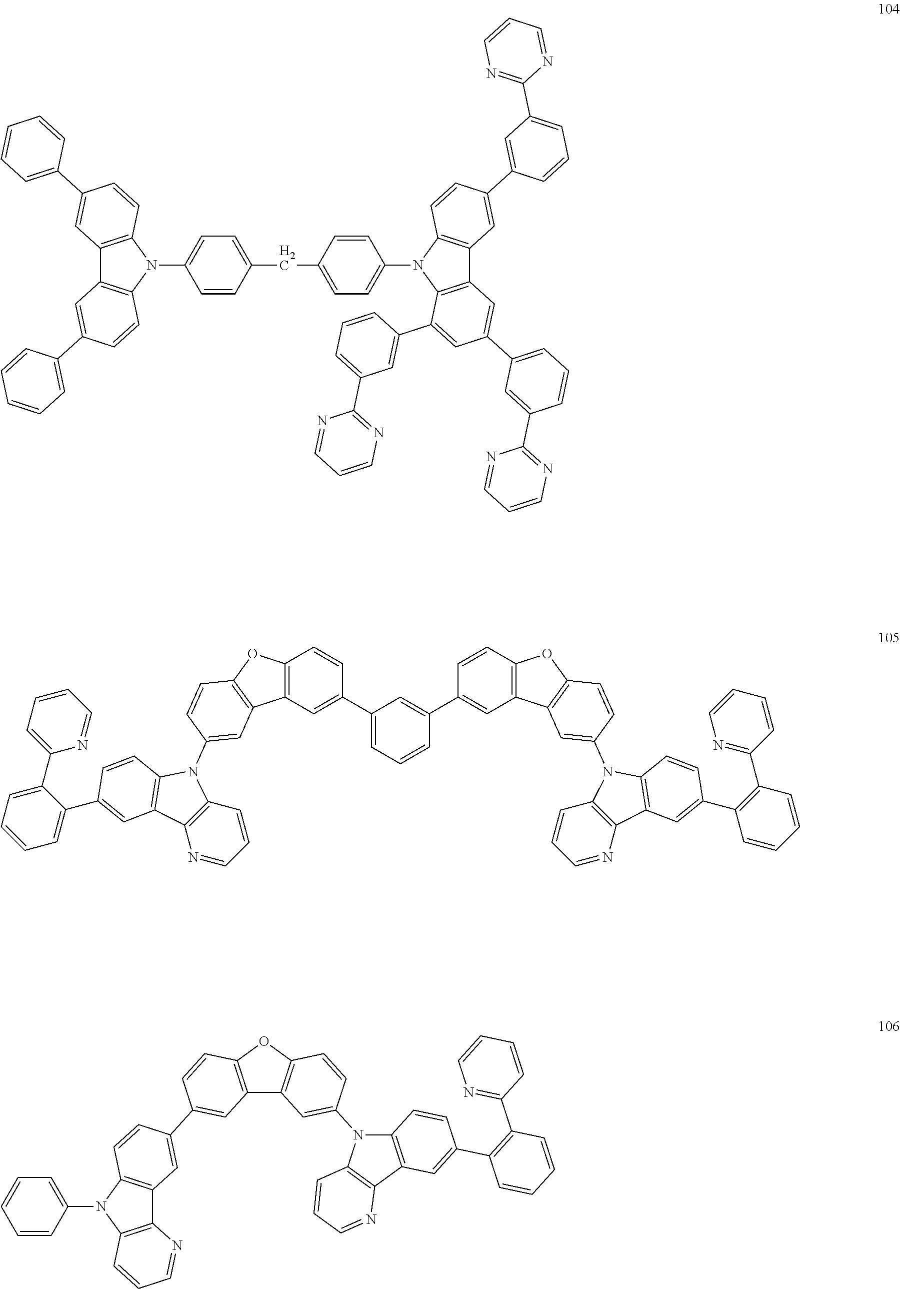

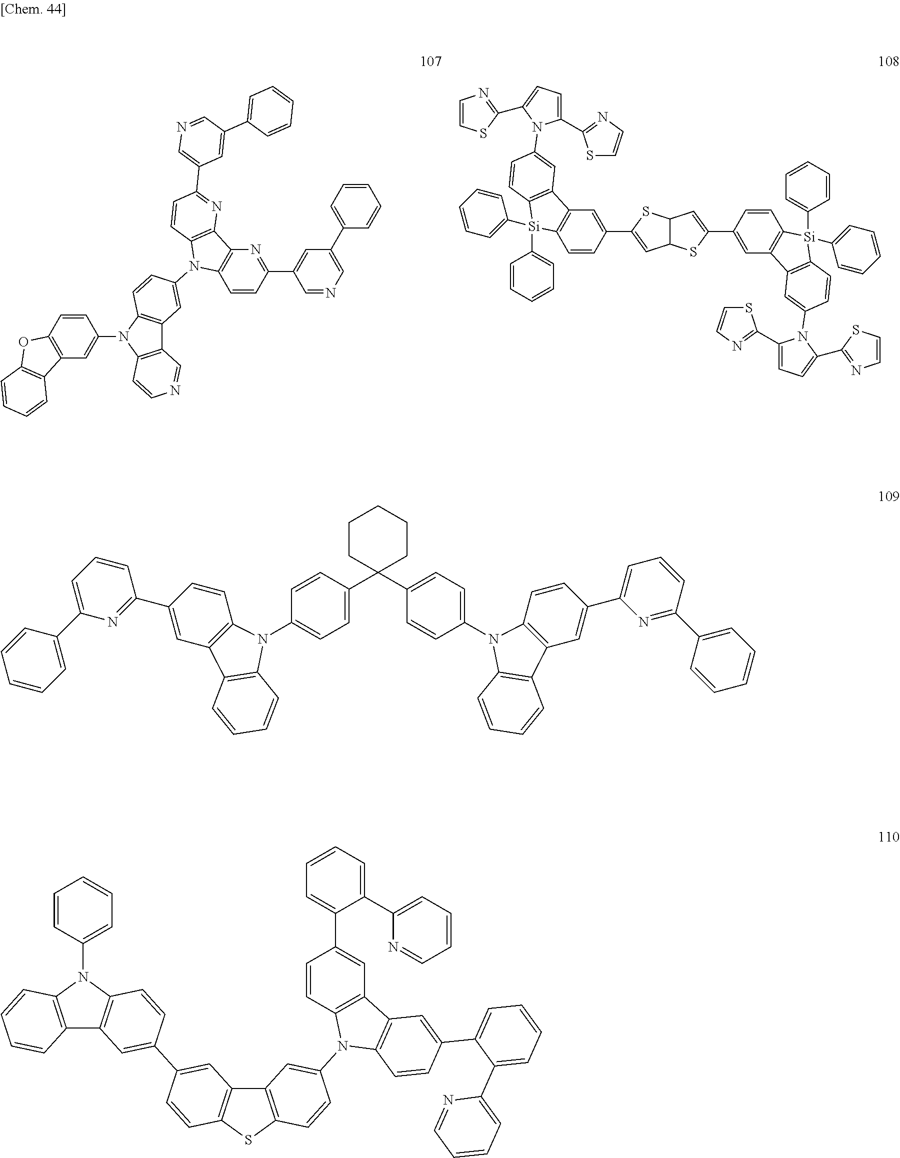

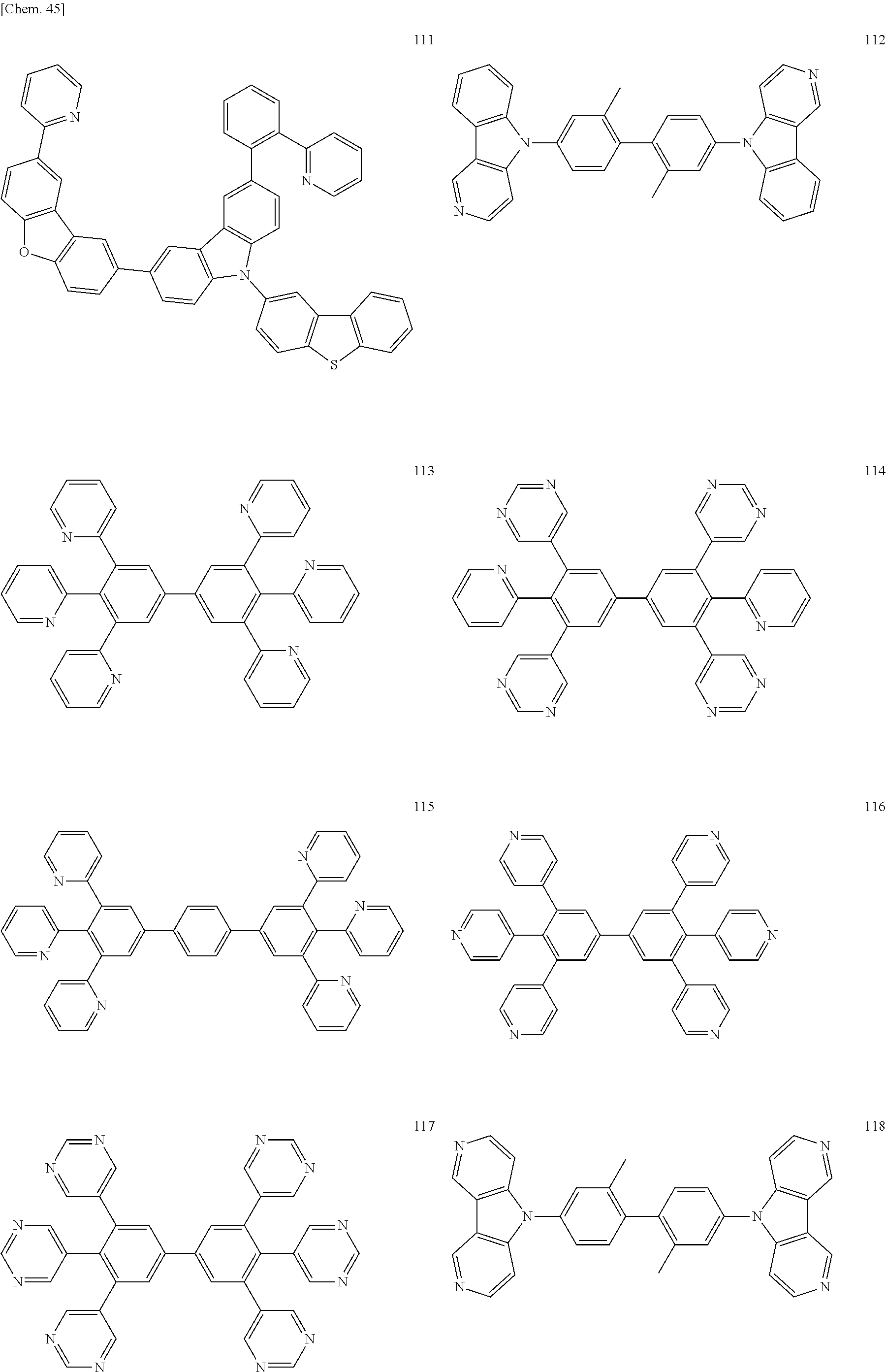

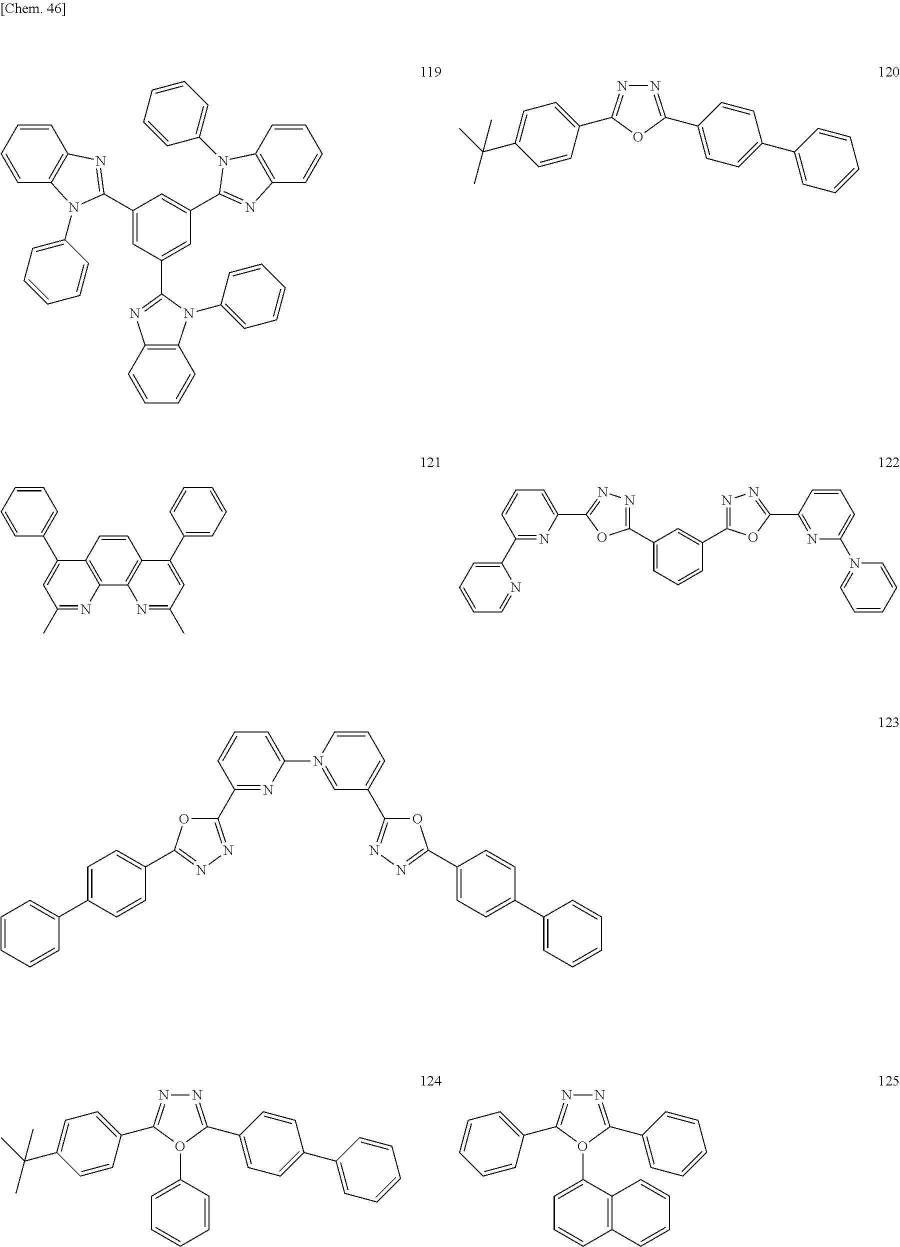

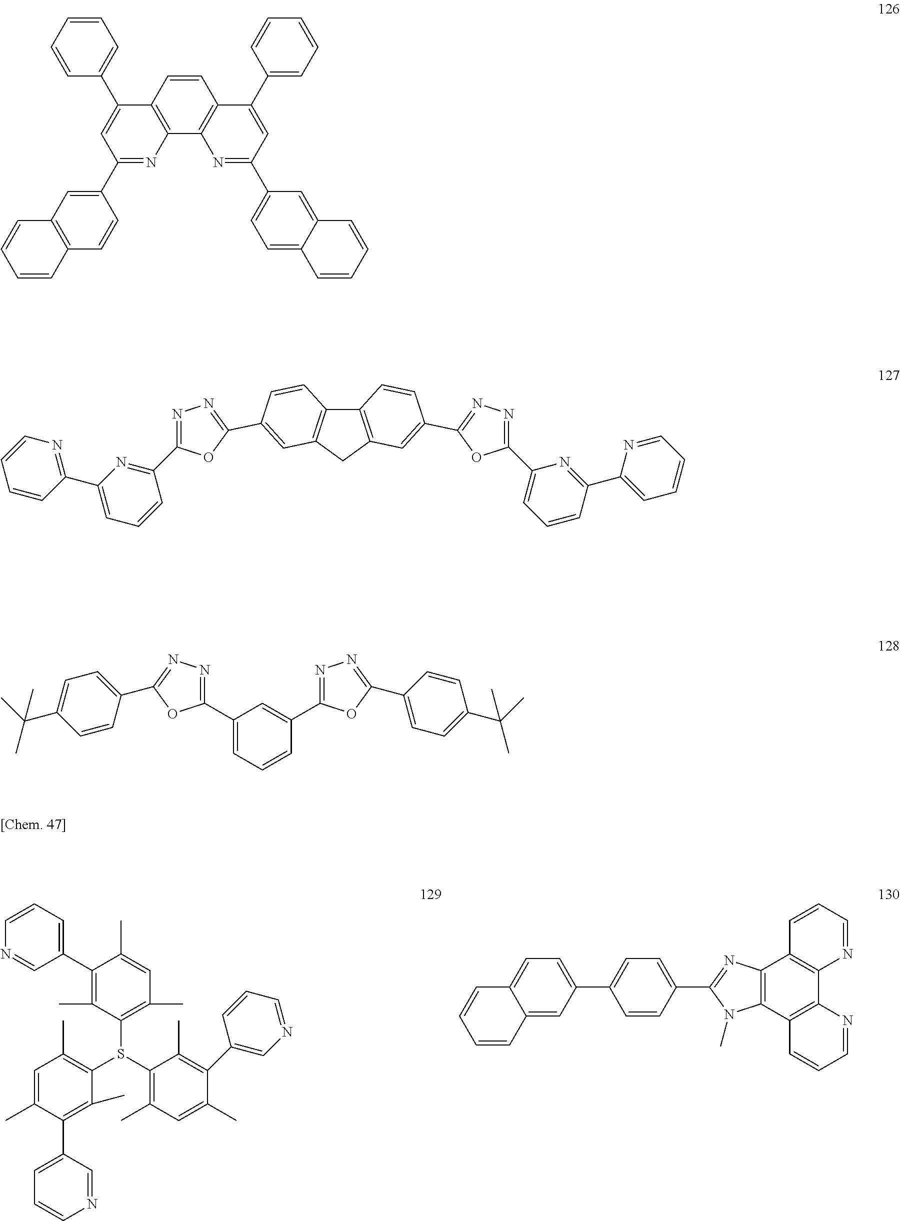

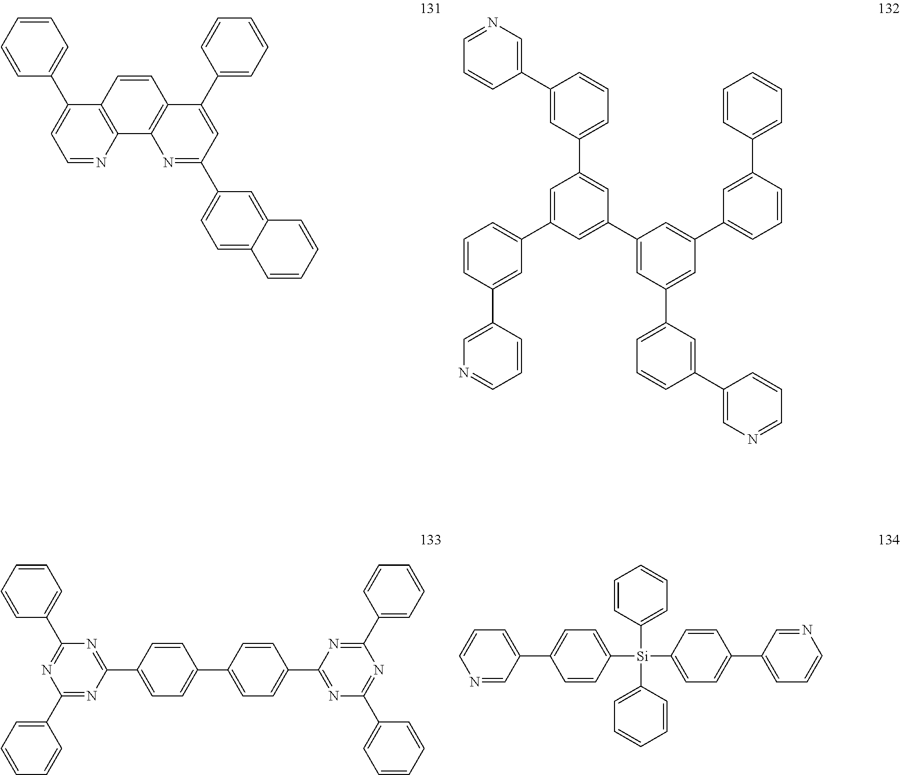

[Synthetic Example of Compound]

Hereinafter, as a synthetic example of a typical compound, a specific synthetic example of Compound 5 will be described, but the present invention is not limited thereto.

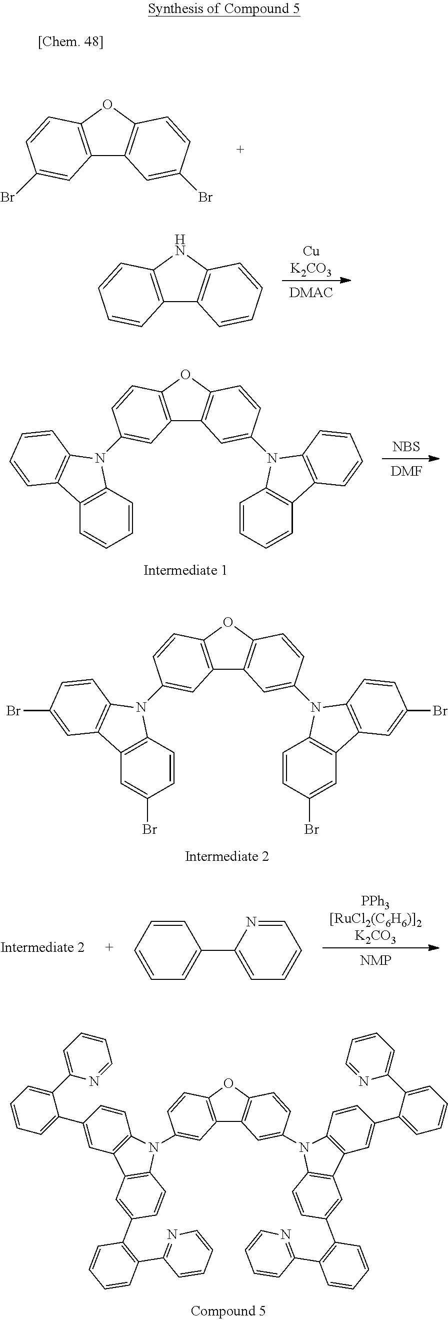

Process 1: Synthesis of Intermediate 1

Under nitrogen atmosphere, 2,8-dibromodibenzofuran (1.0 mole), of carbazole (2.0 moles), copper powder (3.0 moles), potassium carbonate (1.5 moles) were mixed in 300 ml of DMAc (dimethylacetamide) and then stirred for 24 hours at 130° C. After the reaction liquid thus obtained was cooled to room temperature, 1 L of toluene was added to the liquid, the resultant liquid was washed three times with distilled water, the solvent was distilled away from the washed layer under reduced pressure, and purification of the residue with silica gel flash chromatography (n-heptane:toluene=4:1 to 3:1) gave Intermediate 1 at a yield of 85%.

Process 2: Synthesis of Intermediate 2

At room temperature under atmospheric pressure, Intermediate 1 (0.5 mole) was dissolved into 100 ml of DMF (dimethylformamide), NBS (N-bromosuccinic acid imide) (2.0 moles) was added, and then stirred over one night at room temperature. The obtained precipitate was filtered and washed with methanol, with the result that Intermediate 2 was obtained at a yield of 92%.

Process 3: Synthesis of Compound 5

Under nitrogen atmosphere, Intermediate 2 (0.25 mole), 2-phenylpyridine (1.0 mole), ruthenium complex [(η₆-C₆H₆)RuCl₂]₂ (0.05 mole), triphenylphosphine (0.2 mole), potassium carbonate (12 moles) were mixed in 3 L of NMP (N-methyl-2-pyrrolidone), and then stirred over one night at 140° C.

After the reaction liquid was cooled to room temperature, 5 L of dichloromethane was added, and then the liquid was filtered. The solvent was distilled away from the filtrate under reduced pressure (800 Pa, 80° C.), and the residue was purified with silica gel flash chromatography (CH₂Cl₂:Et₃N=20:1 to 10:1).

After the solvent was distilled away under reduced pressure, the residue was again dissolved into dichloromethane and washed three times with water. After the substance obtained by the washing was dried with anhydrous magnesium sulfate, the solvent was distilled away under reduced pressure from the dried substance, with the result that Compound 5 was obtained at a yield of 68%.

[Method of Forming Nitrogen-Containing Layer]

In case where the nitrogen-containing layer is formed on the substrate 11 as mentioned above, the formation methods thereof include a method using a wet process such as a coating method, an inkjet method or a dipping method, and a method using a dry process such as a vapor deposition method (resister heating, EB method and the like), a sputtering method or a CVD method, and the like. Among them, the vapor deposition method is preferably applied.

Particularly, in the case where the nitrogen-containing layer is formed using a plurality of compounds, there is applied a co-vapor deposition method in which a plurality of compounds is supplied at the same time from a plurality of vapor deposition sources. In the case of using a high molecular weight material as a compound, the coating method is preferably applied. In the case, a coating solution in which the compound is dissolved in a solvent is used. The solvent for dissolving the compound is not limited. In the case where the nitrogen-containing layer is formed using a plurality of compounds, a coating solution may be produced using a solvent which can dissolve such a plurality of compounds.

[Organic Functional Layer]

The organic functional layer 14 can exemplify a configuration in which [positive hole injection layer/positive hole transport layer/light-emitting layer/electron transport layer/electron injection layer] are laminated in this order in the upper portion of the first electrode 13 as an anode, and is required to have at least the light-emitting layer constituted by using an organic material. The positive hole injection layer and the positive hole transport layer may be provided as a positive hole transport/injection layer which has the positive hole transporting property and the positive hole injecting property. The electron transport layer and the electron injection layer may be provided as a single layer having the electron transporting property and the electron injecting property. Moreover, in the organic functional layer 14, for example, the electron injection layer may be constituted of an inorganic material.

In addition, in the organic functional layer 14, a positive hole blocking layer and an electron blocking layer also other than these layers may be provided as necessary. Furthermore, the light-emitting layer has various light-emitting layers which generate various emitted lights having various wavelengths, and may be formed as a light-emitting layer unit by laminating the various light-emitting layers via non-emitting intermediate layers. The intermediate layer may function as the positive hole blocking layer and the electron blocking layer.

[Light-Emitting Layer]

The light-emitting layer contains, for example, a phosphorescence-emitting compound as a light-emitting material.

The light-emitting layer is a layer which emits light through recombination of electrons injected from an electrode or an electron transport layer and positive holes injected from the positive hole transport layer. A portion that emits light may be either the inside of the light-emitting layer or an interface between the light-emitting layer and its adjacent layer.

The configuration of the light-emitting layer is not particularly limited as long as the light-emitting material contained therein satisfies a light emission requirement. In addition, there may be a plurality of light-emitting layers having the same emission spectrum and/or emission maximum wavelength. In the case, it is preferable that non-luminescent intermediate layers (not shown) are present between the respective light-emitting layers.

The total thickness of the light-emitting layers is preferably within a range of 1 to 100 nm, and more preferably within a range of 1 to 30 nm from the viewpoint of obtaining a lower driving voltage. Note that the total thickness of the light-emitting layers is a thickness including the thickness of the intermediate layers when the non-luminescent intermediate layers are present between the light-emitting layers.

In the case of the light-emitting layer constituted by lamination of a plurality of layers, it is preferable to adjust the thickness of individual light-emitting layer to be within a range of 1 to 50 nm and it is more preferable to adjust the thickness thereof to be within a range of 1 to 20 nm. When the plurality of the laminated light-emitting layers corresponds to the emitted color of blue, green and red, respectively, the relationship between the respective thicknesses of the light-emitting layers of blue, green and red is not particularly limited.

The above light-emitting layer can be formed by a well-known thin film forming method such as a vacuum vapor deposition method, a spin coating method, a casting method, an LB method or an ink-jet method of a light-emitting material and a host compound, which are described below.

In addition, in the light-emitting layer, a plurality of light-emitting materials may be mixed. Furthermore, a fluorescence-emitting material and a fluorescence-emitting material (also referred to as fluorescence-emitting dopant, fluorescence-emitting compound) may be mixed in the same light-emitting layer.

It is preferable that the light-emitting layer is constituted so as to contain a host compound (also referred to as emitting host) and a light-emitting material (also referred to as light-emitting dopant compound, a guest compound), and emit light through the light-emitting material.

(Host Compound)

The host compound contained in the light-emitting layer is preferably a compound having a phosphorescence quantum yield in phosphorescence emission of less than 0.1 at room temperature (25° C.). In addition, the host compound more preferably has a phosphorescent quantum yield of less than 0.01. Furthermore, among the compounds contained in the light-emitting layer, a volume ratio in the layer of 50% or more is preferable.

A well-known host compound may be used as the host compound, alone or in combination of a plurality of kinds. The use of a plurality of host compounds makes it possible to adjust transfer of charges, and to increase an efficiency of the organic EL element 10. Furthermore, the use of a plurality of light-emitting materials described below makes it possible to mix different colors of light to be emitted, and to thereby obtain any luminous color.

The host compound to be used may be a well-known low molecular weight compound, a high molecular compound having a repeating unit or a low-molecular-weight compound having a polymerizable group such as a vinyl group or an epoxy group (evaporation-polymerizable light emission host) may be used.

The well-known host compound is preferably a compound preventing a light emission wavelength from becoming longer and having a high Tg (glass transition temperature), while having a positive hole transport ability and an electron transport ability. The glass transition temperature Tg herein is a value measured using DSC (Differential Scanning Colorimetry) in accordance with JIS-K-7121.

Examples of the host compound which is applicable to the organic electroluminescent element include the compound H1 to H79 described in Paragraphs [0163] to [0178] of Japanese Patent Laid-Open No. 2013-4245. The compounds H1 to H79 described in Paragraphs [0163] to [0178] of Japanese Patent Laid-Open No. 2013-4245 are incorporated into the present description.

Furthermore, specific examples of other well-known host compounds include compounds described in the following documents; for example, Japanese Patent Laid-Open Nos. 2001-257076, 2002-308855, 2001-313179, 2002-319491, 2001-357977, 2002-334786, 2002-8860, 2002-334787, 2002-15871, 2002-334788, 2002-43056, 2002-334789, 2002-75645, 2002-338579, 2002-105445, 2002-343568, 2002-141173, 2002-352957, 2002-203683, 2002-363227, 2002-231453, 2003-3165, 2002-234888, 2003-27048, 2002-255934, 2002-260861, 2002-280183, 2002-299060, 2002-302516, 2002-305083, 2002-305084 and 2002-308837.

(Light-Emitting Material)

The light-emitting material that can be used in the organic electroluminescent element of the present embodiment includes a phosphorescence-emitting compound (also referred to as a phosphorescent compound or a phosphorescence-emitting material).

The phosphorescence-emitting compound is defined as a compound in which light emission from an excited triplet state is observed, and, specifically, a compound which emits phosphorescence at room temperature (25° C.) and a phosphorescence quantum yield at 25° C. is 0.01 or more, and preferable phosphorescence quantum yield is 0.1 or more.

The above-described phosphorescence quantum yield can be measured by a method described on page 398 of Bunko II of Dai 4 Han Jikken Kagaku Koza 7 (Spectroscopy II of Lecture of Experimental Chemistry vol. 7, 4th edition) (1992, published by Maruzen Co., Ltd.). The phosphorescence quantum yield in a solution can be measured using various solvents, and when the phosphorescence-emitting compound used in the example, it is sufficient that the above-described phosphorescence quantum yield (0.01 or more) is achieved in any of arbitrary solvents.

There are two kinds of principles regarding light emission of the phosphorescence-emitting compound. One is an energy transfer type, wherein carriers recombine on a host compound which transfers the carriers so as to produce an excited state of the host compound, this energy is transferred to a phosphorescence-emitting compound, and then light emission from the phosphorescence-emitting compound is carried out. The other is a carrier trap-type, in which a phosphorescence-emitting compound serves as a carrier trap, carriers recombine on the phosphorescence-emitting compound, and then light emission from the phosphorescence-emitting compound is carried out. In either case, the excited state energy of the phosphorescence-emitting compound is required to be lower than that of the host compound.

The phosphorescence-emitting compound can be suitably selected and used from the well-known phosphorescence-emitting compounds used for light-emitting layers of general organic electroluminescent elements, preferably a complex-based compound containing metal of the groups 8 to 10 in the element periodic table, and more preferably an iridium compound, an osmium compound, a platinum compound (a platinum complex-based compound) or a rare earth complex, and most preferably an iridium compound.

In the organic electroluminescent element of the present embodiment, at least one light-emitting layer may contain two or more kinds of phosphorescence-emitting compounds, and a ratio of concentration of the phosphorescence-emitting compound in the light-emitting layer may vary in the direction of thickness of the light-emitting layer.

An amount of the phosphorescence-emitting compound is preferably 0.1% by volume or more and less than 30% by volume to the total volume of the light-emitting layer.

Examples of the phosphorescence emitting compound which is applicable to the organic electroluminescent element include preferably the compounds represented by the general formula (4), the general formula (5), the general formula (6) and the exemplified compounds described in Paragraphs [0185] to [0235] of Japanese Patent Laid-Open No. 2013-4245. As the other exemplified compounds, the following Ir-46, Ir-47, Ir-48 are shown. The compounds represented by the general formula (4), the general formula (5), the general formula (6) and the exemplified compounds (Pt-1 to Pt-3, Os-1, Ir-1 to Ir-45) described in Paragraphs [0185] to [0235] of Japanese Patent Laid-Open No. 2013-4245 are incorporated into the present description.

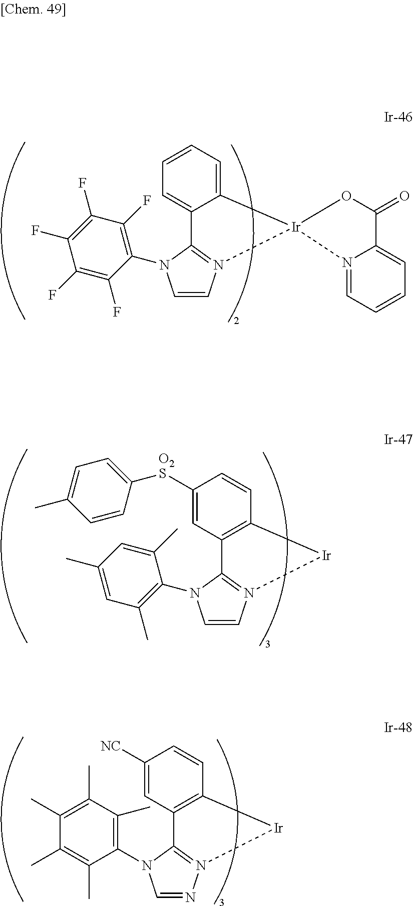

Note that, in a preferable aspect, each of these phosphorescence-emitting compounds (also referred to as phosphorescence-emitting metal complexes) is contained in the light-emitting layer of the organic EL element 10 as a light-emitting dopant, and may be contained in an organic functional layer in the layer other than the light-emitting layer.

Furthermore, the phosphorescence-emitting compound can be suitably selected and used from the well-known phosphorescence-emitting compounds used for light-emitting layers of organic EL elements 10.

The above-described phosphorescence-emitting compounds (also referred to as phosphorescence-emitting metal complexes and the like) can be synthesized by employing methods described in documents such as Organic Letters, vol. 3, No. 16, pp. 2579-2581 (2001); Inorganic Chemistry, vol. 30, No. 8, pp. 1685-1687 (1991); J. Am. Chem. Soc., vol. 123, p. 4304 (2001); Inorganic Chemistry, vol. 40, No. 7, pp. 1704-1711 (2001); Inorganic Chemistry, vol. 41, No. 12, pp. 3055-3066 (2002); New Journal of Chemistry, vol. 26, p. 1171 (2002); and European Journal of Organic Chemistry, vol. 4, pp. 695-709 (2004); and reference documents described in these documents.

(Fluorescence-Emitting Material)

Examples of the fluorescence-emitting material include a coumarin-based dye, a pyran-based dye, a cyanine-based dye, a croconium-based dye, a squarylium-based dye, an oxobenzanthr dye acene-based dye, a fluorescein-based dye, a rhodamine-based dye, a pyrylium-based dye, a perylene-based dye, a stilbene-based dye, a polythiophene-based dye, or a rare earth complex-based fluorescent material or the like.

[Injection Layer: Positive Hole Injection Layer, Electron Injection Layer]

The injection layer is a layer disposed between an electrode and the light-emitting layer in order to decrease a driving voltage and to enhance luminance of light emitted, which is detailed in Part 2, Chapter 2 “Denkyoku Zairyo” (pp. 123-166) of “Yuki EL Soshi To Sono Kogyoka Saizensen (Nov. 30, 1998, published by N. T. S Co., Ltd.)”, and examples thereof include a positive hole injection layer and an electron injection layer.

The injection layer can be provided as necessary. The positive hole injection layer is disposed between an anode and the light-emitting layer or the positive hole transport layer, and the electron injection layer is disposed between a cathode and the light-emitting layer or the electron transport layer.

The positive hole injection layer is also detailed in documents such as Japanese Patent Laid-Open Nos. 9-45479, 9-260062 and 8-288069, and examples include a phthalocyanine layer represented by copper phthalocyanine, an oxide layer represented by vanadium oxide, an amorphous carbon layer, a polymer layer employing a conductive polymer such as polyaniline (emeraldine) or polythiophene, and the like.

The electron injection layer is also detailed in documents such as Japanese Patent Laid-Open Nos. 6-325871, 9-17574 and 10-74586 and examples include: a metal layer represented by strontium or aluminum, an alkali metal halide layer represented by potassium fluoride, an alkali earth metal compound layer represented by magnesium fluoride, an oxide layer represented by molybdenum oxide, and the like. It is preferable that the electron injection layer is a very thin film, and the thickness thereof is within a range of 1 nm to 10 μm although it depends on the material thereof.

[Positive Hole Transport Layer]

The positive hole transport layer is formed of a positive hole transport material having a function of transporting positive holes, and a positive hole injection layer and an electron blocking layer are also included in the positive hole transport layer in the broad sense of the word. The positive hole transport layer can be provided as a single layer or as a plurality of layers.

The positive hole transport material is a material having an injection capability or transport capability of positive holes, and barrier property against electrons and either an organic substance or an inorganic substance may be used. Examples include a triazole derivative, an oxadiazole derivative, an imidazole derivative, a polyarylalkane derivative, a pyrazoline derivative and a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline-based copolymer, and a conductive high molecular oligomer, particularly, a thiophene oligomer and the like.

Those described above can be used as the positive hole transport material. However, it is preferable to use a porphyrin compound, an aromatic tertiary amine compound and a styrylamine compound, particularly, an aromatic tertiary amine compound.

Typical examples of the aromatic tertiary amine compound and the styrylamine compound include N,N,N′,N′-tetraphenyl-4,4′-diaminophenyl; N,N′-diphenyl-N,N′-bis(3-methylphenyl)-[1,1′-biphenyl]-4,4′-diamine (TPD); 2,2-bis(4-di-p-tolylaminophenyl)propane; 1,1-bis(4-di-p-tolylaminophenyl)cyclohexane; N,N,N′,N′-tetra-p-tolyl-4,4′-diaminobiphenyl; 1,1-bis(4-di-p-tolylaminophenyl)-4-phenylcyclohexane; bis(4-dimethylamino-2-metylphenyl)phenylmethane; bis(4-di-p-tolylaminophenyl)phenylmethane; N,N′-diphenyl-N,N′-di(4-methoxyphenyl)-4,4′-diaminobiphenyl N,N,N′,N′-tetraphenyl-4,4′-diaminodiphenylether; 4,4′-bis(diphenylamino)quadriphenyl; N,N,N-trip-tolyl)amine; 4-(di-p-tolylamino)-4′-[4-(di-p-tolylamino)styryl]stilbene; 4-N, N-diphenylamino-(2-diphenylvinyl)benzene; 3-methoxy-4′-N,N-diphenylaminostilbenzene; N-phenylcarbazole; those having two condensed aromatic rings in a molecule described in U.S. Pat. No. 5,061,569, for instance, 4,4′-bis[N-(1-naphthyl)-N-phenylamino]biphenyl (NPD), 4,4′,4″-tris[N-(3-methylphenyl)-N-phenylamino]triphenylamin e (MTDATA) in which three triphenylamine units are bonded in a star burst form described in Japanese Patent Laid-Open No. 04-308688 and the like.

Furthermore, polymer materials in which these materials are introduced into a polymer chain or constitute a main chain of a polymer can also be used. In addition, inorganic compounds such as a p-type-Si and a p-type-SiC can also be used as the positive hole injection material and the positive hole transport material.

Moreover, it is also possible to use so-called p-type positive hole transport materials described in documents such as Japanese Patent Laid-Open No. 11-251067 and Applied Physics Letters 80 (2002), p. 139 by J. Huang et. al. It is preferable to use these materials in view of being able to obtain a light-emitting element having high efficiency.

The positive hole transport layer can be formed by making the above-described positive hole transport material a thin film by a well-known method such as the vacuum vapor deposition method, the spin coating method, the casting method, the printing method including the ink-jet method or the LB method. The thickness of the positive hole transport layer is not particularly limited, but the thickness is generally within a range about of 5 nm to 5 μm, preferably within a range of 5 to 200 nm. This positive hole transport layer may have a single layer structure constituted of one or two or more of the above-described materials.

Furthermore, it is possible to enhance the p property by doping the material of the positive hole transport layer with impurities. Examples include those described in documents such as Japanese Patent Laid-Open Nos. 04-297076, 2000-196140, 2001-102175 and J. Appl. Phys., 95, 5773 (2004).

As described above, it is preferable that enhancement of a high p property of the positive hole transport layer makes it possible to produce an element which consumes lower electric power.

[Electron Transport Layer]

The electron transport layer is formed of a material having a function of transporting electrons, and in a broad sense, the electron injection layer and a positive hole blocking layer (not shown) are included in the electron transport layer. The electron transport layer can be provided as a single layer or a laminated layer of a plurality of layers.

In the electron transport layer having a single layer structure and the electron transport layer having a laminated layer structure, the electron transport material constituting a layer provided adjacent to the light-emitting layer has a function of transporting electrons injected from the cathode to the light-emitting layer. The material described above can be optionally selected and used from well-known compounds. Examples include a nitro-substituted fluorene derivative, a diphenylquinone derivative, a thiopyrandioxide derivative, carbodiimide, a fluorenylidenemethane derivative, anthraquinonedimethane, an anthrone derivative, and an oxadiazole derivative and the like. Furthermore, in the above-described oxadiazole derivative, a thiadiazole derivative which is formed by substituting the oxygen atom of the above oxadiazole ring by a sulfur atom, and a quinoxaline derivative having a quinoxaline ring which is well-known as an electron withdrawing group can be used as the material of the electron transport layer. Moreover, polymer materials in which these materials are introduced into a polymer chain or constitute a main chain of a polymer can also be used.

Additionally, metal complexes of an 8-quinolinol derivative such as: tris(8-quinolinol)aluminum (Alq3), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum and bis(8-quinolinol) zinc (Znq), and metal complexes in which the central metal of the these metal complexes is substituted by In, Mg, Cu, Ca, Sn, Ga or Pb can also be used as the material of the electron transport layer.

Additionally, a metal-free or metalphthalocyanine and those in which the terminals thereof are substituted by an alkyl group, a sulfonic acid group or the like can be preferably used as the material of the electron transport layer. Moreover, the distyrylpyrazine derivative mentioned as an example of the material of the light-emitting layer can also be used as the material of the electron transport layer, and in the same way as the positive hole injection layer and the positive hole transport layer, inorganic semiconductors such as an n type-Si and an n type-SiC can also be used as the material of the electron transport layer.

The electron transport layer can be formed by thinning the above-described electron transport material by a well-known method such as the vacuum vapor deposition method, the spin coating method, the casting method, the printing method including the ink-jet method or the LB method. The thickness of the electron transport layer is not particularly limited, but the thickness is generally within a range of 5 nm to 5 μm, preferably within a range of 5 to 200 nm. This electron transport layer may have a single layer structure constituted of one or two or more of the above-described materials.

Furthermore, it is possible to enhance the n property by doping impurities into the electron transport layer. Examples thereof include those described in documents such as Japanese Patent Laid-Open Nos. 04-297076, 10-270172, 2000-196140 and 2001-102175 and J. Appl. Phys., 95, 5773 (2004). Moreover, it is preferable to introduce potassium or a potassium compound into the electron transport layer. Examples of the potassium compound that can be used include, for example, potassium fluoride, and the like. As described above, by enhancement of an n property of the electron transport layer, an element which consumes lower electric power can be produced.

Moreover, it is preferable to use, for example, the above nitrogen-containing compounds of compound No. 1 to No. 45, the nitrogen-containing compounds having the structure represented by the above general formulae (1) to (6), the above nitrogen-containing compounds of 1 to 134, as the material of the electron transport layer (compound having electron transporting property).

[Blocking Layer: Positive Hole Blocking Layer, Electron Blocking Layer]

The blocking layer is provided as necessary in addition to the basic constituent layers of thin organic compound films described above. Examples thereof include a positive hole blocking layer described in documents such as Japanese Patent Laid-Open Nos. 11-204258, 11-204359, and p. 237 of “Yuki EL Soshi To Sono Kogyoka Saizensen (Organic EL Element and Front of Industrialization thereof) (Nov. 30, 1998, published by N. T. S Co., Ltd.)”, and the like.

The positive hole blocking layer has a function of the electron transport layer in a broad sense. The positive hole blocking layer is formed of a positive hole blocking material having a remarkably small capability to transport positive holes while having a function of transporting electrons and can increase recombination probability of electrons and positive holes by blocking positive holes while transporting electrons. Furthermore, as necessary, the configuration of an electron transport layer described below can be used as the positive hole blocking layer. It is preferable that the positive hole blocking layer is provided adjacent to the light-emitting layer.

On the other hand, the electron blocking layer has a function as the positive hole transport layer in abroad sense. The electron blocking layer is formed of a material having a very little capability to transport electrons while having a function of transporting positive holes, and can increase the recombination probability of electrons and positive holes by blocking electrons while transporting positive holes. Furthermore, as necessary, the configuration of a positive hole transport layer described below can be applied to the electron blocking layer. The thickness of the positive hole blocking layer according to the present invention is preferably 3 to 100 nm, more preferably 5 to 30 nm.

The covering intermediate layer 16 is formed so as to cover the portion, on the substrate 11 having the barrier layer 12, other than a portion where the light-emitting laminate 19 composed of the first electrode 13, the organic functional layer 14 and the second electrode 15 are arranged.

The covering intermediate layer 16 is a member which seals the light-emitting laminate 19 composed of the first electrode 13, the organic functional layer 14 and the second electrode 15 together with the sealing member 18 and the sealing resin layer 17. Therefore, it is preferable to use a material having a function of suppressing intrusion of water and oxygen which degrade the light-emitting laminate 19, for the covering intermediate layer 16.

In addition, since the covering intermediate layer 16 has a configuration of making direct contact with the barrier layer 12 and the sealing resin layer 17, it is preferable to use a material which is excellent in joining property to the barrier layer 12 and the sealing resin layer 17.

The covering intermediate layer 16 is preferably formed of a compound having a high sealing property such as an inorganic oxide, an inorganic nitride or an inorganic carbide.

Specifically, the covering intermediate layer 16 can be formed by SiGₓ, Al₂O₃, In₂O₃, TiGₓ, ITO (tin indium oxide), AlN, Si₃N₄, SiGₓN, TiOₓN, SiC, and the like.

The covering intermediate layer 16 can be formed by a known procedure such as a sol-gel method, a vapor deposition method, a CVD, an ALD (Atomic Layer Deposition), a PVD, or a spattering method.

Furthermore, in the atmospheric pressure plasma method, there can be separately made the composition, of the covering intermediate layer 16, of: a silicon oxide; an inorganic oxide having a silicon oxide as a main component; or a mixture of an inorganic carbide, an inorganic nitride, an inorganic sulfide, and an inorganic halide such as an inorganic oxide nitride or an inorganic oxide halide, by selection of conditions such as an organic metal compound that is a raw material (referred to as a raw starting material), decomposition gas, decomposing temperature and applied power.

For example, silicon oxide is produced by using a silicon compound as a raw material compound and oxygen as a decomposition gas. Additionally, silicon nitride oxide is produced by using a silazane as a raw material compound. This is because, in a plasma space, very high actively charged particles or active radicals exist at a high density, and thus a multi-stage chemical reaction is accelerated at a high speed in the plasma space and the elements in the plasma space are converted to chemically stable compounds in an extremely short time.

The state of the raw material for forming the covering intermediate layer 16 may be any of gas, liquid and solid at room temperature under normal pressure as long as the raw material is a silicon compound. In the case of gas, the gas can be directly introduced into the discharge space, but in the case of liquid or solid, the liquid or solid is used after vaporization by a means such as heating, bubbling, decompression, or ultrasonic irradiation. The raw material may be used after dilution with a solvent. An organic solvent such as methanol, ethanol, n-hexane and a mixture thereof can be used as such a solvent. Note that the influence of the solvent can be almost ignored because each of these diluent solvents is decomposed into a molecular or an atomic state during the plasma discharge treatment.

Examples of the silicon compound include silane, tetramethoxysilane, tetraethoxysilane, tetra-n-propoxysilane, tetra-iso-propoxsilane, tetra-n-butoxysilane, tetra-t-butoxysilane, dimethyldimethoxysilane, dimethyldiethoxysilane, diethyldimethoxysilane, diphenylsimethoxysilane, methyltriethoxysilane, ethyltrimethoxysilane, phenyltriethoxysilane, (3,3,3-trifluoropropyl)trimethoxysilane, hexamethyldisyloxane, bis(dimethylamino)dimethylsilane, bis(dimethylamino)methylvinylsilane, bis(ethylamino)dimethylsilane, N,O-bis(trimethylsilyl)acetoamide, bis(trimethylsilyl)carbodiimide, diethylaminotrimethylsilane, dimethylaminodimethylsilane, hexamethyldisilazane, heaxamethylcyclotrisilazane, heptamethylsilazane, nonamethyltrisilazane, octamethylcyclotetrasilazane, tetrakisdimethyaminosilazane, tetraisocyanatesilane, tetramethyldisilazane, tris(dlmethylamino)silane, triethoxyfluorosilane, allyldimethylsilane, allyltrimethylsilane, benzyltrimethylsilane, bis(trimethylsilyl)acetylene, 1,4-bistrimethylsilyl-1,3-butadiine, di-t-butylsilane, 1,3-disilabutane, bis(trimethylsilyl)methane, cyclopentanedienyltrimethylsilane, phenyldimethylsilane, phenyltrimethylsilane, propagyltrimethylsilane, tetramethylsilane, trimethylsilylacetylene, 1-(trimethylsilyl)-1-propine, tris(trimehtylsilyl)methane, tris(trimethylsilyl)silane, vinyltrimethylsilane, hexamethyldisilane, octamethylcyclotetrasiloxane, tetramethylcyclotetrasiloxane, heaxmethylcycrotetrasiloxane, M-silicate 51, and the like.

Furthermore, examples of the decomposition gas for decomposing the raw material gas containing silicon and obtaining the covering intermediate layer 16 include hydrogen gas, methane gas, acetylene gas, carbon monoxide gas, carbon dioxide gas, nitrogen gas, ammonium gas, nitrogen monoxide gas, nitrogen oxide gas, nitrogen dioxide gas, oxygen gas, steam, fluorine gas, hydrogen fluoride, trifluoroalcohol, trifluorotoluene, hydrogen sulfide, sulfur dioxide, carbon disulfide, chlorine gas, and the like.

The covering intermediate layer 16 containing silicon oxide, nitride gas, carbide and the like can be obtained by appropriately selecting the above raw material gas containing silicon and the decomposition gas.

In the atmospheric pressure plasma method, such a reactive gas is mixed with a discharge gas that easily reaches a plasma state, and then the resultant mixed gas is sent to a plasma discharge generation device. Nitrogen gas and/or an element of Group 18 of periodic table such as helium, neon, argon, krypton, xenon or radon are used as such a discharge gas. Among them, nitrogen, helium and argon are preferably used.

A film formation is carried out by mixing the discharge gas and the reactive gas, and then, as a gas (mixed gas) for forming a thin film, supplying the resultant mixed gas to the plasma discharge (plasma generation) device. Although the ratio between the discharge gas and the reactive gas varies depending on the properties of the layer to be formed, the reactive gas is supplied so that a ratio of the discharge gas to the entire mixed gases is 50% or more.

[Sealing Member]

A sealing member 18 is a material for covering the organic EL element 10, and a plate-like (film-like) sealing member 18 is fixed to a substrate 11 by a sealing resin layer 17. The sealing member 18 is provided in a state of exposing the organic EL element 10 and the terminal part (not shown) of the second electrode 15. In addition, the sealing member 18 may be constituted so that an electrode is provided on the sealing member 18, and the electrode is electrically conducted with the organic EL element 10 and the terminal part of the second electrode 15, in the organic EL element 10.

The substrate 11 having the above barrier layer 12 can be used as the sealing member 18.

A metal foil obtained by laminating a resin film (polymer film) is preferably used as the sealing member 18. Although the metal foil obtained by laminating a resin film cannot be used as the substrate 11 on the lighting side, but the foil is a low-cost sealing material having a low moisture permeability. Thus, the foil is suitable for the sealing member 18 which is not intended for light extraction.

Note that the metal foil is different from a metallic thin film formed by spattering or vapor deposition, or an electrically conductive film formed from a flowable material for an electrode such as an electrically conductive paste, and refers to a foil or film of a metal formed by rolling method, or the like.

The metal foil is not limited to the type of metal, and examples of the metal foil include a copper (Cu) foil, aluminum (Al) foil, gold (Au) foil, brass foil, nickel (Ni) foil, titanium (Ti) foil, copper alloy, stainless steel foil, tin (Sn) foil and high-nickel allow foil. Among these various metal foils, particularly preferable metal foil is the Al foil.

The thickness of the metal foil is preferably 6 to 50 μm. When the thickness is less than 6 μm, a pin hole may be created at the time of use, depending on the type of the material used for the metal foil, and there is a case where the required barrier function (moisture permeability, oxygen permeability) cannot be obtained. When the thickness is more than 50 μm, there is a case where the production cost is increased depending on the type of the material used for the metal foil, or the thickness of the organic EL element 10 is increased, with the result that the advantages of using the film-like sealing member 18 may be decreased.

In the metal foil with the resin film laminated thereon, various materials disclosed in the “New Development in the Functional Packaging Materials” (Toray Research Center) can be used as the resin film. Examples that can be used include polyethylene resin, polypropylene resin, polyethylene terephthalate resin, polyamide resin, ethylene-vinyl alcohol copolymer resin, ethylene-vinyl acetate copolymer resin, acrylonitryl-butadiene copolymer resin, cellophane resin, vinylon resin, polyvinylidene chloride, and the like. Resins such as the polypropylene resin and nylon resin may be drawn, or may be coated with the polyvinylidene chloride resin. Furthermore, the polyethylene resin of either a low density or a high density may be used.

A plate-like or film-like substrate can be used as the sealing member 18. For example, a glass substrate and a polymer substrate are included, and these substrate materials may be used further in the form of thin film. Examples of glass substrate can include particularly soda lime glass, barium strontium-containing glass, lead glass, alminosilicate glass, borosilicate glass, barium borosilicate glass, quartz and the like. In addition, examples of the polymer substrate can include polycarbonate, acryl, polyethylene terephthalate, polyethersulfide, polysulfone, and the like.

Among them, the polymer substrate in the form of a thin film is preferably used as the sealing member 18 from the viewpoint of thinning the element.

The sealing member 18 preferably has an oxygen transmittance measured in accordance with the method of JIS-K-7126-1987 of 1×10⁻³ ml/(m²·24 hr·atm) or less and a water vapor transmittance (25±0.5° C., relative humidity (90±2)% RH) measured in accordance with the method of JIS-K-7129-1992 of 1×10⁻³ g/(m²·24 hr) or less.

Furthermore, the above substrate material may also be processed into the form of a recessed plate to thereby be used as the sealing member 18. In this case, processing such as sandblast processing or chemical etching processing is performed on the substrate member to thereby form recessed portions.

Additionally, a metal material may be used without being limited to the form. Examples of the metal materials include one or more metals or alloys selected from the group consisting of stainless steel, iron, copper, aluminum, magnesium, nickel, zinc, chromium, titanium, molybdenum, silicon, germanium and tantalum. The whole light-emitting panel provided with the organic EL element 10 can be made thinner by using such a metal material as the sealing member 18 in a thin type film shape.

[Sealing Resin Layer]

The sealing resin layer 17 for fixing the sealing member 18 to the substrate 11 is also used in order to seal the organic EL element 10 held between the sealing member 18 and the substrate 11. Examples of the sealing resin layer 17 include a thermosetting adhesive such as an acrylic acid-based oligomer or methacrylic acid-based oligomer having a reactive vinyl group, or a thermosetting adhesive such as epoxy-based adhesive.

In addition, the form of the sealing resin layer 17 is preferably a thermosetting adhesive which is processed into a form of sheet. When using the sheet-like thermosetting adhesive, an adhesive (sealing material) which exhibits non-flowing property at normal temperature (approximately 25° C.), and which expresses flowability at a temperature within a range of 50 to 130° C. by heating is used.

An arbitrary adhesive can be used as the thermosetting adhesive. A suitable thermosetting adhesive is selected from the viewpoint of enhancement of adhesion to the sealing member 18 and the substrate 11 which are adjacent to the sealing resin layer 17. For example, there can be used, as the thermosetting adhesive, a resin containing, as main components, a compound having ethylenic double bond at the end or branch of the molecule and a thermally curable adhesive. Alternatively, depending on a lamination device and curing treatment device used during the production processes of the organic EL element 10, a thermosetting adhesive of melt-type may be used.

Furthermore, two or more of the above-described adhesives may be used in a mixed manner, and an adhesive having thermosetting property and ultraviolet ray curable property may be used.

### 2. Organic Electroluminescent Element

### Second Embodiment

### Overall Covered

[Configuration of Organic Electroluminescent Element]

Next, the second embodiment will be explained. FIG. 2 shows a schematic configuration of the organic electroluminescent element in the second embodiment. Hereinafter, the configuration of the organic electroluminescent element will be explained by referring this drawing.

The organic EL element 20 shown in FIG. 2 includes the substrate 11, the barrier layer 12, the first electrode 13, the organic functional layer 14, the second electrode 15, the covering intermediate layer 21, the sealing resin layer 17 and the sealing member 18. The organic EL element 20 has the same configuration as that of the above-described first embodiment except the covering intermediate layer 21. Therefore, in the following explanation, the overlapped detailed explanation as to the same constituent of the organic EL element in the first embodiment is omitted, and the organic EL element in the second embodiment will be explained.

In the organic EL element 20 shown in FIG. 2, the light-emitting laminate 19 composed of the first electrode 13, the organic functional layer 14 and the second electrode 15 is disposed on the substrate 11 having the barrier layer 12. In addition, the covering intermediate layer 21 is formed so as to cover the barrier layer 12 and the side surface and upper surfaces of the light-emitting laminate 19. Furthermore, the sealing member 18 is joined onto the covering intermediate layer 21 via the sealing resin layer 17.

In this configuration, the covering intermediate layer 21 is formed on the barrier layer 12 around the light-emitting laminate 19 (the organic functional layer 14), and is further formed from the surfaces of the barrier layer 12 to the position higher than the light-emitting laminate 19. Furthermore, the covering intermediate layer 21 is formed so as to cover the entire upper surface of the light-emitting laminate 19. Therefore, the sealing resin layer 17 which joins the sealing member 18 is connected only to the top of the covering intermediate layer 21.

The covering intermediate layer 21 can be formed using the same material as that of the organic EL element of the above first embodiment, and also can be formed by the same manufacturing method.

The sealing property of the organic EL element 20 is further enhanced by using the above material having a high sealing property such as the inorganic oxide, the inorganic nitride and the inorganic carbide, for the covering intermediate layer 21. Therefore, the sealing property of the organic EL element 20 can be further enhanced in comparison with the configuration of being sealed only by the sealing resin layer 17.

In the above-described configuration, the sealing resin layer 17 has a configuration of not making contact with the barrier layer 12 of the modified-polysilazane layer, or the light-emitting laminate 19 composed of the first electrode 13, the organic functional layer 14 and the second electrode 15. Thereby, the covering intermediate layer 21 can block the contact of the light-emitting laminate 19 with the resin component, an organic component and a component such as a filler which are contained in the sealing resin layer 17. As a result, it is possible to prevent degeneration and degradation of the organic functional layer 14 and the second electrode 15 by the contact with the components contained in the sealing resin layer 17 because of heating and pressurization in the solid-sealing process.

Furthermore, generally in the organic EL element, the processes from the formation of the first electrode 13, to the formation of the organic functional layer 14 and the formation of the second electrode 15 are carried out through serial processes under vacuum. In contrast to this, the solid-sealing process using the sealing resin layer 17 and the sealing member 18 are carried out in vacuum.

In such a case, unless the light-emitting laminate 19 is covered by the covering intermediate layer 21, the organic functional layer 14, the first electrode 13 and the second electrode 15 are exposed to the atmosphere. Accordingly, there is a possibility that the reliability of the organic EL element is influenced due to degradation of the organic functional layer 14, the first electrode 13 and the second electrode 15, by the contact with moisture and oxygen in the atmosphere.

In the organic EL element 20, when forming the covering intermediate layer 21 by the above method, the processes from the formation of the first electrode 13, to the formation of the organic functional layer 14, the formation of the second electrode 15, and the formation of the covering intermediate layer 21 can be carried out through a series of processes in vacuum. In this case, also in the solid-sealing process, the light-emitting laminate 19 composed of the first electrode 13, the organic functional layer 14 and the second electrode 15 is covered by the covering intermediate layer 21, and thus the light-emitting laminate 19 is not exposed to the atmosphere. As a result, in the solid-sealing process, it is possible to suppress the degradation of the first electrode 13, the organic functional layer 14, and the second electrode 15 and to further enhance the reliability of the organic EL element.

Note that, in the configuration shown in FIG. 2, although the light-emitting laminate 19 is configured to be covered by the covering intermediate layer 21 by forming the covering intermediate layer 21 at the position higher than the upper surface of the light-emitting laminate 19, a configuration of the covering intermediate layer 21 which covers the light-emitting laminate 19 is not limited to the above configuration. For example, by formation of the covering intermediate layer 21 through the use of a highly covering method such as ALD method, the light-emitting laminate 19 can be covered from the side surface to the upper surface by the covering intermediate layer 21 which is thinner than the light-emitting laminate 19. Namely, even in the configuration in which the covering intermediate layer 21 is not formed so that the thickness of the covering intermediate layer 21 is larger than that of the light-emitting laminate 19, the side surface and the upper surface of the light-emitting laminate 19 can be configured to be covered by the covering intermediate layer 21. In this configuration, the same effects as those in the configuration shown in FIG. 2 can be obtained.

According to the above configuration, the adhesion of the sealing resin layer 17 can be enhanced. Therefore, it is possible to suppress the peeling-off of the sealing member 18, by interposing the covering intermediate layer 21 between the barrier layer 12 made of the modified-polysilazane layer and the sealing resin layer 17.

Furthermore, it is possible to suppress the degradation of the organic EL element 20 by covering the light-emitting laminate 19 composed of the first electrode 13, the organic functional layer 14 and the second electrode 15, with the covering intermediate layer 21.

Accordingly, the reliability of the organic EL element can be further enhanced.

### 3. Organic Electroluminescent Element

### Third Embodiment

### Two Barrier Layers

[Configuration of Organic Electroluminescent Element]

Next, the third embodiment will be explained. FIG. 3 shows a schematic configuration of the organic electroluminescent element in the third embodiment. Hereinafter, the configuration of the organic electroluminescent element will be explained by referring this drawing.

The organic EL element 30 shown in FIG. 3 includes the substrate 11, a second barrier layer 32, a first barrier layer 31, the first electrode 13, the organic functional layer 14, the second electrode 15, the covering intermediate layer 21, the sealing resin layer 17 and the sealing member 18. The organic EL element 30 has the same configuration as that of the above-described second embodiment shown in FIG. 2 except the configuration of the first barrier layer 31 and the second barrier layer 32. Therefore, in the following explanation, the overlapped detailed explanation as to the same constituent of the organic EL element in the first embodiment and the second embodiment is omitted, and the organic EL element in the third embodiment will be explained.

In the organic EL element 30 shown in FIG. 3, the second barrier layer 32 is formed on the substrate 11. In addition, the first barrier layer 31 is formed on the second barrier layer 32. In addition, the light-emitting laminate 19 composed of the first electrode 13, the organic functional layer 14 and the second electrode 15 is disposed on the first barrier layer 31. Additionally, the covering intermediate layer 21 is formed so as to cover the first barrier layer 31 and the side surface and upper surfaces of the light-emitting laminate 19. Furthermore, the sealing member 18 is joined onto the covering intermediate layer 21 via the sealing resin layer 17.

In this configuration, a plurality of the barrier layer is formed in order to enhance the barrier property of the substrate 11. The first barrier layer 31 obtained by disposing the light-emitting laminate 19 composed of the first electrode 13, the organic functional layer 14 and the second electrode 15 is composed of the above-described modified-polysilazane layer. The second barrier layer 32 is provided between the first barrier layer 31 composed of the modified-polysilazane layer and the substrate 11.

In the case of forming the barrier layer from a plurality of layers, the total thickness of the barrier layers is within the range of 10 to 10000 nm, preferably within the range of 10 to 5000 nm, more preferably within the range of 100 to 3000 nm, and particularly preferably within the range of 200 to 2000 nm.

As described above, the laminated structure of the two barrier layers can be formed on the substrate 11, by forming the second barrier layer between the substrate 11 and the first barrier layer 31 of the modified-polysilazane layer. Furthermore, the barrier layer may be a laminated structure of three or more layers by forming a plurality of the barrier layer between the substrate 11 and the first barrier layer 31 made of the modified-polysilazane layer. By forming the barrier layer made of a plurality of the layer, the barrier property of the barrier layer provided on the substrate 11 can be enhanced in comparison with the case where the barrier layer is formed by the single modified-polysilazane layer.

The modified-polysilazane layer constituting the first barrier layer 31 can be formed by using the same material as that of the barrier layer in the above first embodiment, and also can be formed by the same manufacturing method.

The second barrier layer 32 may be formed by the same material as the first barrier layer 31, or may be formed by a different material.

There is used a material having a function of suppressing intrusion of water, oxygen, or the like which degrades the resin film into elements, for the second barrier layer 32. For example, the second barrier layer 32 is preferably formed by a coating film of an inorganic material or an organic material, or by a combination of these coating films. Specifically, there can be used silicon oxide, silicon dioxide, silicon nitride, and the like. Furthermore, in order to improve the fragility of the barrier film, it is more preferable to impart a laminated structure of these inorganic layers and a layer made of an organic material (organic layer). The lamination order of the inorganic layer and the organic layer is not particularly limited, and it is preferable that the both are alternately laminated a plurality of times.

In addition, the second barrier layer 32 preferably has a water vapor transmission rate of 0.01 g/(m²·24 hr) or less when measured in accordance with JIS-K-7129-1992 (temperature: 25 ±0.5° C., relative humidity: 90±2% RH). Furthermore, an oxygen transmission rate measured in accordance with JIS-K-7126-1987 is preferably 10⁻³ ml/(m²·24 h·atm) or less and a water vapor transmission rate is preferably 10⁻⁵ g/(m²·24 hr) or less.

Furthermore, the method for forming the barrier film is not particularly limited, and there can be used, for example, a vacuum vapor deposition method, a spattering method, a reactive spattering method, a molecular beam epitaxy method, a cluster ion beam method, an ion plating method, a plasma polymerization method, an atmospheric plasma polymerization method, a plasma CVD method, a laser CVD method, a thermal CVD method, a coating method, and the like. Particularly, the atmospheric plasma discharge polymerization method described in Japanese Patent Laid-Open No. 2004-68143 can be preferably used.

A preferable exemplary aspect as the second barrier layer 32 is preferably constituted of an inorganic film which has a refractive index distribution in the thickness direction, and which has one or more extreme values in the distribution of the refractive index. The inorganic film having one or more extreme values in the distribution of the refractive index can be constituted by the light-emitting laminate made of a plurality of layers which is constituted of a material containing silicon, oxygen and carbon, and which has different contents of silicon, oxygen and carbon.

Hereinafter, the inorganic film having one or more extreme values in the distribution of the refractive index, which is applicable to the second barrier layer 32 will be explained.

In the above inorganic film, a distribution curve of each element representing a relation between the distance from the surface of the second barrier layer 32 in the direction of thickness and the ratio of an atomic weight (atom ratio) of the above each element (silicon, oxygen or carbon) preferably satisfies the following conditions.

Note that the atom ratio of silicon, oxygen, or carbon is represented by the ratio of silicon, oxygen, or carbon relative to the total amount of each element of silicon, oxygen, and carbon [(Si, O, C)/(Si+O+C)].

The silicon distribution curve, the oxygen distribution curve and the carbon distribution curve represent the atom ratio of silicon, the atom ratio of oxygen and the atom ratio of carbon at a distance from the surface of the second barrier layer 32, respectively. Furthermore, a distribution curve representing the relation between the distance from the surface (interface at the first electrode 13 side) of the second barrier layer 32 in the direction of thickness and the ratio of a total atomic weight (atom ratio) of oxygen and carbon is defined as an oxygen-carbon distribution curve.

In the inorganic film constituting the second barrier layer 32, the atom ratios of silicon, oxygen and carbon, or the distribution curve of each element preferably satisfy the following conditions (i) to (iii).
(i) The atom ratio of silicon, the atom ratio of oxygen and the atom ratio of carbon satisfy a condition represented by a formula (1) below in regions of 90% or more of the thickness.

(the atom ratio of oxygen)>(the atom ratio of silicon)>(the atom ratio of carbon) (1)

Alternatively, the atom ratio of silicon, the atom ratio of oxygen and the atom ratio of carbon satisfy a condition represented by a formula (2) below in regions of 90% or more of the thickness.

(the atom ratio of carbon)>(the atom ratio of silicon)>(the atom ratio of oxygen) (2)

(ii) The carbon distribution curve has at least one maximum value and minimum value.

(iii) The absolute value of the difference between the maximum value and the minimum value of the atom ratios of carbon in the carbon distribution curve is 5 at % or more.

In addition, the inorganic film constituting the second barrier layer 32 may contain nitrogen in addition to silicon, oxygen and carbon. The refractive index of the second barrier layer 32 can be controlled by containing nitrogen. For example, the refractive index of SiO₂ is 1.5, whereas the refractive index of SiN is approximately 1.8 to 2.0. Therefore, the refractive index of 1.6 to 1.8, which is a preferable value, can be attained by containing nitrogen in the second barrier layer 32 and forming SiON in the second barrier layer 32. In this way, the refractive index of the second barrier layer 32 can be controlled by adjusting the content of nitrogen.

In the case where nitrogen is contained in addition to silicon, oxygen and carbon, the atom ratio of the silicon, oxygen, carbon or nitrogen is represented by the ratio of the silicon, oxygen, or carbon or nitrogen relative to the total amount of respective elements of silicon, oxygen, carbon and nitrogen [(Si, O, C, N)/(Si+O+C+N)].

The silicon distribution curve, the oxygen distribution curve, the carbon distribution curve and the nitrogen distribution curve represent the atom ratio of silicon, the atom ratio of oxygen, the atom ratio of carbon and the atom ratio of nitrogen at a distance from the surface of the second barrier layer 32, respectively.

The above-described inorganic film constituting the second barrier layer 32 is preferably a layer formed by a plasma chemical vapor deposition (plasma CVD) method. Particularly, the inorganic layer is preferably formed by the plasma chemical vapor deposition method of generating plasma by disposing the substrate 11 on a pair of film deposition rolls and by discharging between the pair of film deposition rolls. The plasma chemical vapor deposition method may be a method of the Penning discharge plasma system. Furthermore, when discharging between the pair of film deposition rolls, it is preferable to alternately reverse polarities of the pair of film deposition rolls.

When generating plasma in the plasma chemical vapor deposition method, it is preferable to generate plasma discharge in a space between a plurality of film deposition rolls. Particularly, it is more preferable to generate plasma by disposing the substrate 11 for each of a pair of film deposition rolls and by discharging between the pair of film deposition rolls, through the use of the pair of film deposition rolls.

According to this method, film deposition can be carried out on the substrate 11 existing on one film deposition roll, by arranging the substrate 11 on the pair of film deposition rolls, and by discharging between the film deposition rolls. Simultaneously, the film deposition can be carried out on the substrate 11 existing on the other film deposition roll. Therefore, the film deposition rate can be increased by two times and thus the thin film can be effectively produced. Furthermore, it is possible to form the films having the same structure on the respective substrate 11 of the one pair of film deposition rolls.

In addition, a film deposition gas containing an organic silicon compound and oxygen is preferably used for the above plasma chemical vapor deposition method. A content of oxygen in the film deposition gas is preferably not more than a theoretical amount required for completely oxidizing the total amount of the organic silicon compound in the film deposition gas.

The inorganic film constituting the second barrier layer 32 is preferably a layer formed by a continuous film deposition process.

### 4. Method of Manufacturing Organic Electroluminescent Element

### Fourth Embodiment

### Method of Manufacturing Organic Electroluminescent Element

The method of manufacturing the organic electroluminescent element 10 shown in FIG. 1 will be explained as one example of the method of manufacturing an organic electroluminescent element.

First, the barrier layer 12 is formed on the substrate 11 at a thickness of approximately 1 nm to 100 μm. For example, the polysilazane-containing liquid is coated on the substrate 11 at a given thickness. In addition, the barrier layer 12 made of the modified-polysilazane layer is formed by subjecting the coating film to the excimer treatment.

Note that, in the case of a configuration of having a plurality of barrier layer as in the third embodiment, each of various barrier layers is formed on the substrate 11 before forming the barrier layer 12.

Next, the light-emitting laminate 19 is formed on the barrier layer 12.

First, the first electrode 13 is formed on the barrier layer 12. The first electrode 13 is formed of a transparent electrically conductive material. For example, an electrode containing silver as a main component and having a thickness of approximately 3 nm to 15 nm, or a transparent electrically conductive substance such as ITO having a thickness of approximately 100 nm is formed. The first electrode 13 is formed by a spin coating method, a casting method, an inkjet method, a vapor deposition method, a spattering method, a printing method, or the like, and a vacuum vapor deposition method is particularly preferable from the viewpoints or the like that a homogeneous layer is easily obtained and that a pin hole is difficult to be generated. In addition, before and after the formation of the first electrode 13, pattern formation of an auxiliary electrode is carried out as necessary.

Next, the organic functional layer 14 is formed on the first electrode 13 by forming a positive hole injection layer, a positive hole transport layer, a light emitting layer, an electron transport layer and an electron injection layer in this order. Each of these layers is formed by a spin coating method, a casting method, an inkjet method, a vapor deposition method, a spattering method, a printing method, or the like; and a vacuum vapor deposition method or the spin coating method is particularly preferable from the viewpoints that a homogeneous layer is easily obtained and that a pin hole is difficult to be generated. Furthermore, a different forming method may be applied to each of the layers. When employing the vapor deposition method for forming each of these layers, although the vapor deposition conditions are different depending on the kinds of compound to be used, it is generally desirable to appropriately select a heating temperature of a boat for accommodating a compound within the ranges of 50° C. to 450° C., a degree of vacuum within the range of 10⁻⁶ Pa to 10⁻² Pa, a vapor deposition rate within the range of 0.01 nm/sec to 50 nm/sec, a substrate temperature within the range of −50° C. to 300° C., and a thickness within the range of 0.1 μm to 5 μm.

Next, the second electrode 15 serving as a cathode is formed by an optional forming method such as the vapor deposition method or the spattering method. At this time, while maintaining an insulation state to the first electrode 13 by the organic functional layer 14, a pattern formation is carried out so that a terminal part is pulled out at the peripheral edge of the substrate 11 from the upper side of the organic functional layer 14.

According to the above procedures, the light-emitting laminate 19 is formed on the barrier layer 12.

Then, the covering intermediate layer 16 is formed on the barrier layer 12 where the first electrode 13, the organic functional layer 14 and the second electrode 15 are not provided, namely, on the barrier layer 12 around the light-emitting laminate 19. The covering intermediate layer 16 is obtained, for example, by forming a compound such as an inorganic oxide, an inorganic nitride or an inorganic carbide at a thickness of not more than the upper surface of the second electrode 15 by the atmospheric pressure plasma method.

Note that, when forming the covering intermediate layer which covers the first electrode 13, the organic functional layer 14 and the second electrode 15 as in the second embodiment, a layer of the compound such as an inorganic oxide, an inorganic nitride or an inorganic carbide may be formed to a thickness (height) of covering the second electrode 15, by the above manufacturing method. Alternately, the covering intermediate layer which covers the side surface and the upper surface of the light-emitting laminate 19 may be formed by using a highly covering method.

Subsequently, the solid-sealing is carried out using the sealing resin layer 17 and the sealing member 18. First, the sealing resin layer 17 is formed on one side of the sealing member 18. In addition, the sealing resin layer 17 formation surface of the sealing member 18 is overlapped on the substrate 11 via the covering intermediate layer 16 so that the terminals of the lead electrodes of the first electrode 13 and the second electrode 15 are outside the sealing resin layer 17. A pressure is applied to the substrate 11 and the sealing member 18 after overlapping the substrate 11 and the sealing member 18. Furthermore, the temperature is increased to a curing temperature or more of the sealing resin layer 17 in order to cure the sealing resin layer 17.

According to the above steps, there is obtained the organic EL element 10 which is provided with the barrier layer of the modified-polysilazane layer and the covering intermediate layer 16 on the substrate 11 and which is solid-sealed. In the production of the organic EL element 10, it is preferable to carry out production throughout from the first electrode 13 to the covering intermediate layer 16 by one vacuum drawing, but other forming method may be applied by taking out a sample from a vacuum atmosphere in the middle of the vacuum drawing. At that time, care needs to be taken to carry out the procedures under a dry inert gas atmosphere.

Note that, in the above-described embodiment, there is made the explanation of the organic electroluminescent element of the bottom emission type in which the substrate and the barrier layer are included, and thereon, the first electrode, the organic functional layer and the second electrode are provided, and further the element is solid-sealed. The organic electroluminescent element is not limited to the bottom emission type, but may be, for example, a top emission type in which the light is taken out from the second electrode, or may be the both emission type where the light is taken out from the both sides. In the case where the organic electroluminescent element is a top emission type, the emitted light h is taken out from the second electrode by using a transparent material for the second electrode. In the case where the organic electroluminescent element is a both emission type, the emitted light h is taken out from the both surfaces by using a transparent material for the second electrode.

### EXAMPLES

Hereinafter, the present invention will be explained more specifically on the basis of Examples, but the present invention is not limited to following Examples.

[Production of Organic Electroluminescent Element of Bottom Emission Type]

Respective organic EL elements of samples 101 to 107, 201 to 207, 301 to 307 were produced so that the area of a light-emitting region became 5 cm×5 cm. In Table 2 below, configurations of respective layers in the respective organic EL elements of samples 101 to 107, 201 to 207, 301 to 307 are shown.

[Production Procedure of Organic Electroluminescent Element of Sample 101]

In the production of the sample 101, first, a second barrier layer and a first barrier layer were formed on a substrate of the transparent biaxial stretched polyethylene naphthalate film, and thereon, an undercoat layer formed of the compound No. 10 which is shown as the above nitrogen-containing layer and the electrically conductive layer made of silver were formed to produce a translucent electrode. Furthermore, an organic functional layer and a counter electrode were formed on the translucent electrode, and then the covering intermediate layer was formed. Furthermore, the organic EL element of the sample 101 was produced by solid-sealing with a sealing resin layer and a sealing member.

(Formation of Second Barrier Layer)

The substrate was set to the CVD roll coater (W35 Series, manufactured by KOBELCO), and an inorganic film (Si, O, C) which contains silicon, oxygen and carbon and has one or more extreme values in the distribution of the refractive index was produced, as the second barrier layer, on the substrate at a thickness of 300 nm under the following film formation condition (plasma CVD condition).

Supply amount of raw material gas (HMDSO): 50 sccm (Standard Cubic Centimeter per Minute)

Supply amount of oxygen gas (O₂): 500 sccm

Degree of vacuum in vacuum chamber: 3 Pa

Applied electric power from power source for plasma generation: 1.2 kW

Frequency of power source for plasma generation: 80 kHz

Transporting speed of film: 0.5 m/min.

(Formation of First Barrier Layer)

First, a 10% by mass of dibutyl ether solution of paerhydropolysilazane (AQUAMICANN120-10, non-catalytic type, manufactured by AZ Electronic Materials Co., Ltd.) was produced as a polysilazane-containing liquid.

Next, the polysilazane-containing liquid was coated on the substrate obtained by forming the second barrier layer through the use of a wireless bar so as to have a dry average thickness of 300 nm, and was treated for 1 minute under the atmosphere of the temperature of 85° C., humidity 55% RH to thereby be dried. Further, the moisture removing treatment was performed after the resultant coated film was kept for 10 minutes under the atmosphere of the temperature of 25° C. and humidity 10% RH (drew point −8° C.), with the result that the polysilazane-coating film was formed.

Subsequently, the following modification treatment was performed under the following modification condition by using the following ultraviolet ray irradiation apparatus after the substrate obtained by forming the polysilazane layer was fixed on the operation stage, with the result that a first barrier layer made of the polysilazane modified layer was formed on the substrate.

Ultraviolet ray irradiation apparatus: Excimer irradiation apparatus manufactured by M.D.Com

MODEL: MECL-M-1-200

Irradiation wavelength: 172 nm

Gas sealed in lamp: Xe

Excimer lamp light intensity: 130 mW/cm² (172 nm)

Distance between sample and light source: 1 mm

Stage heating temperature: 70° C.

Oxygen concentration in irradiation apparatus: 1.0%

Excimer lamp irradiation time: 5 sec.

(Formation of Undercoat Layer and First Electrode)

Next, the substrate obtained by forming a layer up to the first barrier layer was fixed onto a substrate holder of a commercial vapor deposition apparatus, the compound No. 10 was placed in the resistance heating boat made of tungsten, and then the substrate holder and the heating boat were attached to a first vacuum tank of the vacuum vapor deposition apparatus. In addition, silver (Ag) was placed in the resistance heating boat made of tungsten, and was attached to the second vacuum tank of the vacuum vapor deposition apparatus.

Subsequently, after reducing a pressure of the first vacuum tank of the vacuum vapor deposition apparatus to 4×10⁻⁴ Pa, the heating boat obtained by placing the compound No. 10 was heated by applying an electric current, and then, the undercoat layer of the first electrode having a thickness of 10 nm was provided at a vapor deposition rate of 0.1 nm/sec to 0.2 nm/sec.

Next, the substrate obtained by forming a layer up to the undercoat layer was moved to the second vacuum tank under vacuum, and after reducing a pressure of the second vacuum tank to 4×10⁻⁴ Pa, the heating boat containing silver was heated by applying an electric current. Thereby, there was formed the first electrode made of silver having a thickness of 8 nm at a vapor deposition rate of 0.1 nm/sec to 0.2 nm/sec.

(Organic Functional Layer to Second Electrode)

Subsequently, while moving the substrate after reducing a pressure to a degree of vacuum of 1×10⁻⁴ Pa by using the commercially available vacuum vapor deposition apparatus, the compound HT-1 was deposited at a vapor deposition rate of 0.1 nm/sec, with the result that the positive hole transport layer (HTL) of 20 nm was provided.

After that, by using the compound A-3 (blue light-emitting dopant), the compound A-1 (green light-emitting dopant), the compound A-2 (red light-emitting dopant) and the compound H-1 (host compound), the light-emitting layer having the thickness of 70 nm was formed in the co-deposition manner that the compound A-3 was deposited by changing the vapor deposition rate linearly depending on the position so as to be 35% by weight to 5% by weight in the direction of thickness, the compound A-1 and the compound A-2 were deposited at a vapor deposition rate of 0.0002 nm/sec to be a concentration of 0.2% by weight regardless to the film thickness, and the compound H-1 was deposited by changing the vapor deposition rate linearly depending on the position so as to be 64.6% by weight to 94.6% by weight.

After that, the electron transport layer was formed by deposition of the compound ET-1 at a film thickness of 30 nm, and further a potassium fluoride (KF) layer was formed at a thickness of 2 nm. Furthermore, the second electrode was formed by vapor deposition of aluminum at a thickness of 100 nm.

Note that the above-described compound HT-1, the compounds A-1 to -3, the compound H-1, and the compound ET-1 are the compounds shown in the followings.

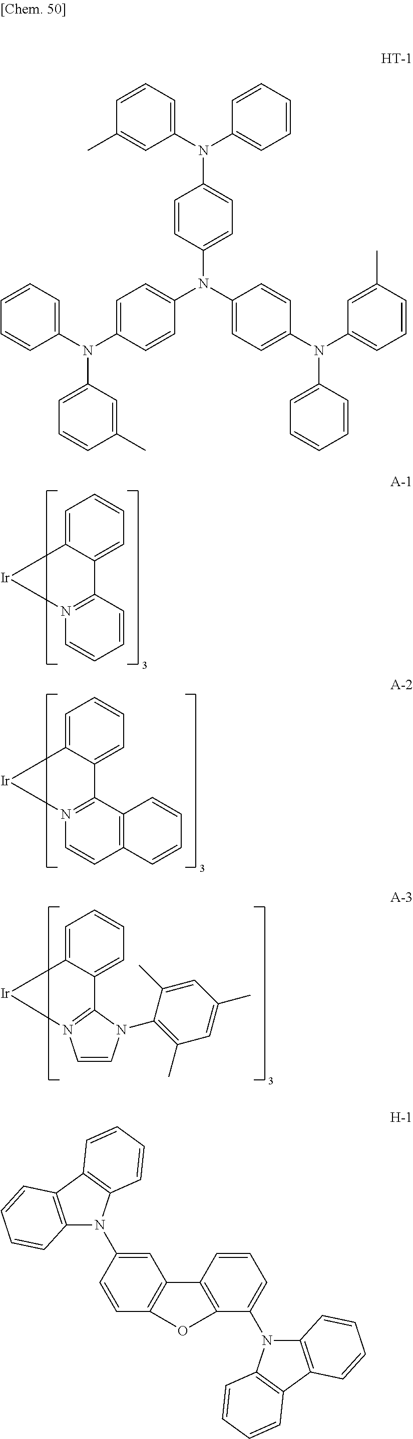

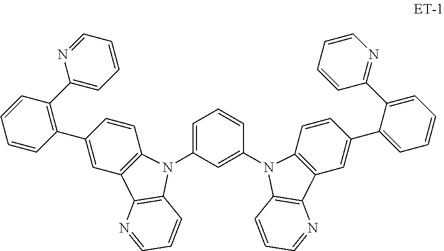 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1]

(Formation of Covering Intermediate Layer)

Next, the covering intermediate layer was formed on the barrier layer around the light-emitting laminate in which the first electrode, the organic functional layer and the second electrode are not formed. The covering intermediate layer was partially formed on the barrier layer around the light-emitting laminate except the light-emitting laminate so as to expose the upper surface of the second electrode in the same way as in the above first embodiment.

First, the sample obtained by forming a layer up to the second electrode was transported to the CVD apparatus. Next, after reducing the inner pressure of the vacuum tank of the CVD apparatus to 4×10⁻⁴ Pa, a silane gas (SiH₄), an ammonia gas (NH₃), a nitrogen gas (N₂) and a hydrogen gas (H₂) were introduced to the chamber. In the same way, a covering intermediate layer was formed by formation of a silicon nitride film of 250 nm by the plasma CVD method.

(Solid Sealing)

Through the use of the sample obtained by producing layers up to the covering intermediate layer and a sealing member obtained by coating, at a thickness of 30 μm, one surface of an aluminum foil having a thickness of 100 μm which was laminated with polyethylene terephthalate (PET) resin, the surface of the sealing member on which the adhesive was formed was continuously overlapped with the surface of the organic function layer so that the electrically conductive layer of the translucent electrode of the element and the edge part of an extraction electrode of the counter electrode appeared outside.

Next, the sample was disposed in a reduced pressure device and was held for five minutes while pressure was applied to the overlapped substrates each other under conditions of 90° C. and a reduced pressure of 0.1 MPa. Subsequently, the overlapped members were returned to the atmospheric pressure circumstance and were further heated at 120° C. for 15 minutes, with the result that the adhesive was cured.

The above-described sealing process was performed under the atmospheric pressure and under a nitrogen atmosphere of a moisture content of 1 ppm or less, in accordance with JIS B 9920, under conditions of measured cleanness of class 100, a dew-point temperature of −80° C. or less, an oxygen concentration of 0.8 ppm or less and atmospheric pressure. Note that descriptions related to the formation or the like of an extraction wiring from the positive electrode and the negative electrode are omitted.

According to the above-described process, the organic EL element of the sample 101 was produced.

[Procedure for Producing Organic Electroluminescent Element of Sample 102]

An organic EL element of Sample 102 was produced in the same procedure as in Sample 101 except that the covering intermediate layer was formed on the barrier layer and all over the light-emitting laminate including the side surface and the upper surface in the same way as in the above second embodiment.

[Procedure for Producing Organic Electroluminescent Element of Sample 103]

An organic EL element of Sample 103 was produced in the same procedure as in Sample 101 except that the material constituting the covering intermediate layer was a silicon oxide film of 250 nm. The covering intermediate layer was partially formed on the barrier layer around the light-emitting laminate except the light-emitting laminate so as to expose the upper surface of the second electrode in the same way as in the above first embodiment.

First, the sample obtained by forming a layer up to the second electrode was transported to the CVD apparatus. Next, after reducing the inner pressure of the vacuum tank of the CVD apparatus to 4×10⁻⁴ Pa, a silane gas (SiH₄), an oxygen gas (O₂), a nitrogen gas (N₂) and a hydrogen gas (H₂) were introduced to the chamber. In the same way, a covering intermediate layer was formed by formation of a silicon oxide film of 200 nm by the plasma CVD method.

[Procedure for producing organic electroluminescent element of Sample 104]

An organic EL element of Sample 104 was produced in the same procedure as in Sample 103 except that the covering intermediate layer was formed on the barrier layer and all over the light-emitting laminate including the side surface and the upper surface in the same way as in the above second embodiment.

[Procedure for Producing Organic Electroluminescent Element of Sample 105]

An organic EL element of Sample 105 was produced in the same procedure as in Sample 101 except that the material constituting the covering intermediate layer was an aluminum oxide film of 20 nm. The covering intermediate layer was partially formed on the barrier layer around the light-emitting laminate except the light-emitting laminate so as to expose the upper surface of the second electrode in the same way as in the above first embodiment.

First, the sample obtained by forming a layer up to the second electrode was transported to the PEALD apparatus. Next, at a temperature of the substrate of 80° C., a cycle that TMA (tetramethyl aluminum) and oxygen are alternately introduced is repeated by using the TMA as a raw material, argon as a purge gas. In the same way, a covering intermediate layer was formed by formation of an aluminum oxide film of 20 nm by the PEALD method.

[Procedure for Producing Organic Electroluminescent Element of Sample 106]

An organic EL element of Sample 106 was produced in the same procedure as in Sample 105 except that the covering intermediate layer was formed on the barrier layer and all over the light-emitting laminate including the side surface and the upper surface in the same way as in the above second embodiment. The covering intermediate layer composed of the aluminum oxide film of 20 nm was formed on the barrier layer and all over the light-emitting laminate including the side surface and the upper surface, by using the ALD method.

[Procedure for Producing Organic Electroluminescent Element of Sample 107]

An organic EL element of Sample 107 was produced without forming the covering intermediate layer. The production procedure was the same as the procedure in Sample 101 except that the covering intermediate layer was not formed.

[Procedure for Producing Organic Electroluminescent Element of Sample 201]

An organic EL element of Sample 201 was produced in the same procedure as in Sample 101 except that the second barrier layer was the modified-polysilazane layer in the same procedure as the above Sample 101. The second barrier layer was formed in the same way as in the first barrier layer of Sample 101. The covering intermediate layer was partially formed on the barrier layer around the light-emitting laminate except the light-emitting laminate so as to expose the upper surface of the second electrode in the same way as in the above first embodiment.

(Formation of Second Barrier Layer)

First, a 10% by mass of paerhydropolysilazane (AQUAMICA NN120-10, non-solvent type, manufactured by AZ Electronic Materials Co., Ltd.) in dibutyl ether was produced as the polysilazane-containing liquid.

Next, the polysilazane-containing liquid was coated on the substrate by a wireless bar so that a dry average thickness was 300 nm, and treated and dried under the atmosphere of the temperature of 85° C., humidity 55% RH for 1 minute. Furthermore, the polysilazane layer was formed by carrying out the moisture removing treatment after keeping under the atmosphere of the temperature of 25° C., humidity 10% RH (drew point −8° C.) for 10 minutes.

Next, the substrate in which the polysilazane layer was formed was fixed on the operation stage, and the modification treatment was carried out using the following ultraviolet ray irradiation apparatus under the following modification condition, with the result that the second barrier layer made of the modified-polysilazane layer was formed on the substrate.

Ultraviolet ray irradiation apparatus: Excimer irradiation apparatus manufactured by M.D.Com

MODEL: MECL-M-1-200

Irradiation wavelength: 172 nm

Gas sealed in lamp: Xe

Excimer lamp light intensity: 130 mW/cm² (172 nm)

Distance between sample and light source: 1 mm

Stage heating temperature: 70° C.

Oxygen concentration in irradiation apparatus: 1.0%

Excimer lamp irradiation time: 5 sec.

In Sample 201, the first barrier layer was further formed on the thus formed second barrier layer. Therefore, Sample 201 has the barrier layer having the configuration where the similar modified-polysilazane layers are laminated.

[Procedure for Producing Organic Electroluminescent Element of Sample 202]

An organic EL element of Sample 202 was produced in the same procedure as in Sample 201 except that the covering intermediate layer was formed on the barrier layer and all over the light-emitting laminate including its side surface and the upper surface in the same procedure as in the above second embodiment.

[Procedure for Producing Organic Electroluminescent Element of Sample 203]

An organic EL element of Sample 203 was produced in the same procedure as in Sample 201 except that the material for the covering intermediate layer was a silicon oxide film of 250 nm. The covering intermediate layer made of silicon oxide was formed in the same procedure as in Sample 103. The covering intermediate layer was partially formed on the barrier layer around the light-emitting laminate except the light-emitting laminate so as to expose the upper surface of the second electrode in the same procedire as in the above first embodiment.

[Procedure for Producing Organic Electroluminescent Element of Sample 204]

An organic EL element of Sample 204 was produced in the same procedure as in Sample 203 except that the covering intermediate layer was formed on the barrier layer and all over the light-emitting laminate including its side surface and the upper surface in the same procedure as in the above second embodiment.

[Procedure for Producing Organic Electroluminescent Element of Sample 205]

An organic EL element of Sample 205 was produced in the same procedure as in Sample 201 except that the material for the covering intermediate layer was an aluminum oxide film of 20 nm. The covering intermediate layer of aluminum oxide was formed in the same procedure as in Sample 105. The covering intermediate layer was partially formed on the barrier layer around the light-emitting laminate except the light-emitting laminate so as to expose the upper surface of the second electrode in the same way as in the above first embodiment.

[Procedure for Producing Organic Electroluminescent Element of Sample 206]

An organic EL element of Sample 206 was produced in the same procedure as in Sample 205 except that the covering intermediate layer was formed on the barrier layer and all over the light-emitting laminate including its side surface and the upper surface in the same procedure as in the above second embodiment.

[Procedure for Producing Organic Electroluminescent Element of Sample 207]

An organic EL element of Sample 207 was produced without forming the covering intermediate layer. The production procedure was the same as the procedure in Sample 201 except that the covering intermediate layer was not formed.

[Procedure for Producing Organic Electroluminescent Element of Sample 301]

An organic EL element of Sample 301 was produced in the same procedure as in Sample 101 except that the second barrier layer was not formed in the procedure of the above Sample 101. Namely, the organic EL element of Sample 301 was produced by forming only the first barrier layer on the substrate. The first barrier layer was formed in the same procedure as in the first barrier layer of Sample 101. The covering intermediate layer was partially formed on the barrier layer around the light-emitting laminate except the light-emitting laminate so as to expose the upper surface of the second electrode in the same way as in the above first embodiment.

[Procedure for Producing Organic Electroluminescent Element of Sample 302]

An organic EL element of Sample 302 was produced in the same procedure as in Sample 301 except that the covering intermediate layer was formed on the barrier layer and all over the light-emitting laminate including its side surface and the upper surface in the same procedure as in the above second embodiment.

[Procedure for Producing Organic Electroluminescent Element of Sample 303]

An organic EL element of Sample 303 was produced in the same procedure as in Sample 301 except that the material for the covering intermediate layer was a silicon oxide film of 250 nm. The covering intermediate layer made of silicon oxide was formed in the same procedure as in Sample 103. The covering intermediate layer was partially formed on the barrier layer around the light-emitting laminate except the light-emitting laminate so as to expose the upper surface of the second electrode in the same way as in the above first embodiment.

[Procedure for Producing Organic Electroluminescent Element of Sample 304]

An organic EL element of Sample 304 was produced in the same procedure as in Sample 303 except that the covering intermediate layer was formed on the barrier layer and all over the light-emitting laminate including its side surface and the upper surface in the same procedure as in the above second embodiment.

[Procedure for Producing Organic Electroluminescent Element of Sample 305]

An organic EL element of Sample 305 was produced in the same procedure as in Sample 301 except that the material for the covering intermediate layer was an aluminum oxide film of 20 nm. The covering intermediate layer made of aluminum oxide was formed in the same procedure as in Sample 105. The covering intermediate layer was partially formed on the barrier layer around the light-emitting laminate except the light-emitting laminate so as to expose the upper surface of the second electrode in the same way as in the above first embodiment.

[Procedure for Producing Organic Electroluminescent Element of Sample 306]

An organic EL element of Sample 306 was produced in the same procedure as in Sample 305 except that the covering intermediate layer was formed on the barrier layer and all over the light-emitting laminate including its side surface and the upper surface in the same procedure as in the above second embodiment.

[Procedure for Producing Organic Electroluminescent Element of Sample 307]

An organic EL element of Sample 307 was produced without forming the covering intermediate layer. The production procedures were the same as the procedures in Sample 301 except that the covering intermediate layer was not formed.

[Evaluation of Organic Electroluminescent Element]

(Bending Resistance)

The bending resistance was measured by bending each sample so as to apply a curvature of 30 mmφ bending diameter to the light emitting surface and the sealing surface at room temperature, and was evaluated by the number of cycle of bending at the time when the sealing member was peeled off.

1: 1 to 50 cycles
2: 51 to 100 cycles
3: 101 to 200 cycles
4: 201 to 300 cycles
5: Not peeled off even through bending by 301 cycles or more

(Storability: Generation Rate of Dark Spots)

The dark spot (hereinafter, referred to as DS) is a non-light emitting point formed on the organic EL element, and is formed by the brought-in moisture from the barrier substrate, the moisture entering through the barrier substrate to the EL layer, the brought-in moisture from the sealing member, and the like. The generation rate of DS was determined by subjecting each sample to the environmental test under the following conditions.

Each sample was kept for 24 hours under a circumstance of 85° C., 85% RH. Thereafter, in terms of each sample, a rate of generation (generation rate, initial DS generation rate) of dark spot area (non-light emitting portion) was measured by lighting of a constant voltage power supply. Note that each of the dark spot generation rates was calculated by photographing the light emission surface of the organic EL element of each sample, and then subjecting the image date to prescribed image processing.

Each of the measured dark spot generation rates was discriminated on the basis of the following five evaluation criteria, and the storability of each sample was evaluated.

5: Dark spot generation rate of 1% or less
4: Dark spot generation rate of more than 1% and less than 3%
3: Dark spot generation rate of 3% or more and less than 5%
2: Dark spot generation rate of 5% or more and less than 10%
1: Dark spot generation rate of 10% or more

Each of the configurations and the evaluation results of the organic EL elements of the above Sample 101 to 107, 201 to 207, and 301 to 307 is shown in Table 2.

TABLE 2

| | | | | Covering intermediate layer | | | | Storability | |
|---|---|---|---|---|---|---|---|---|---|
| Sample | | Barrier layer | | | Covered | Formation | Bending | (DS generation | |
| No. | Substrate | First | Second | Material | range | method | resistance | rate) | |
| 101 | PEN | PHPS | Si, O, C | SiNx | Partially | CVD | 5 | 5 | Present |
| | | | | | | | | | invention |
| 102 | PEN | PHPS | Si, O, C | SiNx | Overall | CVD | 5 | 5 | Present |
| | | | | | | | | | invention |
| 103 | PEN | PHPS | Si, O, C | SiOx | Partially | CVD | 4 | 5 | Present |
| | | | | | | | | | invention |
| 104 | PEN | PHPS | Si, O, C | SiOx | Overall | CVD | 4 | 5 | Present |
| | | | | | | | | | invention |
| 105 | PEN | PHPS | Si, O, C | Al₂O₃ | Partially | ALD | 3 | 5 | Present |
| | | | | | | | | | invention |
| 106 | PEN | PHPS | Si, O, C | Al₂O₃ | Overall | ALD | 3 | 5 | Present |
| | | | | | | | | | invention |
| 107 | PEN | PHPS | Si, O, C | — | — | — | 1 | 4 | Comparative |
| | | | | | | | | | example |
| 201 | PEN | PHPS | PHPS | SiNx | Partially | CVD | 5 | 4 | Present |
| | | | | | | | | | invention |
| 202 | PEN | PHPS | PHPS | SiNx | Overall | CVD | 5 | 4 | Present |
| | | | | | | | | | invention |
| 203 | PEN | PHPS | PHPS | SiOx | Partially | CVD | 4 | 4 | Present |
| | | | | | | | | | invention |
| 204 | PEN | PHPS | PHPS | SiOx | Overall | CVD | 4 | 4 | Present |
| | | | | | | | | | invention |
| 205 | PEN | PHPS | PHPS | Al₂O₃ | Partially | ALD | 3 | 4 | Present |
| | | | | | | | | | invention |
| 206 | PEN | PHPS | PHPS | Al₂O₃ | Overall | ALD | 3 | 4 | Present |
| | | | | | | | | | invention |
| 207 | PEN | PHPS | PHPS | — | — | — | 1 | 3 | Comparative |
| | | | | | | | | | example |
| 301 | PEN | PHPS | — | SiNx | Partially | CVD | 5 | 3 | Present |
| | | | | | | | | | invention |
| 302 | PEN | PHPS | — | SiNx | Overall | CVD | 5 | 3 | Present |
| | | | | | | | | | invention |
| 303 | PEN | PHPS | — | SiOx | Partially | CVD | 4 | 3 | Present |
| | | | | | | | | | invention |
| 304 | PEN | PHPS | — | SiOx | Overall | CVD | 4 | 3 | Present |
| | | | | | | | | | invention |
| 305 | PEN | PHPS | — | Al₂O₃ | Partially | ALD | 3 | 3 | Present |
| | | | | | | | | | invention |
| 306 | PEN | PHPS | — | Al₂O₃ | Overall | ALD | 3 | 3 | Present |
| | | | | | | | | | invention |
| 307 | PEN | PHPS | — | — | — | — | 1 | 2 | Comparative |
| | | | | | | | | | example |

As shown in Table 2, each of Samples 101 to 106, 201 to 206 and 301 to 306 obtained by providing the covering intermediate layer has more enhanced bending resistance than each of Samples 107, 207 and 307 without the covering intermediate layer. Accordingly, the adhesion of the sealing resin layer can be enhanced, with the result that the peeling-off of the sealing member is suppressed by forming the covering intermediate layer.

Furthermore, the sample obtained by forming the silicon nitride film as the covering intermediate layer has more excellent result in the bending resistant test than other samples. In addition, the sample obtained by forming the silicon oxide film has a better result next to the silicon nitride film. The result shows that the covering intermediate layer is preferably formed as an inorganic nitride.

In addition, the sample obtained by forming the silicon nitride film or the silicon oxide film by the CVD method as the covering intermediate layer has more enhanced bending resistance than sample obtained by forming the aluminum oxide by the ALD method. The result shows that the film formed by the CVD method is preferable as the covering intermediate layer.

Furthermore, each of Samples 101 to 107 and 201 to 207 obtained by providing the second barrier layer has more enhanced storability than each of Samples 301 to 307 without the second barrier layer. From the result, it is found that the barrier property of the substrate is enhanced by laminating a plurality of barrier layer, with the result that the reliability of the organic EL element is enhanced.

Moreover, each of Samples 101 to 107 obtained by forming, as the second barrier layer, the inorganic film containing silicon, oxygen and carbon by the plasma CVD method and having one or more extreme values in the distribution of the refractive index has more enhanced storability than each of Samples 201 to 207 obtained by forming the modified-polysilazane layer as the second barrier layer.

Accordingly, it is found that the barrier property of the substrate can be enhanced by having the above inorganic film as the second barrier layer. In addition, it is found that the barrier layer obtained by n laminating different materials has more enhanced barrier property than that of the barrier layer obtained by laminating the same material.

Note that the present invention is not limited to the configurations explained in the above-described embodiments, and various modifications and changes are possible within the scope not deviating from the gist of the present invention.
10, 20, 30 Organic electroluminescent (EL) element
11 Substrate
12 Barrier layer
13 First electrode
14 Organic functional layer
15 Second electrode
16, 21 Covering intermediate layer
17 Sealing resin layer
18 Sealing member
19 Light-emitting laminate
31 First barrier layer
32 Second barrier layer

1. An organic electroluminescent element which is solid-sealed by a flexible substrate and a sealing member joined, by a sealing resin layer, to the flexible substrate, the element comprising:
a barrier layer that is provided on a flexible substrate and comprises a modified-polysilazane layer;
a laminate that is laid out on top of the barrier layer and is provided with an organic functional layer that has at least one light-emitting layer between a pair of electrodes;
a covering intermediate layer formed on top of the barrier layer at least at the periphery of the laminate; and
a sealing member joined to the top of the covering intermediate layer with a sealing resin layer interposed therebetween.

2. The organic electroluminescent element according to claim 1, wherein the sealing resin layer includes a thermosetting resin.

3. The organic electroluminescent element according to claim 1, wherein the covering intermediate layer covers the laminated body.

4. The organic electroluminescent element according to claim 1, wherein the covering intermediate layer contains silicon nitride.

5. The organic electroluminescent element according to claim 1, wherein the barrier layer is a laminated structure of a first barrier layer and a second barrier layer, and the second barrier layer is provided on the flexible substrate, and the first barrier layer is provided on the second barrier layer.

6. The organic electroluminescent element according to claim 5, wherein the second barrier layer includes a modified-polysilazane layer.

7. A method of manufacturing an organic electroluminescent element, comprising the steps of:
forming a barrier layer on a flexible substrate;
forming a laminate by laminating, on top of the barrier layer, a pair of electrodes and an organic functional layer that has at least one light-emitting layer between the electrodes;
forming a covering intermediate layer on top of the barrier layer at the periphery of the laminate; and
coating a sealing resin layer and performing solid-sealing by a sealing member.

8. The method of manufacturing the organic electroluminescent element according to claim 7, wherein the covering intermediate layer is formed by a CVD method.
